(19) United States
(12) Patent Application Publication
(10) Pub. No.: US 2024/0219732 A1
(43) Pub. Date: Jul. 4, 2024

(54) ELECTRONIC DEVICE

(71) Applicant: SEMICONDUCTOR ENERGY LABORATORY CO., LTD., Atsugi-shi, Kanagawa-ken (JP)

(72) Inventors: Hidekazu MIYAIRI, Hadano, Kanagawa (JP); Sho KATO, Isehara, Kanagawa (JP)

(21) Appl. No.: 18/558,060

(22) PCT Filed: Apr. 28, 2022
(86) PCT No.: PCT/IB2022/053935

§ 371 Date: Oct. 30, 2023

(30) Foreign Application Priority Data
May 7, 2021 (JP) 2021-079172

(51) Int. Cl. G02B 27/01; H01L 25/16; H01L 25/18; H10K 59/90; H10K 59/95

(52) U.S. Cl. CPC G02B 27/0172; G02B 2027/0112; G02B 2027/0178; H01L 25/167; H01L 25/18; H10K 59/90; H10K 59/95

(57) ABSTRACT

An electronic device with high luminance is provided. The electronic device includes a first display apparatus, a second display apparatus, and an optical element. The first display apparatus includes a first light-emitting element and the second display apparatus includes a second light-emitting element. A color of first light emitted from the first light-emitting element is different from a color of second light emitted from the second light-emitting element. An optical element is provided between the first display apparatus and the second display apparatus. The optical element includes a first light guide plate and a second light guide plate.

### TECHNICAL FIELD

One embodiment of the present invention relates to a display apparatus, an electronic device, and a fabrication method thereof.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a driving method thereof, and a manufacturing method thereof.

### BACKGROUND ART

In recent years, display apparatuses have been expected to be applied to a variety of uses. Examples of uses for a large display apparatus include a television device for home use (also referred to as a TV or a television receiver), digital signage, and a PID (Public Information Display). In addition, a smartphone, a tablet terminal, and the like including a touch panel are being developed as portable information terminals.

Furthermore, display apparatuses have been required to have higher resolution. For example, electronic devices for virtual reality (VR), augmented reality (AR), substitutional reality (SR), or mixed reality (MR) are given as devices requiring high-resolution display apparatuses and have been actively developed.

A display apparatus including a micro light-emitting diode (micro LED) as a display device (also referred to as a display element) has been proposed (e.g., Patent Document 1). The display apparatus using micro LEDs as display devices has advantages of high luminance, high contrast, a long lifetime, and the like, and has been actively developed as a next-generation display apparatus.

### REFERENCE

### Patent Document

[Patent Document 1] Specification of United States Patent Application Publication No. 2014/0367705

### SUMMARY OF THE INVENTION

### Problems to be Solved by the Invention

Electronic devices for VR and AR require display apparatuses with high resolution and high luminance. In the case where micro LEDs are used as light-emitting elements of the display apparatus, the micro LEDs are required to have fineness and high luminance. Here, to obtain a high-luminance display apparatus, micro LEDs of different colors (e.g., three colors of red (R), green (G), and blue (B)) preferably emit light at the same or substantially the same luminance. However, it is known that the luminance of the micro LEDs of different colors depend on materials used for the light-emitting elements.

An object of one embodiment of the present invention is to provide a display apparatus or an electronic device with high luminance. An object of one embodiment of the present invention is to provide a display apparatus or an electronic device with high resolution. An object of one embodiment of the present invention is to provide a display apparatus or an electronic device with high definition. An object of one embodiment of the present invention is to provide a display apparatus or an electronic device with high display quality. An object of one embodiment of the present invention is to provide a display apparatus or an electronic device with low power consumption. An object of one embodiment of the present invention is to provide a display apparatus or an electronic device with high reliability. An object of one embodiment of the present invention is to provide a display apparatus or an electronic device with a wide color gamut.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is an electronic device including a first display apparatus, a second display apparatus, and an optical element. The first display apparatus includes a first light-emitting element, and the second display apparatus includes a second light-emitting element. A color of first light emitted from the first light-emitting element is different from a color of second light emitted from the second light-emitting element. The optical element is provided between the first display apparatus and the second display apparatus. The optical element includes a first light guide plate and a second light guide plate.

Another embodiment of the present invention is an electronic device including a first display apparatus, a second display apparatus, and an optical element. The first display apparatus includes a first light-emitting element, and the second display apparatus includes a second light-emitting element. A color of first light emitted from the first light-emitting element is different from a color of second light emitted from the second light-emitting element. The optical element is provided between the first display apparatus and the second display apparatus. The optical element includes a first light guide plate, a second light guide plate, a first input portion diffraction element, a second input portion diffraction element, a first output portion diffraction element, and a second output portion diffraction element. The first input portion diffraction element has a function of making the first light enter the first light guide plate, and the second input portion diffraction element has a function of making the second light enter the second light guide plate. The first output portion diffraction element has a function of delivering the first light entering the first light guide plate to an outside of the first light guide plate, and the second output portion diffraction element has a function of delivering the second light entering the second light guide plate to an outside of the second light guide plate.

In the above electronic device, it is preferable that the first display apparatus include a region overlapping with the second display apparatus with the optical element therebetween.

In the above electronic device, it is preferable that the first display apparatus do not overlap with the second display apparatus with the optical element therebetween.

In the above electronic device, it is preferable that the second display apparatus further include a third light-emitting element, and the color of the first light, the color of the second light, and a color of third light emitted from the third light-emitting element be different from each other.

In the above electronic device, it is preferable that the optical element further include a third input portion diffraction element and a third output portion diffraction element, the third input portion diffraction element have a function of making the third light enter the first light guide plate, the third output portion diffraction element have a function of delivering the third light entering the first light guide plate to the outside of the first light guide plate, and an image be formed by synthesizing the first light and the third light delivered by the first light guide plate and the second light delivered by the second light guide plate.

In the above electronic device, it is preferable that the first light-emitting element be an element emitting red light, the second light-emitting element be an element emitting green light, and the third light-emitting element be an element emitting blue light.

In the above electronic device, it is preferable that the first light-emitting element, the second light-emitting element, and the third light-emitting element be each a micro light-emitting diode including an inorganic compound as a light-emitting material.

In the above electronic device, it is preferable that the first light-emitting element be a micro light-emitting diode including an organic compound as a light-emitting material, and the second light-emitting element and the third light-emitting element be each a micro light-emitting diode including an inorganic compound as a light-emitting material.

In the above electronic device, it is preferable that the first light-emitting element be an element emitting blue light, the second light-emitting element be an element emitting green light, and the third light-emitting element be an element emitting red light.

In the above electronic device, it is preferable that the first light-emitting element, the second light-emitting element, and the third light-emitting element be each a micro light-emitting diode including an organic compound as a light-emitting material.

In the above electronic device, it is preferable that the first display apparatus further include a fourth light-emitting element, the second display apparatus further include a third light-emitting element, and the color of the first light, the color of the second light, a color of third light emitted from the third light-emitting element, and a color of fourth light emitted from the fourth light-emitting element be different from each other.

In the above electronic device, it is preferable that an image be formed by synthesizing the first light, the second light, the third light, and the fourth light delivered by the optical element.

In the above electronic device, it is preferable that the first light-emitting element be an element emitting red light, the second light-emitting element be an element emitting green light, the third light-emitting element be an element emitting blue light, and the fourth light-emitting element be an element emitting yellow light.

In the above electronic device, it is preferable that the second display apparatus further include a third light-emitting element and a fourth light-emitting element, and the color of the first light, the color of the second light, a color of third light emitted from the third light-emitting element, and a color of fourth light emitted from the fourth light-emitting element be different from each other.

In the above electronic device, it is preferable that an image be formed by synthesizing the first light, the second light, the third light, and the fourth light delivered by the optical element.

In the above electronic device, it is preferable that the first light-emitting element be an element emitting red light, the second light-emitting element be an element emitting green light, the third light-emitting element be an element emitting blue light, and the fourth light-emitting element be an element emitting white light.

Note that all of a plurality of light-emitting elements included in the above electronic device may be micro light-emitting diodes including an organic compound as a light-emitting material, or all of the plurality of light-emitting elements included in the above electronic device may be micro light-emitting diodes including an inorganic compound as a light-emitting material.

Alternatively, at least one of the plurality of light-emitting elements included in the above electronic device may be a micro light-emitting diode including an organic compound as a light-emitting material, or at least one of the plurality of light-emitting elements included in the above electronic device may be a micro light-emitting diode including an inorganic compound as a light-emitting material.

Alternatively, at least one of the plurality of light-emitting elements included in the above electronic device may be a micro light-emitting diode using a quantum dot.

### Effect of the Invention

One embodiment of the present invention can provide a display apparatus or an electronic device with high luminance. One embodiment of the present invention can provide a display apparatus or an electronic device with high resolution. One embodiment of the present invention can provide a display apparatus or an electronic device with high definition. One embodiment of the present invention can provide a display apparatus or an electronic device with high display quality. One embodiment of the present invention can provide a display apparatus or an electronic device with low power consumption. One embodiment of the present invention can provide a display apparatus or an electronic device with high reliability. One embodiment of the present invention can provide a display apparatus or an electronic device with a wide color gamut.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a perspective view illustrating a structure example of an electronic device. FIG. 1B is a schematic top view illustrating the structure example of the electronic device. FIG. 1C is a schematic side view illustrating the structure example of the electronic device.

FIG. 2A and FIG. 2B are cross-sectional views illustrating structure examples of an electronic device.

FIG. 3A and FIG. 3B are cross-sectional views illustrating structure examples of an electronic device.

FIG. 4A and FIG. 4B are cross-sectional views illustrating structure examples of an electronic device.

FIG. 5A is a perspective view illustrating a structure example of an electronic device. FIG. 5B and FIG. 5C are cross-sectional views illustrating the structure example of the electronic device.

FIG. 6A is a perspective view illustrating a structure example of an electronic device. FIG. 6B and FIG. 6C are cross-sectional views illustrating the structure example of the electronic device.

FIG. 7A is a perspective view illustrating a structure example of an electronic device. FIG. 7B is a schematic side view illustrating the structure example of the electronic device.

FIG. 8A to FIG. 8D are schematic top views illustrating structure examples of an electronic device.

FIG. 9A and FIG. 9B are cross-sectional views illustrating structure examples of an electronic device.

FIG. TOA is a perspective view illustrating a structure example of an electronic device. FIG. 10B to FIG. 10D are cross-sectional views illustrating the structure example of the electronic device.

FIG. 11A is a schematic top view illustrating a structure example of an electronic device. FIG. 11B is a cross-sectional view illustrating the structure example of the electronic device.

FIG. 12A is a schematic top view illustrating a structure example of an electronic device. FIG. 12B is a cross-sectional view illustrating a structure example of the electronic device.

FIG. 13A is a perspective view illustrating a structure example of an electronic device. FIG. 13B and FIG. 13C are cross-sectional views illustrating the structure example of the electronic device.

FIG. 14A is a schematic top view illustrating a structure example of an electronic device. FIG. 14B is a cross-sectional view illustrating the structure example of the electronic device.

FIG. 15A is a schematic top view illustrating a structure example of an electronic device. FIG. 15B is a cross-sectional view illustrating the structure example of the electronic device.

FIG. 16A is a schematic top view illustrating a structure example of an electronic device. FIG. 16B is a cross-sectional view illustrating the structure example of the electronic device.

FIG. 17A to FIG. 17C are schematic side views illustrating structure examples of an electronic device.

FIG. 18A to FIG. 18E are top views illustrating examples of a pixel.

FIG. 19 is a cross-sectional view illustrating an example of a display apparatus.

FIG. 20A to FIG. 20C are cross-sectional views illustrating an example of a method for fabricating a display apparatus.

FIG. 21A and FIG. 21B are cross-sectional views illustrating examples of a display apparatus.

FIG. 22A and FIG. 22B are cross-sectional views illustrating examples of a display apparatus.

FIG. 23A and FIG. 23B are cross-sectional views illustrating an example of a method for fabricating a display apparatus.

FIG. 24 is a cross-sectional view illustrating an example of a display apparatus.

FIG. 25 is a cross-sectional view illustrating an example of a display apparatus.

FIG. 26A to FIG. 26D are diagrams illustrating structure examples of a display apparatus.

FIG. 27A to FIG. 27D are diagrams illustrating structure examples of a display apparatus.

FIG. 28A to FIG. 28C are diagrams illustrating structure examples of a display apparatus.

FIG. 29A to FIG. 29D are diagrams illustrating structure examples of a light-emitting element.

FIG. 30A to FIG. 30C are diagrams illustrating examples of electronic devices.

FIG. 31A to FIG. 31C are diagrams illustrating examples of electronic devices.

FIG. 32 is a diagram illustrating an example of an electronic device.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. Furthermore, the same hatch pattern is used for the portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

The term “film” and the term “layer” can be interchanged with each other depending on the case or circumstances. For example, the term “conductive layer” can be replaced with the term “conductive film”. As another example, the term “insulating film” can be replaced with the term “insulating layer”.

In this specification, a light-emitting diode refers to a semiconductor element that emits light when a voltage is applied. Alternatively, a light-emitting diode refers to a semiconductor element that releases part of energy of recombination of an electron and a hole as light to the outside. There is no limitation on a light-emitting material of a light-emitting diode described in this specification, and as the light-emitting material, it is possible to use an organic compound (a fluorescent material, a phosphorescent material, or the like) or an inorganic compound (a compound semiconductor material, a quantum-dot material, or the like), for example. Note that a light-emitting diode using an organic compound as a light-emitting material is referred to as an organic EL element in some cases. In addition, a light-emitting diode using an inorganic compound as a light-emitting material is referred to as an inorganic EL element in some cases. In this specification, an organic EL element and an inorganic EL element are included in a light-emitting diode.

### Embodiment 1

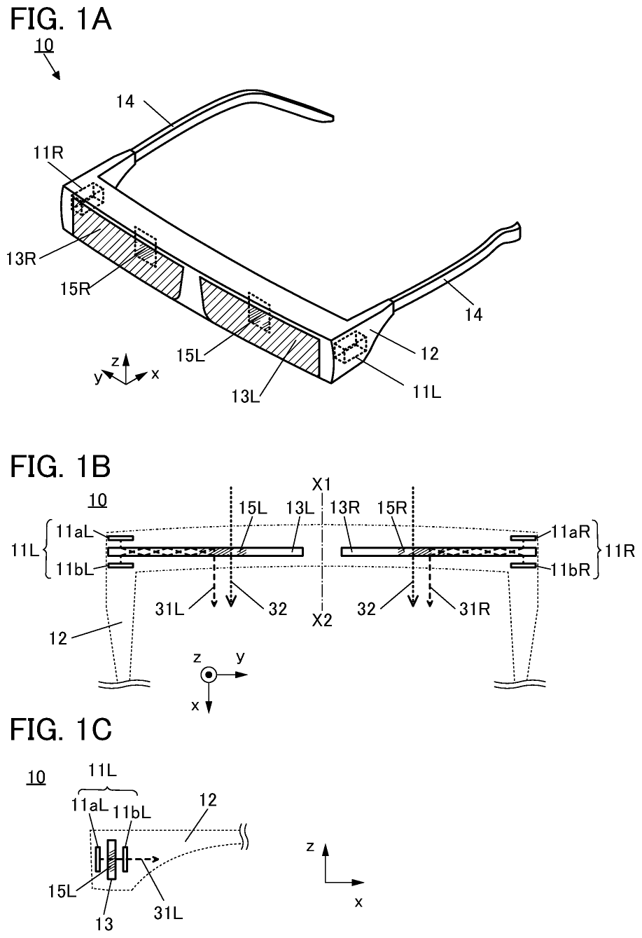

In this embodiment, electronic devices of one embodiment of the present invention are described with reference to FIG. 1 to FIG. 18.

### Structure Example of Electronic Device

One embodiment of the present invention is an electronic device including a first display apparatus, a second display apparatus, and an optical element. The first display apparatus includes a first light-emitting element, and the second display apparatus includes a second light-emitting element. A color of first light emitted from the first light-emitting element is different from a color of second light emitted from the second light-emitting element. The optical element includes a first light guide plate and a second light guide plate. Note that a light guide plate in this specification and the like refers to an optical component having a function of totally reflecting light entering from an input portion diffraction element to be described later so that the light reaches an output portion diffraction element to be described later.

As the first light-emitting element and the second light-emitting element, a micro LED is preferably used. Examples of the micro LED here include an organic LED using an organic material as a light-emitting material and an inorganic LED using an inorganic material as a light-emitting material.

An example of a display apparatus using an organic LED is what is called a monolithic display apparatus where an organic LED to be a light-emitting element is formed over a transistor provided over a glass substrate or a semiconductor substrate.

An example of a display apparatus using an inorganic LED is a display apparatus where an inorganic LED provided over a compound semiconductor substrate is mounted. Examples of a mounting method of the inorganic LED include a monolithic method and a bonding method. The bonding method is a method in which a display apparatus is formed by physically connecting an inorganic LED and a driving transistor, which are formed separately, in each pixel. This method is also referred to as a pick-and-place method.

As described above, to obtain a high-luminance display apparatus, micro LEDs of different colors (e.g., three colors of red (R), green (G), and blue (B)) preferably emit light at the same or substantially the same luminance. However, it is known that the luminance of the micro LEDs of different colors depend on materials used for the light-emitting elements.

Note that a blue (B) wavelength range is greater than or equal to 400 nm and less than 490 nm, and blue (B) light has at least one emission spectrum peak in the wavelength range. A green (G) wavelength range is greater than or equal to 490 nm and less than 580 nm, and green (G) light has at least one emission spectrum peak in the wavelength range. A red (R) wavelength range is greater than or equal to 580 nm and less than 700 nm, and red (R) light has at least one emission spectrum peak in the wavelength range.

For example, in the case of an organic LED, generally, phosphorescent materials are used as red (R) and green (G) light-emitting materials and a fluorescent material is used as a B (blue) light-emitting material. A phosphorescent material has excellent emission efficiency, and a fluorescent material tends to have lower emission efficiency than a phosphorescent material.

In the case of an inorganic LED, a light-emitting element is formed over a compound semiconductor in some cases. For example, in the case where red (R), green (G), and blue (B) light-emitting elements are formed over an indium gallium nitride (InGaN) substrate, it is known that the external quantum efficiency is much lower as the wavelength is longer. That is, to increase the luminance of the red (R) light-emitting element with a long wavelength, the red (R) light-emitting element is formed over a compound semiconductor substrate (e.g., gallium arsenide (GaAs) substrate) that is different from those for the green (G) and blue (B) light-emitting elements.

In view of this, in the electronic device of one embodiment of the present invention, an image is generated by providing light-emitting elements emitting light of different colors separately in two display apparatuses, and optically synthesizing light emitted from the two display apparatuses. For example, in the case where one pixel is composed of three subpixels, the three subpixels can be provided separately in two display apparatuses in a bonding method. Such a structure can reduce an area occupied by one pixel in one display apparatus compared to the structure where three subpixels are provided in one display apparatus. Accordingly, an electronic device with high definition can be achieved. In addition, in the structure where subpixels are separately provided in two display apparatuses utilizing a bonding method, the number of subpixels can be increased while the area occupied by one pixel is kept small. Accordingly, an electronic device with high definition and high color reproducibility can be achieved. Meanwhile, in a monolithic method, a micro LED with low emission efficiency (e.g., a red LED) is formed over a substrate included in one display apparatus and micro LEDs with high emission efficiency (e.g., a green LED and a blue LED) are formed over a substrate included in the other display apparatus, whereby an electronic device with high luminance and high resolution can be achieved.

More specific examples will be described below.

### Structure Example 1

FIG. 1A is a perspective view schematically illustrating a structure example of an electronic device 10 of one embodiment of the present invention. A z-axis shown in FIG. 1A is parallel to the vertical direction (a direction from a foot to a head) of a user (not illustrated), a y-axis shown in FIG. 1A is parallel to the lateral direction of the user, and an x-axis shown in FIG. 1A is parallel to the back and forth direction of the user. The electronic device 10 includes a pair of display apparatuses (a display apparatus 11R and a display apparatus 11L), a housing 12, a pair of optical elements (an optical element 13R and an optical element 13L), and a pair of wearing portions 14. FIG. 1A also illustrates a display region 15R where an image displayed on the display apparatus 11R is projected and a display region 15L where an image displayed on the display apparatus 11L is projected. Note that a “user” described in this specification and the like can be rephrased as a wearer of the electronic device of one embodiment of the present invention.

In the drawings and the like according to this specification, arrows indicating the x-axis, the y-axis, and the z-axis are shown in some cases. In this specification and the like, a direction along the x-axis is referred to as an x-axis direction in some cases. Unless otherwise specified, a forward direction and a backward direction are not distinguished from each other in some cases. Similarly, a direction along the y direction is referred to as a y-axis direction in some cases. A direction along the z-axis is referred to as a z-axis direction in some cases. The x-axis, the y-axis, and the z-axis are orthogonal to each other. In other words, the x-axis direction, the y-axis direction, and the z-axis direction are directions orthogonal to each other.

Note that in this specification and the like, one of a pair of components on the right eye side is denoted by a reference numeral with “R”. The other of the pair of components on the left eye side is denoted by a reference numeral with “L”. For example, the display apparatus 11R is a display apparatus on the right eye side, and the display apparatus 11L is a display apparatus on the left eye side.

In this specification and the like, in the case where the present invention is described using a pair of components that is denoted by a reference numeral without “R” or “L”, the component refers to one or both of the pair of components. In this specification and the like, in the case where the present invention is described using an expression of a display apparatus 11, the display apparatus 11 refers to one or both of the display apparatus 11R and the display apparatus 11L. In other words, the display apparatus 11 described in this specification and the like can be rephrased as one or both of the display apparatus 11R and the display apparatus 11L.

In this specification and the like, in the case where the present invention is described using one of a pair of components, the one of the pair of components can be rephrased as the other of the pair of components in some cases. In this specification and the like, in the case where the present invention is described using the display apparatus 11L, for example, the display apparatus 11L can be rephrased as the display apparatus 11R. As another example, in the case where the present invention is described using the display apparatus 11L and the optical element 13L, the display apparatus 11L can be rephrased as the display apparatus 11R and the optical element 13L can be rephrased as the optical element 13R.

Although FIG. 1A illustrates two display regions (the display region 15R and the display region 15L), the present invention is not limited thereto. The electronic device 10 may include one display region. In this case, the electronic device 10 includes the display apparatus 11R, the housing 12, the optical element 13R, and the pair of wearing portions 14. Alternatively, the electronic device 10 includes the display apparatus 11L, the housing 12, the optical element 13L, and the pair of wearing portions 14.

Although FIG. 1A illustrates a structure where the electronic device 10 includes the pair of optical elements (the optical element 13R and the optical element 13L), the present invention is not limited thereto. The number of optical elements included in the electronic device 10 may be one or three or more. For example, one optical element may serve as both the optical element 13R and the optical element 13L.

The electronic device 10 can project an image displayed on the display apparatus 11 to a display region 15 of an optical element 13. Since the optical element 13 has a light-transmitting property, a user of the electronic device 10 can see an image displayed on the display region 15, which is superimposed on a transmission image seen through the optical element 13. The electronic device 10 can be used as a device for AR, for example.

Although not illustrated in FIG. TA, the housing 12 may be provided with an infrared light source, an infrared light detection portion such as an infrared camera, an acceleration sensor such as a gyroscope sensor, and a processing portion. In this case, the electronic device 10 has a function of measuring a distance from an obstacle or a tracking target to the electronic device 10 with use of the infrared light source and the infrared light detection portion. In addition, the electronic device 10 has a function of sensing the orientation of a user's head with use of the acceleration sensor. Furthermore, the electronic device 10 has a function of simultaneously performing self-localization estimation and environmental map creation on the basis of information including the measured distance and the sensed orientation of the user's head, with use of the processing portion. With these functions, the electronic device 10 can perform display in which a video is superimposed on a specific coordinate in real space (what is called AR display). Note that the technique with which self-localization estimation and environmental map creation are performed simultaneously is referred to as SLAM (Simultaneous Localization and Mapping).

Although not illustrated in FIG. TA, the housing 12 is provided with a wireless receiver or a connector to which a cable can be connected, whereby a video signal or the like can be supplied to the housing 12. The housing 12 may be provided with a camera capable of taking what lies in front thereof. Furthermore, when the housing 12 is provided with an acceleration sensor such as a gyroscope sensor, the orientation of the user's head can be sensed and an image corresponding to the orientation can be displayed in the display region 15. The housing 12 may be provided with a speaker or earphones. The earphones provided in the housing 12 may include a vibration mechanism to function as bone-conduction earphones.

Although not illustrated in FIG. TA, the housing 12 is preferably provided with a battery, in which case charging can be performed with or without a wire. The housing 12 may be provided with a connector to which a cable for supplying a power supply potential can be connected.

Although not illustrated in FIG. TA, the housing 12 may be provided with an infrared light source and an infrared light detection portion (e.g., an infrared camera). The electronic device 10 may have a function of determining the direction of the user's gaze by detecting infrared light emitted from the infrared light source and reflected by an eyeball of the user with the infrared light detection portion, and performing image analysis. That is, the electronic device 10 may have an eye tracking function. The housing 12 may be provided with a camera for capturing an image of the user's eyes and their peripheries. The camera can use information on the movement of the eyeballs or eyelids of the user as an input means. The electronic device 10 may have a function of determining the direction of the user's gaze by analyzing the image of the user's eyes and their peripheries taken by the camera.

Next, a method for projecting an image to the display region 15 of the electronic device 10 is described with reference to FIG. 1B and FIG. 1C. FIG. 1B is a schematic top view of the electronic device 10 seen from above the user, and FIG. 1C is a schematic side view of the electronic device 10 seen from the left side of the user. Note that for clarity of the drawing, FIG. 1C illustrates only components of the electronic device 10 on the left eye side.

The housing 12 is provided with the display apparatus 11R, the display apparatus 11L, the optical element 13R, and the optical element 13L. The display apparatus 11R and the display apparatus 11L are placed line-symmetrically with a dashed-dotted line X1-X2 (a center line that divides the drawing in the lateral direction) shown in FIG. 1B as a symmetrical axis.

The display apparatus 11R includes a display apparatus 11aR and a display apparatus 11bR. The optical element 13R is provided between the display apparatus 11aR and the display apparatus 11bR. The display apparatus 11bR is placed on the user side (the head side of the wearer). Similarly, the display apparatus 11L includes a display apparatus 11aL and a display apparatus 11bL. The optical element 13L is provided between the display apparatus 11aL and the display apparatus 11bL. The display apparatus 11bL is placed on the user side.

Note that the display apparatus 11aR corresponds to the above-described first display apparatus, and the display apparatus 11bR corresponds to the above-described second display apparatus. The display apparatus 11aL corresponds to the above-described first display apparatus, and the display apparatus 11bL corresponds to the above-described second display apparatus.

As illustrated in FIG. 1B and FIG. 1C, the display apparatus 11aL includes a region overlapping with the display apparatus 11bL with the optical element 13L therebetween. Similarly, the display apparatus 11aR includes a region overlapping with the display apparatus 11bR with the optical element 13R therebetween. When seen from the side of the user as illustrated in FIG. 1C, the display apparatus 11aL and the display apparatus 11bL are positioned at the same or substantially the same level as the display region 15L. Similarly, the display apparatus 11aR and the display apparatus 11bR are positioned at the same or substantially the same level as the display region 15R.

The display apparatus 11aR and the display apparatus 11aL each include the first light-emitting element, and the display apparatus 11bR and the display apparatus 11bL each include the second light-emitting element. The color of the first light emitted from the first light-emitting element is preferably different from the color of the second light emitted from the second light-emitting element.

Each of the display apparatus 11bR and the display apparatus 11bL preferably further includes a third light-emitting element. A color of third light emitted from the third light-emitting element is preferably different from the color of the first light and the color of the second light.

Here, a method for projecting an image to the display region 15L is described. Note that in the drawing, a light path is indicated by a dotted arrow, a dashed arrow, or a dashed-dotted arrow in some cases. The dotted arrow, the dashed arrow, or the dashed-dotted arrow in the drawing is schematically shown for easy description of the present invention, and does not necessarily indicate an actual light path.

Light emitted from each of the display apparatus 11aL and the display apparatus 11bL enters the optical element 13L. Inside the optical element 13L, the light is totally reflected by the end surface of the optical element 13L repeatedly, and then reaches the display region 15L. The light that reaches the display region 15L is extracted to the outside of the optical element 13L, whereby the user can visually recognize both light 31L, where light emitted from the display apparatus 11aL and light emitted from the display apparatus 11bL are synthesized, and light 32 passing through the optical element 13L. Since the description of a method for projecting an image to the display region 15R is similar to that of the method for projecting an image to the display region 15L, the description is omitted. Here, light 31R illustrated in FIG. 1B is light where light emitted from the display apparatus 11aR and light emitted from the display apparatus 11bR are synthesized.

For entry of light into the optical element 13 and extraction of light from the optical element 13, a diffraction element is preferably used. Diffraction elements include a transmissive diffraction element and a reflective diffraction element. Examples of the diffraction element include a diffraction lattice, a holographic optical element, and a half mirror. The diffraction lattices include a transmissive diffraction lattice and a reflective diffraction lattice. Holograms displayed by a holographic optical element include an embossed (also referred to as relief) hologram and a volume hologram. Volume holograms include a transmissive volume hologram and a reflective hologram.

In the present invention, it is preferable to use a diffraction lattice or a holographic optical element as the diffraction element. The use of a diffraction lattice or a holographic optical element enables a reduction in the thickness of the optical element 13. Accordingly, the electronic device 10 can be downsized. It is further preferable to use a diffraction lattice as the diffraction element. The diffraction lattice can be fabricated by nanoimprinting, for example. Thus, the manufacturing cost of the electronic device 10 can be reduced as compared to the case of using a holographic optical element.

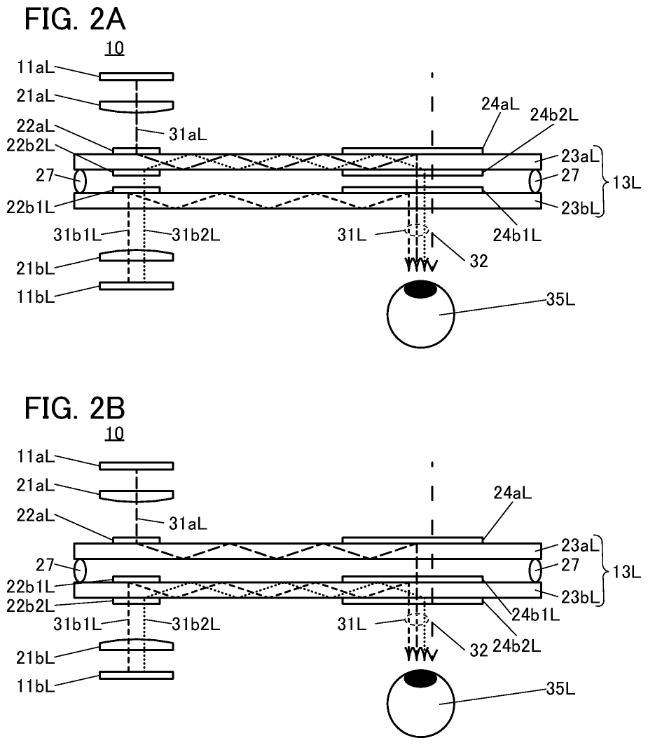

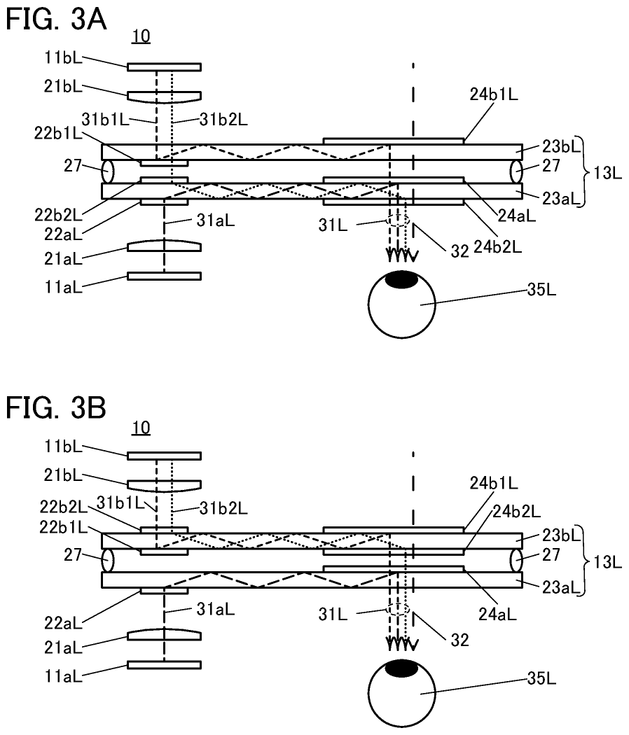

The details of the structure of the electronic device 10 and the details of the method for projecting an image to the display region are described with reference to FIG. 2A, FIG. 2B, FIG. 3A, and FIG. 3B.

### Structure Example 1-1

FIG. 2A is a cross-sectional view illustrating an example of a structure of the electronic device 10 on the left eye side. The electronic device 10 illustrated in FIG. 2A includes the display apparatus 11aL, the display apparatus 11bL, and the optical element 13L on the left eye side. The optical element 13L is provided between the display apparatus 11aL and the display apparatus 11bL. The display apparatus 11bL is placed on the user side.

The display apparatus 11aL illustrated in FIG. 2A emits light 31aL. Note that the color of light emitted by the display apparatus 11aL is not limited to one color, and may be two or more colors.

The display apparatus 11bL illustrated in FIG. 2A emits light 31b1L and light 31b2L. Here, the color of the light 31b1L and the color of the light 31b2L are different from each other. Note that the color of light emitted by the display apparatus 11bL is not limited to two colors, and may be one color or three or more colors.

The optical element 13L includes two light guide plates (a light guide plate 23aL and a light guide plate 23bL). The light guide plate 23aL is placed between the display apparatus 11aL and the light guide plate 23bL. The light guide plate 23bL is placed between the display apparatus 11bL and the light guide plate 23aL. Note that the number of light guide plates included in the optical element 13L may be one or three or more. In addition, one light guide plate may serve as both the light guide plate 23aL and one of the two light guide plates included in the optical element 13R. One light guide plate may serve as both the light guide plate 23bL and the other of the two light guide plates included in the optical element 13R.

Note that the light guide plate 23aL corresponds to the above-described first light guide plate, and the light guide plate 23bL corresponds to the above-described second light guide plate.

The optical element 13L includes a spacer 27. The spacer 27 is provided between the light guide plate 23aL and the light guide plate 23bL. When the spacer 27 is provided between the light guide plate 23aL and the light guide plate 23bL, an air layer is provided on a surface of the light guide plate 23aL and a surface of the light guide plate 23bL. With the air layer, light entering the light guide plate 23aL or the light guide plate 23bL can be totally reflected. Although FIG. 2A illustrates a structure where two spacers 27 are provided between the light guide plate 23aL and the light guide plate 23bL, without limitation thereto, one or three or more spacers 27 may be provided.

Note that the optical element 13L may include, instead of the spacer 27, a low-refractive-index layer that satisfies a condition where light entering the light guide plate 23aL or the light guide plate 23bL is totally reflected. In this case, the low-refractive-index layer is provided between the light guide plate 23aL and the light guide plate 23bL.

The optical element 13L includes three input portion diffraction elements (an input portion diffraction element 22aL, an input portion diffraction element 22b1L, and an input portion diffraction element 22b2L), and three output portion diffraction elements (an output portion diffraction element 24aL, an output portion diffraction element 24b1L, and an output portion diffraction element 24b2L). Note that the number of input portion diffraction elements and the number of output portion diffraction elements are preferably adjusted in accordance with the number of colors of light emitted from the display apparatus 11aL and the display apparatus 11bL. For example, in the case where the number of colors of light emitted from the display apparatus 11aL and the display apparatus 11bL is two, the optical element 13L preferably includes two input portion diffraction elements and two output portion diffraction elements.

Depending on the placement of the input portion diffraction element and the output portion diffraction element, the input portion diffraction element and the output portion diffraction element can each function as the spacer 27. For example, the input portion diffraction element and/or the output portion diffraction element provided between the light guide plate 23aL and the light guide plate 23bL can function as the spacer 27. In this case, the spacer 27 is not necessarily provided.

Note that the input portion diffraction element and the output portion diffraction element may be directly formed over the light guide plate, or may be formed separately from the light guide plate and then attached to the light guide plate.

The input portion diffraction element 22aL has a function of making the light 31aL enter the light guide plate 23aL or the light guide plate 23bL. The input portion diffraction element 22b1L has a function of making the light 31b1L enter the light guide plate 23aL or the light guide plate 23bL. The input portion diffraction element 22b2L has a function of making the light 31b2L enter the light guide plate 23aL or the light guide plate 23bL.

The output portion diffraction element 24aL has a function of delivering the light 31aL entering the light guide plate 23aL or the light guide plate 23bL to the outside of the light guide plate 23aL or the light guide plate 23bL. The output portion diffraction element 24b1L has a function of delivering the light 31b1L entering the light guide plate 23aL or the light guide plate 23bL to the outside of the light guide plate 23aL or the light guide plate 23bL. The output portion diffraction element 24b2L has a function of delivering the light 31b2L entering the light guide plate 23aL or the light guide plate 23bL to the outside of the light guide plate 23aL or the light guide plate 23bL.

In the electronic device 10 illustrated in FIG. 2A, the input portion diffraction element 22aL and the output portion diffraction element 24aL are provided on a surface of the light guide plate 23aL on the display apparatus 11aL side. The input portion diffraction element 22b1L and the output portion diffraction element 24b1L are provided on a surface of the light guide plate 23bL on the display apparatus 11aL side. The input portion diffraction element 22b2L and the output portion diffraction element 24b2L are provided on a surface of the light guide plate 23aL on the display apparatus 11bL side.

In the electronic device 10 illustrated in FIG. 2A, the input portion diffraction element 22b1L and the input portion diffraction element 22b2L may have a function of the spacer 27. The output portion diffraction element 24b1L and the output portion diffraction element 24b2L may have a function of the spacer 27. In this case, the spacer 27 is not necessarily provided.

Next, paths of light emitted from the display apparatus 11aL and the display apparatus 11bL in the electronic device 10 illustrated in FIG. 2A are described.

The light 31aL emitted from the display apparatus 11aL is made to enter the light guide plate 23aL by the input portion diffraction element 22aL. Inside the light guide plate 23aL, the light 31aL is totally reflected by the end surface of the light guide plate 23aL repeatedly, and then reaches the output portion diffraction element 24aL. The light 31aL that reaches the output portion diffraction element 24aL is delivered to a left eye 35L of the user by the output portion diffraction element 24aL. In the structure illustrated in FIG. 2A, the input portion diffraction element 22aL is a transmissive diffraction element and the output portion diffraction element 24aL is a reflective diffraction element.

The light 31b1L emitted from the display apparatus 11bL is made to enter the light guide plate 23bL by the input portion diffraction element 22b1L. Inside the light guide plate 23bL, the light 31b1L is totally reflected by the end surface of the light guide plate 23bL repeatedly, and then reaches the output portion diffraction element 24b1L. The light 31b1L that reaches the output portion diffraction element 24b1L is delivered to the left eye 35L of the user by the output portion diffraction element 24b1L. In the structure illustrated in FIG. 2A, the input portion diffraction element 22b1L and the output portion diffraction element 24b1L are reflective diffraction elements.

The light 31b2L emitted from the display apparatus 11bL is made to enter the light guide plate 23aL by the input portion diffraction element 22b2L. Inside the light guide plate 23aL, the light 31b2L is totally reflected by the end surface of the light guide plate 23aL repeatedly, and then reaches the output portion diffraction element 24b2L. The light 31b2L that reaches the output portion diffraction element 24b2L is delivered to the left eye 35L of the user by the output portion diffraction element 24b2L. In the structure illustrated in FIG. 2A, the input portion diffraction element 22b2L and the output portion diffraction element 24b2L are transmissive diffraction elements.

As described above, the user can visually recognize both the light 31L, where the light 31aL and the light 31b2L delivered by the light guide plate 23aL and the light 31b1L delivered by the light guide plate 23bL are synthesized, and the light 32 passing through the optical element 13L. Since an image is formed by synthesis of the light 31aL and the light 31b2L delivered by the light guide plate 23aL and the light 31b1L delivered by the light guide plate 23bL, the light 31L can be rephrased as an image.

Note that the types (transmissive type and reflective type) of the input portion diffraction element and the output portion diffraction element and the placement of the input portion diffraction element and the output portion diffraction element are not limited to the above, and preferably selected as appropriate depending on the distance between the input portion diffraction element and the output portion diffraction element, the thicknesses of the light guide plate 23aL and the light guide plate 23bL, and the like.

Here, alignment of the light 31aL with the light 31b1L and the light 31b2L is performed, so that a proper image can be obtained. The alignment may be performed on the basis of an alignment mark provided in the display apparatus 11aL and the light guide plate 23aL and on the basis of an alignment mark provided in the display apparatus 11bL and the light guide plate 23bL. Alternatively, alignment of the display apparatus 11aL, the display apparatus 11bL, the light guide plate 23aL, and the light guide plate 23bL may be performed in such a manner that alignment mark images displayed on the display apparatus 11aL and the display apparatus 11bL are synthesized using the optical element 13L and the synthesized image is checked.

Note that a lens 21aL may be provided between the display apparatus 11aL and the light guide plate 23aL. Similarly, a lens 21bL may be provided between the display apparatus 11bL and the light guide plate 23bL. As the lens 21aL and the lens 21bL, a collimate lens, a micro lens array, or the like can be used. The lens 21aL and the lens 21bL may be directly formed over the display apparatus 11aL and the display apparatus 11bL, respectively. Alternatively, the lens 21aL and the lens 21bL may be formed separately from the display apparatus 11aL and the display apparatus 11bL, and may be attached to the display apparatus 11aL and the display apparatus 11bL, respectively.

Here, the housing 12 (not illustrated in FIG. 2A) preferably includes a mechanism that adjusts the distance between the lens 21aL and the display apparatus 11aL, the distance between the lens 21bL and the display apparatus 11bL, or an angle between them. This enables focus adjustment, zooming in/out of an image, or the like. For example, a structure can be employed where one or both of the lens 21aL and the display apparatus 11aL and one or both of the lens 21bL and the display apparatus 11bL can be moved in the optical axis direction.

The above is the detailed description of the method for projecting an image to the display region on the left eye side. As described above, the structure of the electronic device 10 on the left eye side and the structure on the right eye side are positioned line-symmetrically with the dashed-dotted line X1-X2 (the center line that divides the drawing in the lateral direction) shown in FIG. 1B as the symmetrical axis. That is, the structure of the electronic device 10 on the left eye side which is inverted with the dashed-dotted line X1-X2 shown in FIG. 1B as the symmetrical axis corresponds to the structure of the electronic device 10 on the right eye side. Thus, the detailed description of the method for projecting an image to the display region on the left side can be referred to for the details of the method for projecting an image to the display region on the right eye side.

Note that the structure of the electronic device 10 on the left eye side for projecting an image to the display region on the left eye side is not limited to the structure illustrated in FIG. 2A. For example, the structure of the electronic device 10 on the left eye side may be a structure illustrated in FIG. 2B, a structure illustrated in FIG. 3A, or a structure illustrated in FIG. 3B.

### Structure Example 1-2

FIG. 2B is a cross-sectional view illustrating another example of the structure of the electronic device 10 on the left eye side. The electronic device 10 illustrated in FIG. 2B is different from the electronic device 10 illustrated in FIG. 2A in that, on the left eye side, the input portion diffraction element 22b2L and the output portion diffraction element 24b2L are provided on a surface of the light guide plate 23bL on the display apparatus 11bL side.

Since the paths of the light 31aL and the light 31b1L are similar to those described with reference to FIG. 2A, the description is omitted.

The light 31b2L emitted from the display apparatus 11bL is made to enter the light guide plate 23bL by the input portion diffraction element 22b2L. Inside the light guide plate 23bL, the light 31b2L is totally reflected by the end surface of the light guide plate 23bL repeatedly, and then reaches the output portion diffraction element 24b2L. The light 31b2L that reaches the output portion diffraction element 24b2L is delivered to the left eye 35L of the user by the output portion diffraction element 24b2L. Also in the structure illustrated in FIG. 2B, the input portion diffraction element 22aL and the output portion diffraction element 24aL are transmissive diffraction elements.

In the above manner, an image can be projected to the display region on the left eye side.

### Structure Example 1-3

FIG. 3A is a cross-sectional view illustrating another example of the structure of the electronic device 10 on the left eye side. The electronic device 10 illustrated in FIG. 3A is different from the electronic device 10 illustrated in FIG. 2A in that, on the left eye side, the display apparatus 11aL is placed on the user side. Specifically, on the left eye side of the electronic device 10 illustrated in FIG. 3A, the display apparatus 11bL is placed on the side facing the user with the optical element 13L therebetween, the light guide plate 23aL is placed on the user side, and the light guide plate 23bL is placed between the display apparatus 11bL and the light guide plate 23aL.

The electronic device 10 illustrated in FIG. 3A is different from the electronic device 10 illustrated in FIG. 2A in that, on the left eye side, the output portion diffraction element 24aL is provided on the surface of the light guide plate 23aL on the display apparatus 11bL side, the output portion diffraction element 24b1L is provided on the surface of the light guide plate 23bL on the display apparatus 11bL side, and the output portion diffraction element 24b2L is provided on the surface of the light guide plate 23aL on the display apparatus 11aL side.

Since the paths of the light 31aL, the light 31b1L, and the light 31b2L are similar to those described with reference to FIG. 2A, the description is omitted. The types (transmission type and reflective type) of the three input portion diffraction elements and the three output portion diffraction elements illustrated in FIG. 3A are similar to those described with reference to FIG. 2A.

In the above manner, an image can be projected to the display region on the left eye side.

### Structure Example 1-4

FIG. 3B is a cross-sectional view illustrating another example of the structure of the electronic device 10 on the left eye side. The electronic device 10 illustrated in FIG. 3B is different from the electronic device 10 illustrated in FIG. 3A in that, on the left eye side, the input portion diffraction element 22b2L is provided on the surface of the light guide plate 23bL on the display apparatus 11bL side, and the output portion diffraction element 24b2L is provided on the surface of the light guide plate 23bL on the display apparatus 11aL side.

Since the paths of the light 31aL, the light 31b1L, and the light 31b2L are similar to those described with reference to FIG. 2B, the description is omitted. The types (transmission type and reflective type) of the three input portion diffraction elements and the three output portion diffraction elements illustrated in FIG. 3B are similar to those described with reference to FIG. 2B.

In the above manner, an image can be projected to the display region on the left eye side.

FIG. 1B and the like illustrate examples where the display apparatus 11R is placed on the outer corner side of the right eye of the user and the display apparatus 11L is placed on the outer corner side of the left eye of the user; however, the display apparatus 11R may be placed on the inner corner side of the right eye of the user, and the display apparatus 11L may be placed on the inner corner side of the left eye of the user.

In the electronic device 10, the display apparatus 11aL and the display apparatus 11bL are placed to face each other with the optical element 13L therebetween. At this time, an image displayed on the display apparatus 11aL and an image displayed on the display apparatus 11bL are preferably in a laterally (horizontally) inverted relation. Accordingly, a full-color image can be generated by synthesizing the image displayed on the display apparatus 11aL and the image displayed on the display apparatus 11bL, and the full-color image can be projected to the display region 15L.

### Structure Example 1-5

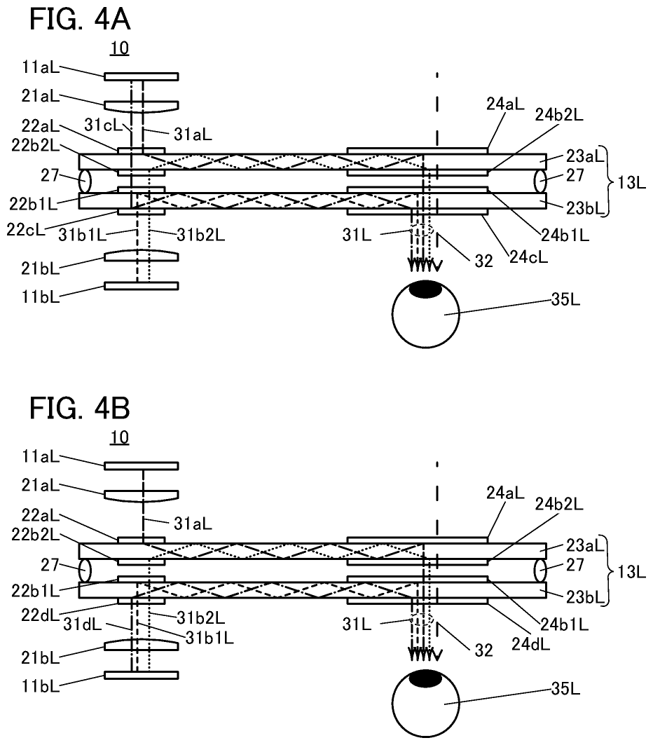

As described above, the color of light emitted by the display apparatus 11aL is not limited to one color, and may be two or more colors. FIG. 4A is a cross-sectional view illustrating an example of the structure of the electronic device 10 on the left eye side. The electronic device 10 illustrated in FIG. 4A is different from the electronic device illustrated in FIG. 2A in that the display apparatus 11aL emits the light 31aL and light 31cL. Note that the light 31cL is emitted from a light-emitting element different from the first light-emitting element. That is, the display apparatus 11aL further includes a fourth light-emitting element that emits the light 31cL. The electronic device 10 illustrated in FIG. 4A is different from the electronic device illustrated in FIG. 2A in including an input portion diffraction element 22cL and an output portion diffraction element 24cL. The electronic device 10 illustrated in FIG. 4A is different from the electronic device 10 illustrated in FIG. 2A in that, on the left eye side, the input portion diffraction element 22cL and the output portion diffraction element 24cL are provided on the surface of the light guide plate 23bL on the display apparatus 11bL side.

The color of the light 31cL is different from the colors of the light 31aL, the light 31b1L, and the light 31b2L. In the case where the color of the light 31aL is red, the color of the light 31b1L is one of green and blue, and the color of the light 31b2L is the other of green and blue, the color of the light 31cL is preferably yellow, for example. Note that the color of the light 31cL is not limited to yellow, and may be any one of cyan, magenta, white, and the like.

The input portion diffraction element 22cL is of a reflective type, and the output portion diffraction element 24cL is of a transmission type. Note that the types (transmissive type and reflective type) of the other three input portion diffraction elements and the other three output portion diffraction elements illustrated in FIG. 4A are similar to those described with reference to FIG. 2A.

Since the paths of the light 31aL, the light 31b1L, and the light 31b2L are similar to those described with reference to FIG. 2A, the description is omitted.

The light 31cL emitted from the display apparatus 11aL is made to enter the light guide plate 23bL by the input portion diffraction element 22cL. Inside the light guide plate 23bL, the light 31cL is totally reflected by the end surface of the light guide plate 23bL repeatedly, and then reaches the output portion diffraction element 24cL. The light 31cL that reaches the output portion diffraction element 24cL is delivered to the left eye 35L of the user by the output portion diffraction element 24cL.

In the above manner, the user can visually recognize both the light 31L, where the light 31aL and the light 31b2L delivered by the light guide plate 23aL and the light 31b1L and the light 31cL delivered by the light guide plate 23bL are synthesized, and the light 32 passing through the optical element 13L. Since an image is formed by synthesis of the light 31aL and the light 31b2L delivered by the light guide plate 23aL and the light 31b1L and the light 31cL delivered by the light guide plate 23bL, the light 31L can be rephrased as an image.

In the above manner, an image can be projected to the display region on the left eye side.

With the above structure, a display apparatus or an electronic device with a wide color gamut can be provided.

### Structure Example 1-6

As described above, the color of light emitted from the display apparatus 11bL is not limited to two colors, and may be one color or three or more colors. FIG. 4B is a cross-sectional view illustrating an example of the structure of the electronic device 10 on the left eye side. The electronic device 10 illustrated in FIG. 4B is different from the electronic device illustrated in FIG. 2A in that the display apparatus 11bL emits the light 31b1L, the light 31b2L, and light 31dL. Note that the light 31dL is emitted from a light-emitting element different from the second light-emitting element and the third light-emitting element. That is, the display apparatus 11aL further includes the fourth light-emitting element that emits the light 31dL. The electronic device 10 illustrated in FIG. 4B is different from the electronic device illustrated in FIG. 2A in including an input portion diffraction element 22dL and an output portion diffraction element 24dL. The electronic device 10 illustrated in FIG. 4B is different from the electronic device 10 illustrated in FIG. 2A in that, on the left eye side, the input portion diffraction element 22dL and the output portion diffraction element 24dL are provided on the surface of the light guide plate 23bL on the display apparatus 11bL side.

The color of the light 31dL is different from the colors of the light 31aL, the light 31b1L, and the light 31b2L. In the case where the color of the light 31aL is red, the color of the light 31b1L is one of green and blue, and the color of the light 31b2L is the other of green and blue, the color of the light 31dL is preferably white, for example. Note that the color of the light 31dL is not limited to white, and may be any one of cyan, magenta, yellow, and the like.

The type of the input portion diffraction element 22dL and the type of the output portion diffraction element 24cL are each a transmission type. Note that the types (transmissive type and reflective type) of the other three input portion diffraction elements and the other three output portion diffraction elements illustrated in FIG. 4B are similar to those described with reference to FIG. 2A.

Since the paths of the light 31aL, the light 31b1L, and the light 31b2L are similar to those described with reference to FIG. 2A, the description is omitted.

The light 31dL emitted from the display apparatus 11bL is made to enter the light guide plate 23bL by the input portion diffraction element 22dL. Inside the light guide plate 23bL, the light 31dL is totally reflected by the end surface of the light guide plate 23bL repeatedly, and then reaches the output portion diffraction element 24dL. The light 31dL that reaches the output portion diffraction element 24dL is delivered to the left eye 35L of the user by the output portion diffraction element 24dL.

In the above manner, the user can visually recognize both the light 31L, where the light 31aL and the light 31b2L delivered by the light guide plate 23aL and the light 31b1L and the light 31dL delivered by the light guide plate 23bL are synthesized, and the light 32 passing through the optical element 13L. Since an image is formed by synthesis of the light 31aL and the light 31b2L delivered by the light guide plate 23aL and the light 31b1L and the light 31dL delivered by the light guide plate 23bL, the light 31L can be rephrased as an image.

In the above manner, an image can be projected to the display region on the left eye side.

With the above structure, a display apparatus or an electronic device with a wide color gamut can be provided.

### Structure Example 2

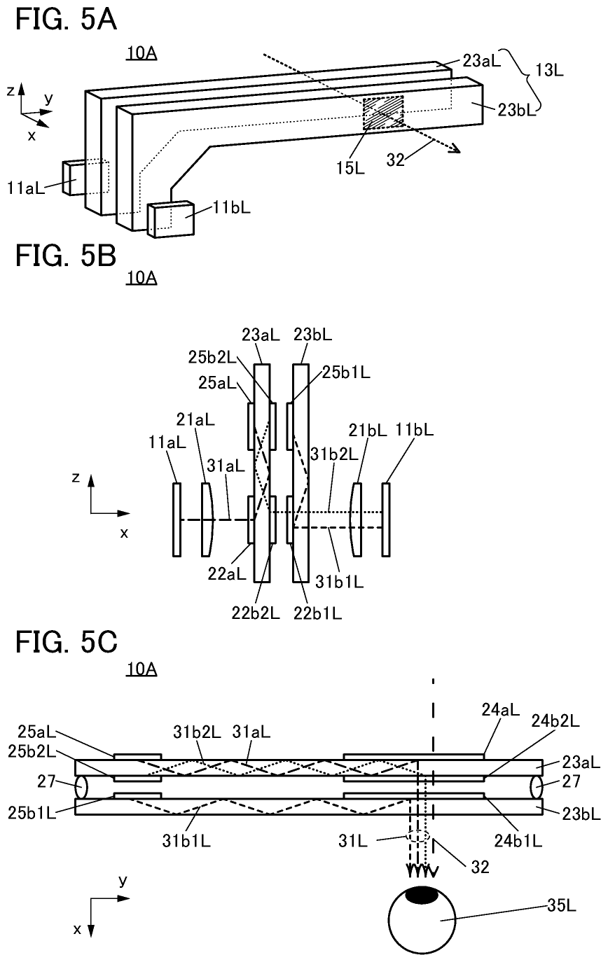

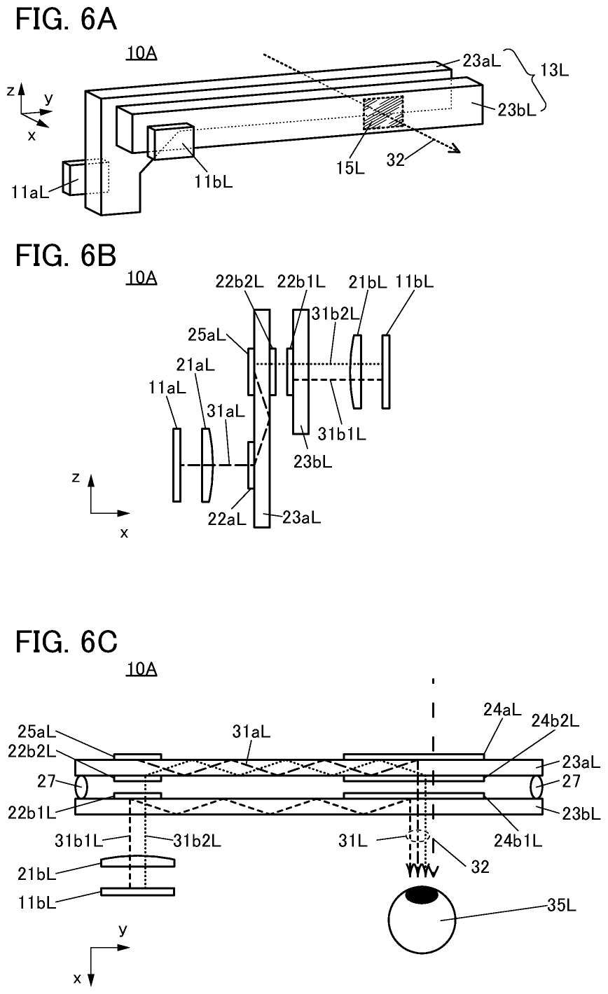

In FIG. 2A, FIG. 2B, FIG. 3A, and FIG. 3B, description is made on the assumption that the display apparatus 11aL and the display apparatus 11bL are positioned at the same or substantially the same level as the display region when seen from the side of the user; however, the level of one or both of the display apparatus 11aL and the display apparatus 11bL may be different from the level of the display region. Here, an electronic device in which the level of one or both of the display apparatus 11aL and the display apparatus 11bL is different from the level of the display region is described with reference to FIG. 5 and FIG. 6.

### Structure Example 2-1

In FIG. 5A is a perspective view illustrating an example of a structure of an electronic device 10A on the left eye side. The z-axis shown in FIG. 5A is parallel to the vertical direction (a direction from a foot to a head) of a user (not illustrated), the y-axis shown in FIG. 5A is parallel to the lateral direction of the user, and the x-axis shown in FIG. 5A is parallel to the back and forth direction of the user. Note that for clarity of the drawing, some components are omitted in the perspective view of FIG. 5A.

FIG. 5B is a cross-sectional view that illustrates the example of the structure of the electronic device 10A on the left eye side illustrated in FIG. 5A and is seen from the left side of the user. FIG. 5B corresponds to the xz plane including the display apparatus 11aL and the display apparatus 11bL. FIG. 5C is a cross-sectional view illustrating the example of the structure of the electronic device 10A on the left eye side seen from above the user. FIG. 5C corresponds to the xy plane including the display region 15L (not illustrated).

The electronic device 10A illustrated in FIG. 5A to FIG. 5C is different from the electronic device 10 illustrated in FIG. 2A in that, on the left eye side, the levels of the display apparatus 11aL and the display apparatus 11bL are lower than the level of the display region 15L. In this case, the display apparatus 11aL includes a region overlapping with the display apparatus 11bL with the optical element 13L therebetween. In addition, the electronic device 10A illustrated in FIG. 5A to FIG. 5C is different from the electronic device illustrated in FIG. 2A in including a diffraction element 25aL, a diffraction element 25b1L, and a diffraction element 25b2L. Specifically, the diffraction element 25aL is provided on the surface of the light guide plate 23aL on the display apparatus 11aL side, the diffraction element 25b1L is provided on the surface of the light guide plate 23bL on the display apparatus 11aL side, and the diffraction element 25b2L is provided on the surface of the light guide plate 23aL on the display apparatus 11bL side.

Here, each of the diffraction element 25aL, the diffraction element 25b1L, and the diffraction element 25b2L is of a reflective type. Note that the types (transmission type and reflective type) of the three input portion diffraction elements illustrated in FIG. 5B are similar to those described with reference to FIG. 2A. In addition, the types (transmission type and reflective type) of the three output portion diffraction elements illustrated in FIG. 5C are similar to those described with reference to FIG. 2A.

The light 31aL emitted from the display apparatus 11aL is made to enter the light guide plate 23aL by the input portion diffraction element 22aL. Inside the light guide plate 23aL, the light 31aL is totally reflected by the end surface of the light guide plate 23aL repeatedly to travel in the z-axis direction, and then reaches the diffraction element 25aL. The traveling direction of the light 31aL that reaches the diffraction element 25aL is changed into the y-axis direction by the diffraction element 25aL, and the light 31aL is totally reflected by the end surface of the light guide plate 23aL repeatedly, and then reaches the output portion diffraction element 24aL. The light 31aL that reaches the output portion diffraction element 24aL is delivered to the left eye 35L of the user by the output portion diffraction element 24aL.

The light 31b1L emitted from the display apparatus 11bL is made to enter the light guide plate 23bL by the input portion diffraction element 22b1L. Inside the light guide plate 23bL, the light 31b1L is totally reflected by the end surface of the light guide plate 23bL repeatedly to travel in the z-axis direction, and then reaches the diffraction element 25b1L. The traveling direction of the light 31b1L that reaches the diffraction element 25b1L is changed into the y-axis direction by the diffraction element 25b1L, and the light 31b1L is totally reflected by the end surface of the light guide plate 23bL repeatedly, and then reaches the output portion diffraction element 24b1L. The light 31b1L that reaches the output portion diffraction element 24b1L is delivered to the left eye 35L of the user by the output portion diffraction element 24b1L.

The light 31b2L emitted from the display apparatus 11bL is made to enter the light guide plate 23aL by the input portion diffraction element 22b2L. Inside the light guide plate 23aL, the light 31b2L is totally reflected by the end surface of the light guide plate 23aL repeatedly to travel in the z-axis direction, and then reaches the diffraction element 25b2L. The traveling direction of the light 31b2L that reaches the diffraction element 25b2L is changed into the y-axis direction by the diffraction element 25b2L, and the light 31b2L is totally reflected by the end surface of the light guide plate 23aL repeatedly, and then reaches the output portion diffraction element 24b2L. The light 31b2L that reaches the output portion diffraction element 24b2L is delivered to the left eye 35L of the user by the output portion diffraction element 24b2L.

In the above manner, an image can be projected to the display region on the left eye side.

### Structure Example 2-2

FIG. 6A is a perspective view illustrating another example of the electronic device 10A on the left eye side. The z-axis shown in FIG. 6A is parallel to the vertical direction (a direction from a foot to a head) of a user (not illustrated), the y-axis shown in FIG. 6A is parallel to the lateral direction of the user, and the x-axis shown in FIG. 6A is parallel to the back and forth direction of the user. Note that for clarity of the drawing, some components are omitted in the perspective view of FIG. 6A.

FIG. 6B is a cross-sectional view that illustrates the example of the structure of the electronic device 10A on the left eye side illustrated in FIG. 6A and is seen from the left side of the user. FIG. 6B corresponds to the xz plane including the display apparatus 11aL and the display apparatus 11bL. FIG. 6C is a cross-sectional view illustrating the example of the structure of the electronic device 10A on the left eye side seen from above the user. FIG. 6C corresponds to the xy plane including the display apparatus 11bL and the display region 15L (not illustrated).

The electronic device 10A illustrated in FIG. 6A to FIG. 6C is different from the electronic device 10 illustrated in FIG. 2A in that, on the left eye side, the level of the display apparatus 11aL is lower than the level of the display region 15L. In the electronic device 10A illustrated in FIG. 6A to FIG. 6C, the display apparatus 11aL does not overlap with 11bL with the optical element 13L therebetween. The electronic device 10A illustrated in FIG. 6A to FIG. 6C is different from the electronic device illustrated in FIG. 2A in including the diffraction element 25aL.

The electronic device 10A illustrated in FIG. 6A to FIG. 6C is different from the electronic device 10A illustrated in FIG. 5A to FIG. 5C in that, on the left eye side, the level of the display apparatus 11bL and the level of the display region 15L are the same or substantially the same. The electronic device 10A illustrated in FIG. 6A to FIG. 6C is different from the electronic device 10A illustrated in FIG. 5A to FIG. 5C in including neither the diffraction element 25b1L nor the diffraction element 25b2L.

Here, the type of the diffraction element 25aL is a reflective type. Note that the types (transmission type and reflective type) of the three input portion diffraction elements illustrated in FIG. 6B are similar to those described with reference to FIG. 2A. In addition, the types (transmission type and reflective type) of the three output portion diffraction elements illustrated in FIG. 5C are similar to those described with reference to FIG. 2A.

Since the path of the light 31aL is similar to that described with reference to FIG. 5B and FIG. 5C, the description is omitted. Since the paths of the light 31b1L and the light 31b2L are similar to those described with reference to FIG. 2A, the description is omitted.

In the above manner, an image can be projected to the display region on the left eye side.

### Structure Example 3

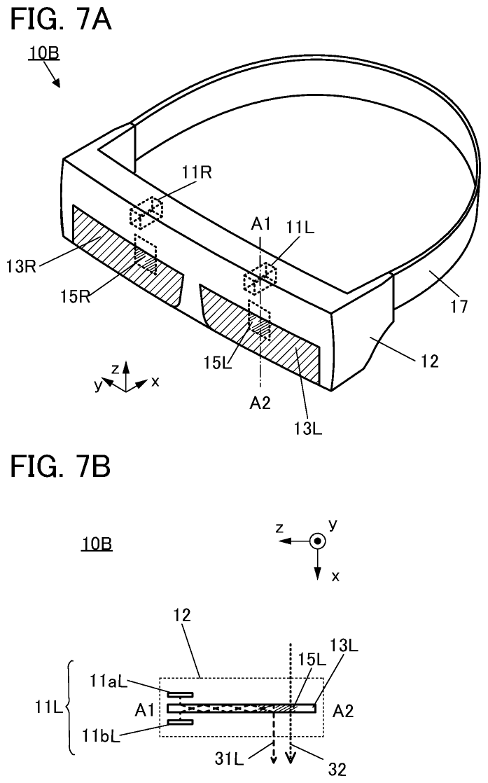

FIG. 1A to FIG. 6B illustrate examples where the display apparatus 11R is placed on the right side of the optical element 13R (on the outer corner side of the right eye) and the display apparatus 11L is placed on the left side of the optical element 13L (on the outer corner side of the left eye); however, the placement of the display apparatus 11R and the display apparatus 11L is not limited thereto. For example, the display apparatus 11R and the display apparatus 11L may be placed above the optical element 13R and the optical element 13L, respectively. Here, an electronic device in which the display apparatus 11R and the display apparatus 11L are placed above the optical element 13R and the optical element 13L, respectively, is described with reference to FIG. 7.

FIG. 7A is a perspective view schematically illustrating a structure example of an electronic device 10B. FIG. 7B is a schematic cross-sectional view illustrating a portion denoted by a dashed-dotted line A1-A2 in FIG. 7A seen from the right side of the user. Note that for clarity of the drawing, FIG. 7B illustrates only components of the electronic device 10B on the left eye side. In FIG. 7B, to make the following description easy, the schematic cross-sectional view is rotated by 90° in the left direction (rotated by 900 with respect to the y-axis).

The electronic device 10B illustrated in FIG. 7A and FIG. 7B is different from the electronic device 10 illustrated in FIG. 1A and the like in that the display apparatus 11R and the display apparatus 11L are placed above the optical element 13R and the optical element 13L, respectively. As illustrated in FIG. 7B, the display apparatus 11aL includes a region overlapping with the display apparatus 11bL with the optical element 13L therebetween. Similarly, the display apparatus 11aR includes a region overlapping with the display apparatus 11bR with the optical element 13R therebetween.

When FIG. 7B and FIG. 1B are compared, the placement of the components included in the electronic device 10B seen from the y-axis direction and the placement of the components included in the electronic device 10 seen from the z-axis direction are equal to each other. That is, the placement of the components included in the electronic device 10B seen from the side of the user is equal to the placement of the components included in the electronic device 10 or the electronic device TOA seen from above the user. Thus, for the details of the structure example of the electronic device 10B, the description made with reference to FIG. 2 to FIG. 6 can be referred to. Specifically, when the z-axis shown in FIG. 1B is regarded as the y-axis shown in FIG. 7B and the y-axis direction shown in FIG. 1B is regarded as the opposite direction of the z-axis direction shown in FIG. 7B, the description made with reference to FIG. 2 to FIG. 6 can be referred to for the details of the structure example of the electronic device 10B.

The electronic device 10B includes a band-like fixing member 17 instead of the pair of wearing portions 14 included in the electronic device 10 illustrated in FIG. 1A. Note that the electronic device 10B may include the pair of wearing portions 14 instead of the band-like fixing member 17. The electronic device 10 may include the band-like fixing member 17 instead of the pair of wearing portions 14.

Although FIG. 7A and the like illustrate examples where the display apparatus 11R and the display apparatus 11L are placed above the optical element 13R and the optical element 13L, respectively, the present invention is not limited thereto. The display apparatus 11R and the display apparatus 11L may be placed below the optical element 13R and the optical element 13L, respectively. Alternatively, one of the display apparatus 11R and the display apparatus 11L may be provided above the optical element, and the other of the display apparatus 11R and the display apparatus 11L may be provided below the optical element.

### Structure Example 4

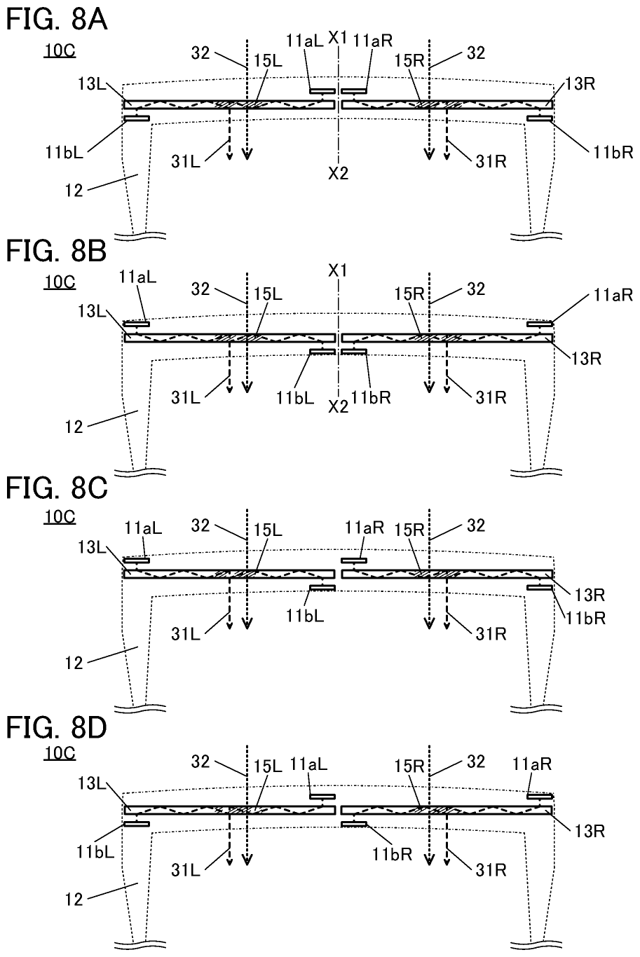

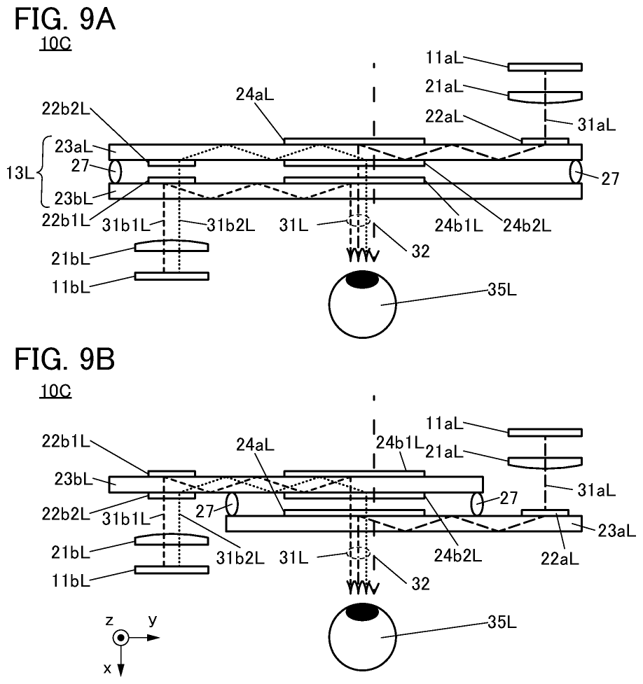

FIG. 1A to FIG. 6B illustrate examples where the display apparatus 11aR and the display apparatus 11bR are placed on the right side of the optical element 13R (on the outer corner side of the right eye) and the display apparatus 11aL and the display apparatus 11bL are placed on the left side of the optical element 13L (on the outer corner side of the left eye); however, the placement of the display apparatus 11aR, the display apparatus 11bR, the display apparatus 11aL, and the display apparatus 11bL is not limited thereto. For example, one of the display apparatus 11aR and the display apparatus 11bR may be placed on the right side of the optical element 13R (on the outer corner side of the right eye), the other of the display apparatus 11aR and the display apparatus 11bR may be placed on the left side of the optical element 13R (on the inner corner side of the right eye), one of the display apparatus 11aL and the display apparatus 11bL may be placed on the left side of the optical element 13L (on the outer corner side of the left eye), and the other of the display apparatus 11aL and the display apparatus 11bL may be placed on the right side of the optical element 13L (on the inner corner side of the left eye). In this case, the display apparatus 11aR does not overlap with the display apparatus 11bR with the optical element 13R therebetween. Similarly, the display apparatus 11aL does not overlap with the display apparatus 11bL with the optical element 13L therebetween. Here, an electronic device that is different from the electronic device 10 in placement of at least one of the display apparatus 11aR, the display apparatus 11bR, the display apparatus 11aL, and the display apparatus 11bL is described with reference to FIG. 8A to FIG. 9B.

### Structure Example 4-1

FIG. 8A is a schematic top view of an electronic device 10C seen from above the user. The electronic device 10C illustrated in FIG. 8A is different from the electronic device 10 illustrated in FIG. 1B in that the display apparatus 11aR is placed on the left side of the optical element 13R (on the inner corner side of the right eye) and the display apparatus 11aL is placed on the right side of the optical element 13L (on the inner corner side of the left eye).

The structure of the electronic device 10C illustrated in FIG. 8A on the left eye side and the structure on the right eye side are positioned line-symmetrically with the dashed-dotted line X1-X2 (the center line that divides the drawing in the lateral direction) shown in FIG. 8A as the symmetrical axis.

Next, the details of the structure of the electronic device 10C and the details of the method for projecting an image to the display region are described with reference to FIG. 9A and FIG. 9B.

FIG. 9A is a cross-sectional view illustrating an example of the structure of the electronic device 10C on the left eye side. The electronic device 10C illustrated in FIG. 9A is different from the electronic device 10 illustrated in FIG. 2A in that the display apparatus 11aL is placed on the right side of the optical element 13L (on the inner corner side of the left eye).

Since the paths of the light 31aL, the light 31b1L, and the light 31b2L are similar to those described with reference to FIG. 2A, the description is omitted. The types (transmissive type and reflective type) of the three input portion diffraction elements and the three output portion diffraction elements illustrated in FIG. 9A are similar to those described with reference to FIG. 2A.

In the above manner, an image can be projected to the display region on the left eye side.

FIG. 9A illustrates a structure where the light guide plate 23aL is placed between the display apparatus 11aL and the light guide plate 23bL, and the light guide plate 23bL is placed between the display apparatus 11bL and the light guide plate 23aL, one embodiment of the present invention is not limited thereto. For example, the light guide plate 23aL may be provided between the display apparatus 11bL and the light guide plate 23bL, and the light guide plate 23bL may be placed between the display apparatus 11aL and the light guide plate 23aL.

FIG. 9B is a cross-sectional view illustrating another example of the structure of the electronic device 10C on the left eye side. The electronic device 10C illustrated in FIG. 9B is different from the electronic device 10C illustrated in FIG. 9A in that the light guide plate 23aL is placed between the display apparatus 11bL and the light guide plate 23bL and the light guide plate 23bL is placed between the display apparatus 11aL and the light guide plate 23aL.

Since the paths of the light 31aL, the light 31b1L, and the light 31b2L are similar to those described with reference to FIG. 2B, the description is omitted. The types (transmissive type and reflective type) of the three input portion diffraction elements and the three output portion diffraction elements illustrated in FIG. 9B are similar to those described with reference to FIG. 2B.

In the above manner, an image can be projected to the display region on the left eye side.

With the structure illustrated in FIG. 9B, an interval between the display apparatus 11aL and the display apparatus 11bL in the x-axis direction can be short. Accordingly, the size or thickness of the electronic device 10C can be reduced.

As described above, the structure of the electronic device 10C illustrated in FIG. 8A on the left eye side and the structure on the right eye side are positioned line-symmetrically with the dashed-dotted line X1-X2 (the center line that divides the drawing in the lateral direction) shown in FIG. 8A as the symmetrical axis. That is, the structure of the electronic device 10C illustrated in FIG. 8A on the right eye side is the same as the structure of the electronic device 10C on the left eye side which is inverted with the dashed-dotted line X1-X2 shown in FIG. 8A as the symmetrical axis. Thus, for the structure on the right eye side and the method for projecting an image to the display region on the right eye side, the description of the structure on the left eye side and the method for projecting an image to the display region on the left eye side can be referred to.

### Structure Example 4-2

FIG. 8B is a schematic top view of the electronic device 10C seen from above the user. The electronic device 10C illustrated in FIG. 8B is different from the electronic device 10 illustrated in FIG. 1B in that the display apparatus 11bR is placed on the left side of the optical element 13R (on the inner corner side of the right eye) and the display apparatus 11bL is placed on the right side of the optical element 13L (on the inner corner side of the left eye).

The structure of the electronic device 10C illustrated in FIG. 8B on the left eye side and the structure on the right eye side are positioned line-symmetrically with the dashed-dotted line X1-X2 (the center line that divides the drawing in the lateral direction) shown in FIG. 8B as the symmetrical axis.

Note that the structure of the electronic device 10C illustrated in FIG. 8B on the right eye side is equal to the structure of the electronic device 10C illustrated in FIG. 8A on the left eye side, and the structure of the electronic device 10C illustrated in FIG. 8B on the left eye side is equal to the structure of the electronic device 10C illustrated in FIG. 8A on the right eye side. Thus, for the details of the structure of the electronic device 10C illustrated in FIG. 8B and the details of the method for projecting an image to the display region, the description made with reference to FIG. 9A and FIG. 9B can be referred to.

### Structural Example 4-3

FIG. 8C is a schematic top view of the electronic device 10C seen from above the user. The electronic device 10C illustrated in FIG. 8C is different from the electronic device 10 illustrated in FIG. 1B in that the display apparatus 11aR is placed on the left side of the optical element 13R (on the inner corner side of the right eye) and the display apparatus 11bL is placed on the right side of the optical element 13L (on the inner corner side of the left eye).

The structure of the electronic device 10C illustrated in FIG. 8C on the left eye side and the structure on the right eye side are the same. Thus, components on the left eye side and components on the right eye side can be fabricated in common. Accordingly, reduction in manufacturing cost can be achieved.

Note that the structure of the electronic device 10C illustrated in FIG. 8C on the left eye side and the structure on the right eye side are equal to the structure of the electronic device 10C illustrated in FIG. 8A on the right eye side. Thus, for the details of the structure of the electronic device 10C illustrated in FIG. 8C and the details of the method for projecting an image to the display region, the description made with reference to FIG. 9A and FIG. 9B can be referred to.

### Structural Example 4-4

FIG. 8D is a schematic top view of the electronic device 10C seen from above the user. The electronic device 10C illustrated in FIG. 8D is different from the electronic device 10 illustrated in FIG. 1B in that the display apparatus 11bR is placed on the left side of the optical element 13R (on the inner corner side of the right eye), and the display apparatus 11aL is placed on the right side of the optical element 13L (on the inner corner side of the left eye).

The structure of the electronic device 10C illustrated in FIG. 8D on the left eye side and the structure on the right eye side are the same. Thus, components on the left eye side and components on the right eye side can be fabricated in common. Accordingly, reduction in manufacturing cost can be achieved.

Note that the structure of the electronic device 10C illustrated in FIG. 8D on the left eye side and the structure on the right eye side are equal to the structure of the electronic device 10C illustrated in FIG. 8A on the left eye side. Thus, for the details of the structure of the electronic device 10C illustrated in FIG. 8D and the details of the method for projecting an image to the display region, the description made with reference to FIG. 9A and FIG. 9B can be referred to.

### Structure Example 5

In one embodiment of the present invention, the structures illustrated in FIG. 1A to FIG. 9B may be combined with each other. For example, a structure may be employed where the levels of the display apparatus 11aR and the display apparatus 11aL are different from the level of the display region and the levels of the display apparatus 11bR and the display apparatus 11bL are the same as the level of the display region. In this case, the display apparatus 11aR does not overlap with the display apparatus 11bR with the optical element 13R therebetween. Similarly, the display apparatus 11aL does not overlap with the display apparatus 11bL with the optical element 13L therebetween.

FIG. 10A is a perspective view illustrating an example of a structure of an electronic device 10D on the left eye side. The z-axis shown in FIG. 10A is parallel to the vertical direction (a direction from a foot to a head) of a user (not illustrated), the y-axis shown in FIG. 10A is parallel to the lateral direction of the user, and the x-axis shown in FIG. 10A is parallel to the back and forth direction of the user. Note that for clarity of the drawing, some components are omitted in the perspective view of FIG. 10A.

FIG. 10B and FIG. 10C are cross-sectional views illustrating an example of the structure of the electronic device 10D on the left eye side. FIG. 10B corresponds to the xz plane including the display apparatus 11aL and FIG. 10C corresponds to the xz plane including the display apparatus 11bL. FIG. 10D is a cross-sectional view illustrating the example of the structure of the electronic device 10D on the left eye side seen from above the user. FIG. 10D corresponds to the xy plane including the display region 15L (not illustrated).

The electronic device 10D illustrated in FIG. 10A to FIG. 10D is different from the electronic device 10 illustrated in FIG. 2A and the like in that, on the left eye side, the display apparatus 11aL is positioned above the display region 15L. In addition, the electronic device 10D illustrated in FIG. 10A to FIG. 10D is different from the electronic device 10B illustrated in FIG. 7A in that the display apparatus 11bL is placed at the same level as the display region 15L.

Since the path of the light 31aL is similar to that described with reference to FIG. 2A, the description is omitted. Since the paths of the light 31b1L and the light 31b2L are similar to those described with reference to FIG. 2B, the description is omitted.

In the above manner, an image can be projected to the display region on the left eye side.

With the above structure, a display apparatus or an electronic device with high luminance can be provided. A display apparatus or an electronic device with high resolution can be provided. A display apparatus or an electronic device with high definition can be provided. A display apparatus or an electronic device with a wide color gamut can be provided.

### Variation Example

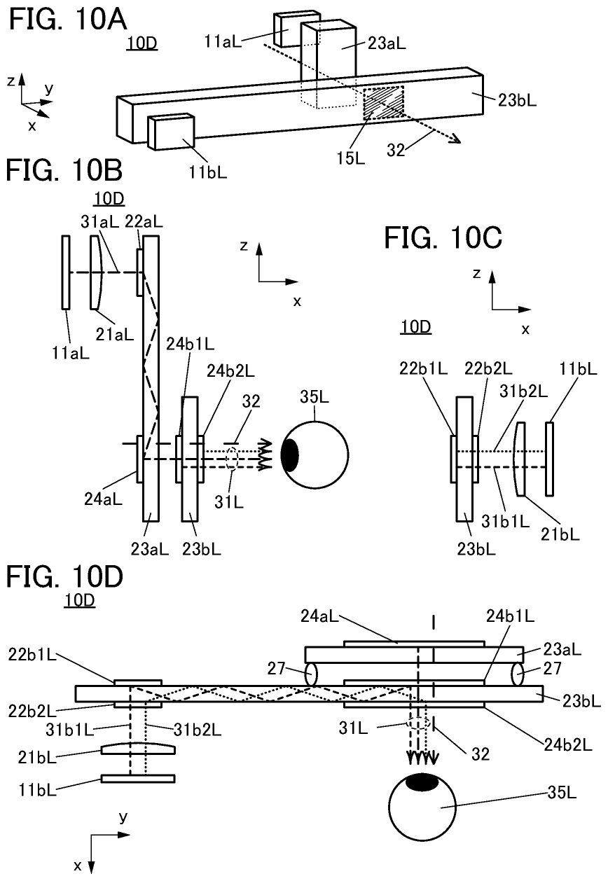

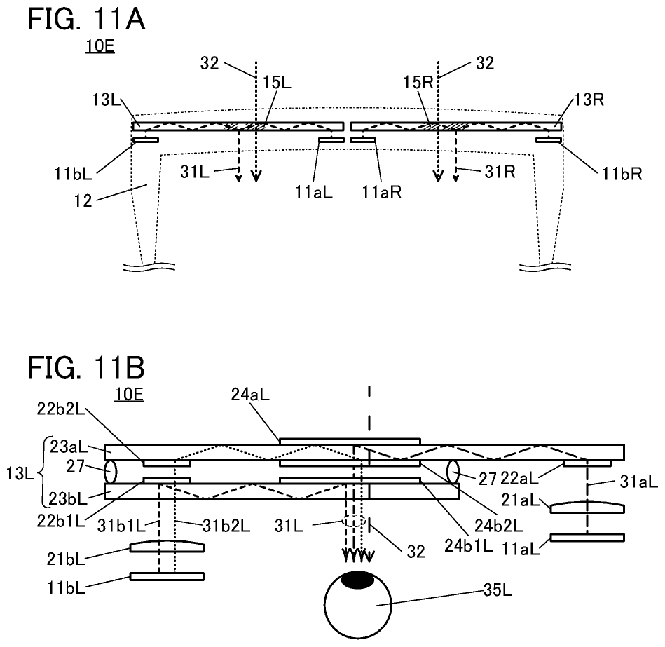

Although the structure where the display apparatus 11aL and the display apparatus 11bL are placed to face each other with the optical element 13L therebetween is described above in <Structure example 1>, the present invention is not limited thereto. The display apparatus 11aL and the display apparatus 11bL may be placed on the same side with respect to the optical element 13L. In this case, the display apparatus 11aL does not overlap with the display apparatus 11bL with the optical element 13L therebetween. When the display apparatus 11aL and the display apparatus 11bL are placed on the same side with respect to the optical element 13L, the bulk of the housing 12 (in particular, the width of the housing 12 in the x-axis direction) can be reduced. In addition, the optical element 13L may have a curved surface. Other examples of the electronic device of one embodiment of the present invention are described below with reference to FIG. 11A to FIG. 17C.

### Variation Example 1

FIG. 11A is a schematic top view of an electronic device TOE seen from above the user (not illustrated).

The electronic device 10E illustrated in FIG. 11A is different from the electronic device 10 illustrated in FIG. 1B in that, on the right eye side, the display apparatus 11aR and the display apparatus 11bR are placed closer to the user than the optical element 13R. Similarly, the electronic device 10E illustrated in FIG. 11A is different from the electronic device 10 illustrated in FIG. 1B in that, on the left eye side, the display apparatus 11aL and the display apparatus 11bL are placed closer to the user than the optical element 13L. Although FIG. 11A illustrates a structure where the distance between the display apparatus 11R and the optical element 13R is equal to the distance between the display apparatus 11bR and the optical element 13R, the present invention is not limited thereto. The distance between the display apparatus 11aR and the optical element 13R may be longer or shorter than the distance between the display apparatus 11bR and the optical element 13R. The same is applied to the relation of the distance between the display apparatus 11aL and the optical element 13L to the distance between the display apparatus 11bL and the optical element 13L.

FIG. 11B is a cross-sectional view illustrating an example of the structure of the electronic device 10E on the left eye side. In the electronic device 10E illustrated in FIG. 11B, on the left eye side, the display apparatus 11aL and the display apparatus 11bL are placed closer to the user than the optical element 13L. The light guide plate 23bL included in the optical element 13L is placed between the display apparatus 11aL and the display apparatus 11bL, and the light guide plate 23aL included in the optical element 13L.

Since the path of the light 31aL is similar to that described with reference to FIG. 3B, the description is omitted. Since the paths of the light 31b1L and the light 31b2L are similar to those described with reference to FIG. 2A, the description is omitted.

In the above manner, an image can be projected to the display region on the left eye side.

FIG. 11A and FIG. 11B illustrate the example where the display apparatus 11aR and the display apparatus 11bR are placed closer to the user than the optical element 13R and the display apparatus 11aL and the display apparatus 11bL are placed closer to the user than the optical element 13L; however, the display apparatus 11aR and the display apparatus 11bR may be placed on the side facing the user with the optical element 13R therebetween, and the display apparatus 11aL and the display apparatus 11bL may be placed on the side facing the user with the optical element 13L therebetween.

The electronic device 10E illustrated in FIG. 12A is different from the electronic device 10 illustrated in FIG. 1B in that, on the right eye side, the display apparatus 11aR and the display apparatus 11bR are placed on the side facing the user with the optical element 13R therebetween. Similarly, the electronic device 10E illustrated in FIG. 12A is different from the electronic device illustrated in FIG. 1B in that, on the left eye side, the display apparatus 11aL and the display apparatus 11bL are placed on the side facing the user with the optical element 13L therebetween. Although FIG. 12A illustrates a structure where the distance between the display apparatus 11aR and the optical element 13R is equal to the distance between the display apparatus 11bR and the optical element 13R, the present invention is not limited thereto. The distance between the display apparatus 11aR and the optical element 13R may be longer or shorter than the distance between the display apparatus 11bR and the optical element 13R. The same is applied to the relation of the distance between the display apparatus 11aL and the optical element 13L to the distance between the display apparatus 11bL and the optical element 13L.

FIG. 12B is a cross-sectional view illustrating an example of the structure of the electronic device 10E illustrated in FIG. 12A on the left eye side. In the electronic device 10E illustrated in FIG. 12B, on the left eye side, the display apparatus 11aL and the display apparatus 11bL are placed on the side facing the user with the optical element 13L therebetween. In addition, the light guide plate 23bL included in the optical element 13L is placed between the display apparatus 11aL and the display apparatus 11bL, and the light guide plate 23aL included in the optical element 13L.

Since the path of the light 31aL is similar to that described with reference to FIG. 2A, the description is omitted. Since the paths of the light 31b1L and the light 31b2L are similar to those described with reference to FIG. 3B, the description is omitted.

In the above manner, an image can be projected to the display region on the left eye side.

The structures illustrated in FIG. 11A to FIG. 12B are described on the assumption that the display apparatus 11aL and the display apparatus 11bL are positioned at the same or substantially the same level as the display region when seen from the side of the user; however, the level of one or both of the display apparatus 11aL and the display apparatus 11bL may be different from the level of the display region.

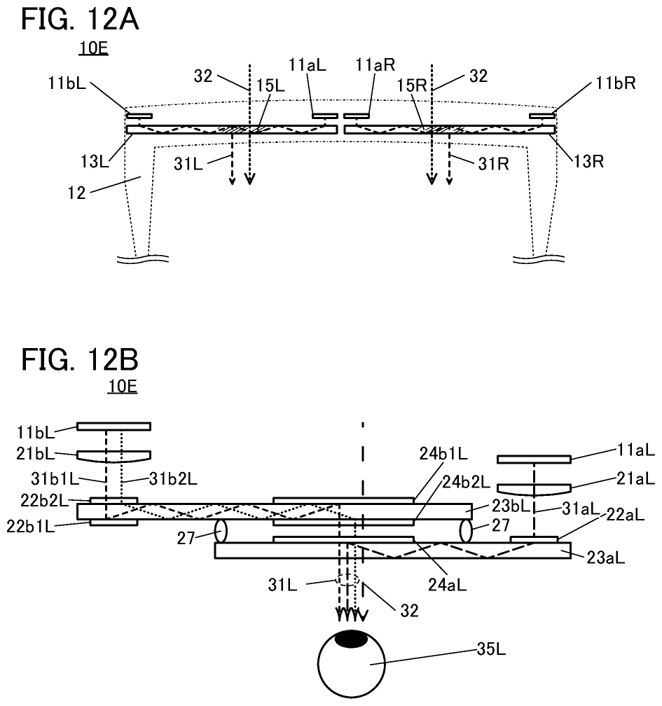

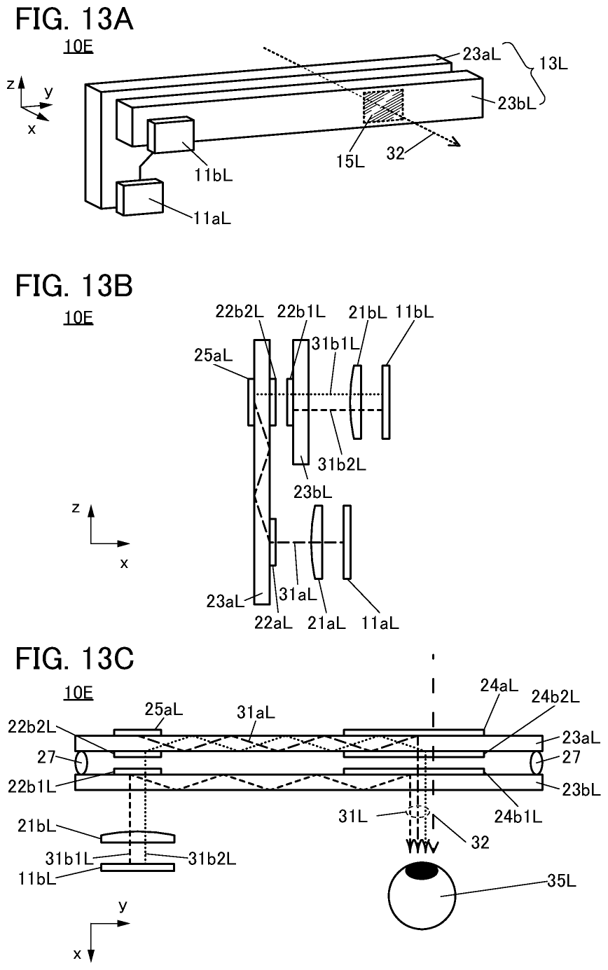

FIG. 13A is a perspective view illustrating another example of the structure of the electronic device 10E on the left eye side. The z-axis shown in FIG. 13A is parallel to the vertical direction (a direction from a foot to a head) of a user (not illustrated), the y-axis shown in FIG. 13A is parallel to the lateral direction of the user, and the x-axis shown in FIG. 13A is parallel to the back and forth direction of the user. For clarity of the drawing, some components are omitted in the perspective view of FIG. 13A.

FIG. 13B is a cross-sectional view illustrating another example of the structure of the electronic device 10E on the left eye side seen from the left side of the user. FIG. 13B corresponds to the xz plane including the display apparatus 11aL and the display apparatus 11bL. FIG. 13C is a cross-sectional view illustrating the another example of the structure of the electronic device 10E seen from above the user. FIG. 13C corresponds to the xy plane including the display apparatus 11bL and the display region 15L (not illustrated).

The electronic device 10E illustrated in FIG. 13A to FIG. 13C is different from the electronic device 10A illustrated in FIG. 6A to FIG. 6C in that, on the left eye side, the display apparatus 11aL is placed closer to the user than the optical element 13L.

Here, the type of the diffraction element 25aL is a reflective type. Note that the types (transmissive type and reflective type) of the three input portion diffraction elements illustrated in FIG. 13B are similar to those described with reference to FIG. 6A. The types (transmissive type and reflective type) of the three output portion diffraction elements illustrated in FIG. 13C are similar to those described with reference to FIG. 6A.

The light 31aL emitted from the display apparatus 11aL is made to enter the light guide plate 23aL by the input portion diffraction element 22aL. Inside the light guide plate 23aL, the light 31aL is totally reflected by the end surface of the light guide plate 23aL repeatedly to travel in the z-axis direction, and then reaches the diffraction element 25aL. The traveling direction of the light 31aL that reaches the diffraction element 25aL is changed into the y-axis direction by the diffraction element 25aL, and the light 31aL is totally reflected by the end surface of the light guide plate 23aL repeatedly, and then reaches the output portion diffraction element 24aL. The light 31aL that reaches the output portion diffraction element 24aL is delivered to the left eye 35L by the output portion diffraction element 24aL.

Since the paths of the light 31b1L and the light 31b2L are similar to those described with reference to FIG. 6B and FIG. 6C, the description is omitted.

In the above manner, an image can be projected to the display region on the left eye side.

The electronic device TOE has a structure where the display apparatus 11aL and the display apparatus 11bL are placed on the same side with respect to the optical element 13L. At this time, an image displayed on the display apparatus 11aL and an image displayed on the display apparatus 11bL may be the same. Accordingly, a full-color image can be generated by synthesizing the image displayed on the display apparatus 11aL and the image displayed on the display apparatus 11bL, and the full-color image can be projected to the display region 15L.

### Variation Example 2

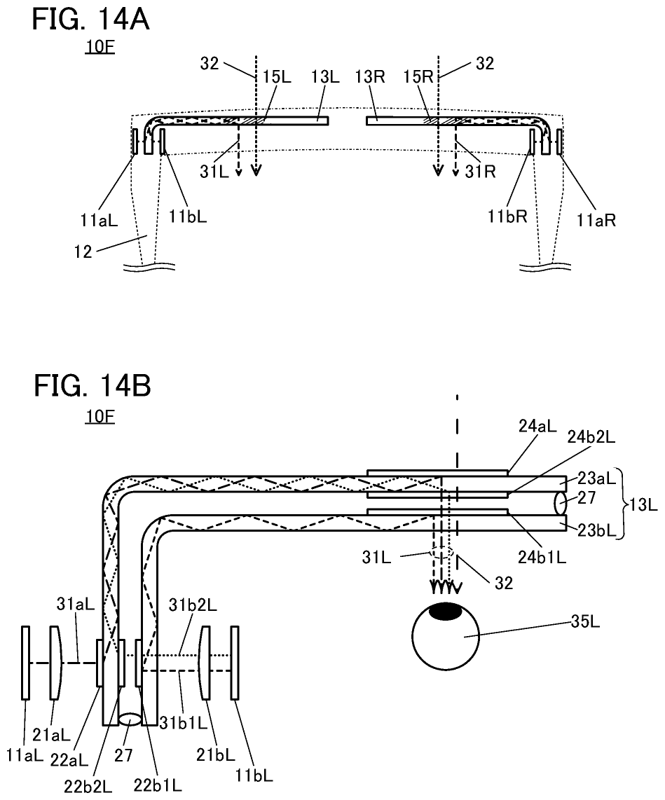

FIG. 14A is a schematic top view of an electronic device 10F seen from above the user. The electronic device 10F illustrated in FIG. 14A is different from the electronic device 10 illustrated in FIG. 1B in that the optical element 13R and the optical element 13L each have a curved surface.

FIG. 14B is a cross-sectional view illustrating an example of a structure of the electronic device 10F on the left eye side. The electronic device 10F illustrated in FIG. 14B is different from the electronic device 10 illustrated in FIG. 2A in that, on the left eye side, the light guide plate 23aL has a curved surface between the input portion diffraction element 22aL and the output portion diffraction element 24aL. In addition, the electronic device 10F illustrated in FIG. 14B is different from the electronic device 10 illustrated in FIG. 2A in that, on the left eye side, the light guide plate 23bL has a curved surface between the input portion diffraction element 22b1L and the output portion diffraction element 24b1L.

Since the paths of the light 31aL, the light 31b1L, and the light 31b2L are similar to those described with reference to FIG. 2A, the description is omitted.

The curved surface of the light guide plate 23aL is preferably designed such that the light 31aL being emitted from the display apparatus 11aL and entering the light guide plate 23aL and the light 31b2L being emitted from the display apparatus 11bL and entering the light guide plate 23aL can reach the output portion diffraction element 24aL and the output portion diffraction element 24b2L, respectively. It is also preferable to provide a low-refractive-index layer or a reflective film for the light guide plate 23aL so that the light 31aL and the light 31b2L entering the light guide 23aL is totally reflected at the curved surface of the light guide plate 23aL and in the vicinity thereof. Note that the same is applied to the curved surface of the light guide plate 23bL.

In the above manner, an image can be projected to the display region on the left eye side.

Note that the structure of the electronic device 10F is not limited to the structure illustrated in FIG. 14A and FIG. 14B. Other examples of the structure of the electronic device 10F are described below.

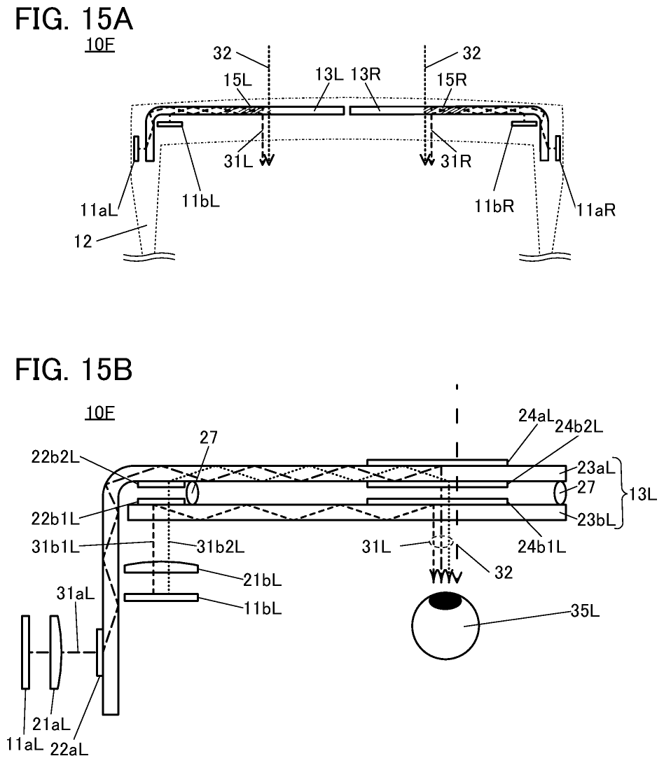

FIG. 15A is a schematic top view of the electronic device 10F seen from above the user, which is different from FIG. 14A. The electronic device 10F illustrated in FIG. 15A is different from the electronic device 10F illustrated in FIG. 14A in placement of the display apparatus 11bR and the display apparatus 11bL. Specifically, the display apparatus 11bR illustrated in FIG. 15A is placed closer to the display region 15R than the curved surface of the optical element 13R. Similarly, the display apparatus 11bL illustrated in FIG. 15A is placed closer to the display region 15L than the curved surface than the optical element 13L.

FIG. 15B is a cross-sectional view illustrating an example of the electronic device 10F illustrated in FIG. 15A on the left eye side. The electronic device 10F illustrated in FIG. 15B is different from the electronic device 10F illustrated in FIG. 14B in that the light guide plate 23bL does not have a curved surface.

Since the paths of the light 31aL, the light 31b1L, and the light 31b2L are similar to those described with reference to FIG. 2A, the description is omitted.

In the above manner, an image can be projected to the display region on the left eye side.

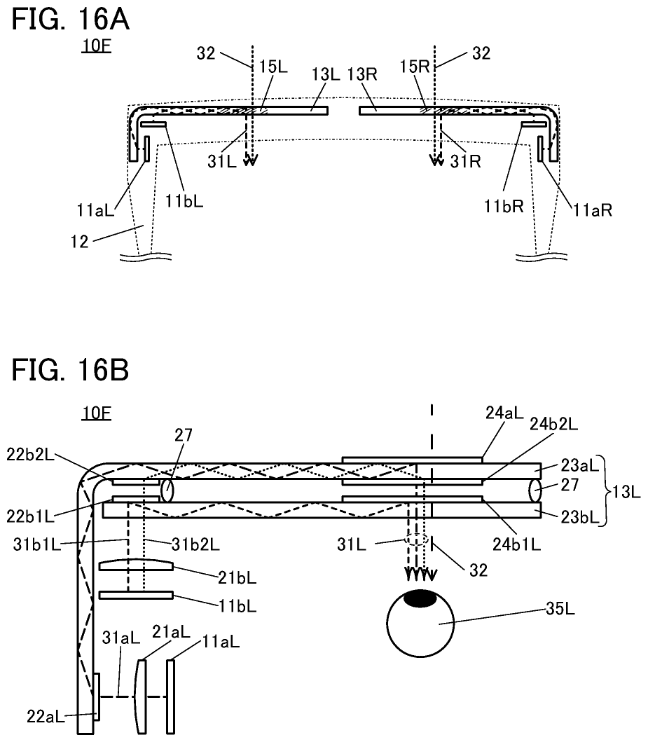

FIG. 16A is a schematic top view of the electronic device 10F seen from above the user, which is different from FIG. 14A and FIG. 15A. The electronic device 10F illustrated in FIG. 16A is different from the electronic device 10F illustrated in FIG. 14A and FIG. 15A in placement of the display apparatus 11bR and the display apparatus 11bL. Specifically, the electronic device 10F illustrated in FIG. 16A is different from the electronic device 10F illustrated in FIG. 15A in that the display apparatus 11aR is placed closer to the user than the optical element 13R. Similarly, the electronic device 10F illustrated in FIG. 16A is different from the electronic device 10F illustrated in FIG. 15A in that the display apparatus 11aL is placed closer to the user than the optical element 13L.

FIG. 16B is a cross-sectional view illustrating an example of the electronic device 10F illustrated in FIG. 16A on the left eye side. The electronic device 10F illustrated in FIG. 16B is different from the electronic device 10F illustrated in FIG. 15B in that the display apparatus 11aL is placed closer to the user than the optical element 13L.

Since the path of the light 31aL is similar to that described with reference to FIG. 3A, the description is omitted. Since the paths of the light 31b1L and the light 31b2L are similar to those described with reference to FIG. 2A, the description is omitted.

In the above manner, an image can be projected to the display region on the left eye side.

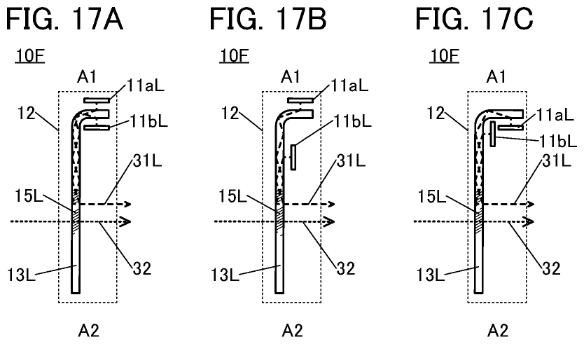

FIG. 17A to FIG. 17C are cross-sectional views illustrating other examples of the structure of the electronic device 10F on the left eye side. As illustrated in FIG. 17A to FIG. 17C, the display apparatus 11L included in the electronic device 10F may be placed above the optical element 13L. Similarly, the display apparatus 11R included in the electronic device 10F illustrated in FIG. 17A to FIG. 17C may be placed above the optical element 13R.

The electronic device 10F illustrated in FIG. 17A is different from the electronic device 10F illustrated in FIG. 14A in that, on the left eye side, the display apparatus 11aL and the display apparatus 11bL are placed above the display region 15L and the curved surface of the optical element 13L is placed above the display region 15L.

The electronic device 10F illustrated in FIG. 17B is different from the electronic device 10F illustrated in FIG. 15A in that, on the left eye side, the display apparatus 11aL and the display apparatus 11bL are placed above the display region 15L and the curved surface of the optical element 13L is placed above the display region 15L.

The electronic device 10F illustrated in FIG. 17C is different from the electronic device 10F illustrated in FIG. 16A in that, on the left eye side, the display apparatus 11aL and the display apparatus 11bL are placed above the display region 15L and the curved surface of the optical element 13L is placed above the display region 15L.

### <<Light-Emitting Element>>

The display apparatus included in the electronic device of one embodiment of the present invention includes a light-emitting element. The light-emitting element functions as a display element (also referred to as a display device).

Alight-emitting diode is preferably used as the light-emitting element. It is particularly preferable to use a micro LED. A display apparatus using a micro LED will be described in detail in Embodiment 2.

As the light-emitting element, an EL element (also referred to as an EL device) such as an OLED (Organic Light Emitting Diode) or a QLED (Quantum-dot Light Emitting Diode) can also be used. Examples of the light-emitting substance (also referred to as a light-emitting material) contained in the EL element include a substance that emits fluorescent light (a fluorescent material), a substance that emits phosphorescent light (a phosphorescent material), an inorganic compound (e.g., a compound semiconductor or a quantum dot material), and a substance that exhibits thermally activated delayed fluorescence (a thermally activated delayed fluorescence (TADF) material). Note that as a TADF material, a material that is in a thermal equilibrium state between a singlet excited state and a triplet excited state may be used. Since such a TADF material enables a short emission lifetime (excitation lifetime), an efficiency decrease of the light-emitting device in a high-luminance region can be inhibited.

### <<Pixel Layout>>

Next, a pixel layout is described. There is no particular limitation on the arrangement of subpixels, and a variety of methods can be employed.

Examples of a top surface shape of the subpixel include polygons such as a triangle, a tetragon (including a rectangle, a trapezoid, or the like), and a pentagon; polygons with rounded corners; polygons with at least one rounded corner; an ellipse; and a circle. Here, the top surface shape of the subpixel corresponds to the top surface shape of a light-emitting region of the light-emitting device.

This section describes structure examples of the electronic device 10 on the left eye side. Since the structure of the electronic device 10 on the right eye side is similar to the structure on the left eye side, the description is omitted.

The display apparatus 11aL includes a pixel 90a, and the display apparatus 11bL includes a pixel 90b. Here, the area of the pixel 90a and the area of the pixel 90b are preferably the same or substantially the same. Accordingly, a full-color image can be generated by synthesizing an image output by the display apparatus 11aL and an image output by the display apparatus 11bL. Then, the full-color image can be projected to the display region 15L.

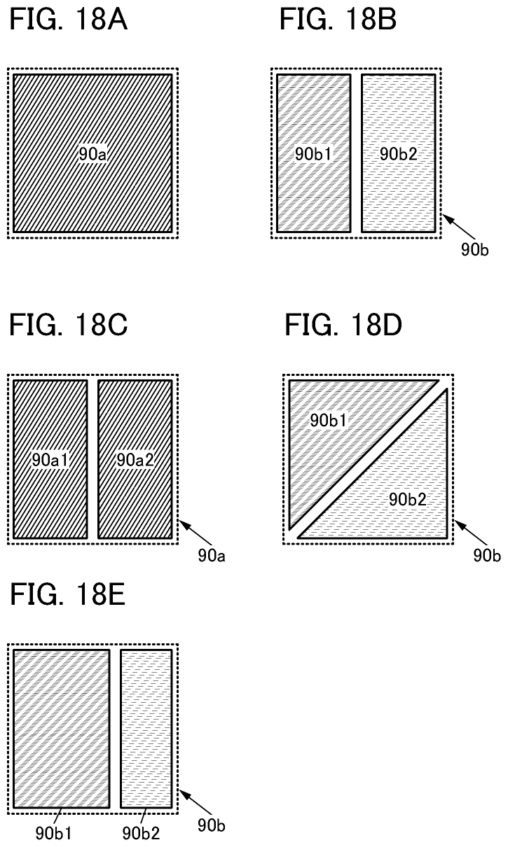

The pixel 90a illustrated in FIG. 18A is composed of one pixel (subpixel). Although the top surface shape of the pixel 90a is a square in FIG. 18A, the top surface shape may be a rough quadrangle or rough hexagon with rounded corners, a circle, or the like.

The pixel 90b illustrated in FIG. 18B is composed of two subpixels: a subpixel 90b1 and a subpixel 90b2. Although the top surface shapes of the subpixel 90b1 and the subpixel 90b2 are rectangles in FIG. 18B, the top surface shapes may be rough quadrangles or rough hexagons with rounded corners, ellipses, or the like.

As described above, the pixel 90a and the pixel 90b preferably have the same or substantially the same area. In this case, the area of the pixel 90a is the same or substantially the same as the sum of the area of the subpixel 90b1 and the area of the subpixel 90b2. Note that the sum of the area of the subpixel 90b1 and the area of the subpixel 90b2 is smaller than the area of the pixel 90a in some cases. Thus, it can be said that the pixel 90a has a larger area than the subpixel 90b1. In addition, it can be said that the pixel 90a has a larger area than the subpixel 90b2.

Note that there is no limitation on the top surface shape of the subpixel, the area of the subpixel, and the like as long as the pixel 90a and the pixel 90b have the same or substantially the same area.

For example, as illustrated in FIG. 18C, the pixel 90a may be composed of two subpixels: a subpixel 90a1 and a subpixel 90a2. Here, the subpixel 90a1 and the subpixel 90a2 preferably emit light of the same color. This structure can make the area of the pixel 90a and the area of the pixel 90b the same or substantially the same. Furthermore, the same mask can be used in formation of the display apparatus 11aL and the display apparatus 11bL, whereby the fabrication cost of the display apparatuses can be reduced.

As illustrated in FIG. 18D, for example, the top surface shapes of the subpixel 90b1 and the subpixel 90b2 may be triangles. Alternatively, the top surface shapes of the subpixel 90b1 and the subpixel 90b2 may be rough triangles with rounded corners.

As illustrated in FIG. 18E, for example, the area of the subpixel 90b1 may be larger than the area of the subpixel 90b2. For example, a light-emitting element with low emission efficiency or low luminance is provided in the subpixel 90b1 with a large area and a light-emitting element with high emission efficiency or high luminance is provided in the subpixel 90b2 with a small area, so that a display apparatus with high display quality can be fabricated.

Here, the pixel 90a includes the first light-emitting element, the subpixel 90b1 includes the second light-emitting element, and the subpixel 90b2 includes the third light-emitting element.

For example, it is preferable that the first light-emitting element be an element emitting red light, the second light-emitting element be an element emitting light of one of green and blue, and the third light-emitting element be an element emitting light of the other of green and blue.

In the above, the first light-emitting element to the third light-emitting element are each preferably a micro LED including an inorganic compound as a light-emitting material. A micro LED emitting red light has lower emission efficiency than a micro LED emitting green light and a micro LED emitting blue light. Thus, the use of a micro LED emitting red light as the pixel 90a with a large area can increase the luminance of a synthesized image. Instead of the micro LED emitting red light, a micro LED emitting blue light and including a color conversion layer that converts blue into red may be used. Meanwhile, a micro LED emitting green light and a micro LED emitting blue light can be monolithically formed at low cost by using a technique of forming gallium nitride over a silicon substrate. Thus, a micro LED emitting green light and a micro LED emitting blue light can be formed over the same substrate, whereby high resolution can be achieved.

In the above, the first light-emitting element may be a micro LED including an organic compound as a light-emitting material, and the second light-emitting element and the third light-emitting element may each be a micro LED including an inorganic compound as a light-emitting material.

For another example, it is preferable that the first light-emitting element be an element emitting blue light, the second light-emitting element be an element emitting light of one of red and green, and the third light-emitting element be an element emitting light of the other of red and green.

In the above, the first light-emitting element to the third light-emitting element are each preferably a micro LED including an organic compound as a light-emitting material. In the case where a fluorescent material is used for a micro LED emitting blue light and phosphorescent materials are used for a micro LED emitting red light and a micro LED emitting green light, the micro LED emitting blue light has lower emission efficiency than the micro LED emitting red light and the micro LED emitting green light. Thus, the use of the micro LED emitting blue light as the pixel 90a with a large area can increase the luminance of a synthesized image. As described later, in the case where an MML structure is employed for the display apparatus, the number of fabrication steps can be smaller than that in the case where light-emitting elements of three colors are formed over the same substrate.

This embodiment can be combined with the other embodiments as appropriate. In this specification, in the case where a plurality of structure examples are shown in one embodiment, the structure examples can be combined as appropriate.

### Embodiment 2

In this embodiment, display apparatuses of one embodiment of the present invention are described with reference to FIG. 19 to FIG. 29.

A display apparatus of this embodiment includes a plurality of light-emitting diodes that are display devices and a plurality of transistors for driving the display devices. The plurality of light-emitting diodes are provided in a matrix. Each of the plurality of transistors is electrically connected to at least one of the plurality of light-emitting diodes.

The display apparatus of this embodiment is formed by attaching the plurality of transistors and the plurality of light-emitting diodes to each other, which are formed over different substrates.

In a method for fabricating the display apparatus of this embodiment, the plurality of light-emitting diodes and the plurality of transistors are attached to each other at a time; thus, even in the case of fabricating a display apparatus having a large number of pixels or a display apparatus with high resolution, the manufacturing time for the display apparatus can be shortened and manufacturing difficulty can be lowered, compared to a method in which light-emitting diodes are mounted on a circuit board one by one.

The display apparatus of this embodiment has a function of displaying an image or a video with the use of the light-emitting diode. In the case where a light-emitting diode, which is a self-luminous device, is used as a display device, a backlight is unnecessary and a polarizing plate does not have to be provided in the display apparatus. Thus, the display apparatus can have reduced power consumption and can be thin and lightweight. A display apparatus using a light-emitting diode as a display device can have high display quality because of its high luminance (e.g., higher than or equal to 5000 cd/m², preferably higher than or equal to 10000 cd/m²), high contrast, and wide viewing angle. Furthermore, with the use of an inorganic material as a light-emitting material, the lifetime of the display apparatus can be extended and the reliability can be increased.

In this embodiment, in particular, an example of using a micro LED as the light-emitting diode is described. Note that in this embodiment, a micro LED having a double heterojunction is described. Note that there is no particular limitation on the light-emitting diode, and for example, a micro LED having a quantum well junction or a nanocolumn LED may be used.

The area of a light-emitting region of the light-emitting diode is preferably less than or equal to 1 mm², further preferably less than or equal to 10000 μm², still further preferably less than or equal to 3000 μm², yet still further preferably less than or equal to 700 μm². The area of the region is preferably greater than or equal to 1 μm², further preferably greater than or equal to 10 μm², still further preferably greater than or equal to 100 μm². Note that in this specification and the like, a light-emitting diode in which the area of a light-emitting region is less than or equal to 10000 μm² is referred to as a micro LED or a micro light-emitting diode in some cases.

The display apparatus of this embodiment preferably includes a transistor including a channel formation region in a metal oxide layer (an OS transistor). An OS transistor has a low off-state current and thus can achieve low power consumption. Thus, a combination with a micro LED can achieve a display apparatus with significantly reduced power consumption. Furthermore, an OS transistor can be formed regardless of the substrate material, and thus a micro LED and the OS transistor can be formed monolithically. Accordingly, the manufacturing yield can be increased. In addition, the manufacturing cost can be reduced. Furthermore, an OS transistor has an extremely low off-state current, and thus can reduce color mixing and black blurring in display and can largely increase the display quality.

The display apparatus of this embodiment preferably includes a transistor including a channel formation region in a semiconductor substrate (e.g., a silicon substrate). This enables high-speed operation of the circuits.

The display apparatus of this embodiment preferably has a stacked-layer structure of a transistor including a channel formation region in a semiconductor substrate and an OS transistor. This enables high-speed operation of a circuit and extremely low power consumption. In this case, the display apparatus is preferably formed by attaching a transistor including a channel formation region in a semiconductor substrate to a micro LED and an OS transistor that are formed monolithically. Alternatively, the display apparatus is preferably formed by attaching a transistor including a channel formation region in a semiconductor substrate and an OS transistor that are formed monolithically to a micro LED. Alternatively, the display apparatus is preferably formed by attaching a transistor including a channel formation region in a semiconductor substrate and an OS transistor that are formed monolithically to a micro LED and an OS transistor that are formed monolithically.

For example, OS transistors may be used in a pixel circuit and a gate driver, and transistors including silicon in the channel formation regions (Si transistors) may be used in a source driver. Alternatively, for example, OS transistors may be used in the pixel circuit and Si transistors may be used in the source driver and the gate driver. One or both of a Si transistor and an OS transistor may be used as a transistor included in a variety of functional circuits such as an arithmetic circuit and a memory circuit.

### Structure Example 1 of Display Apparatus

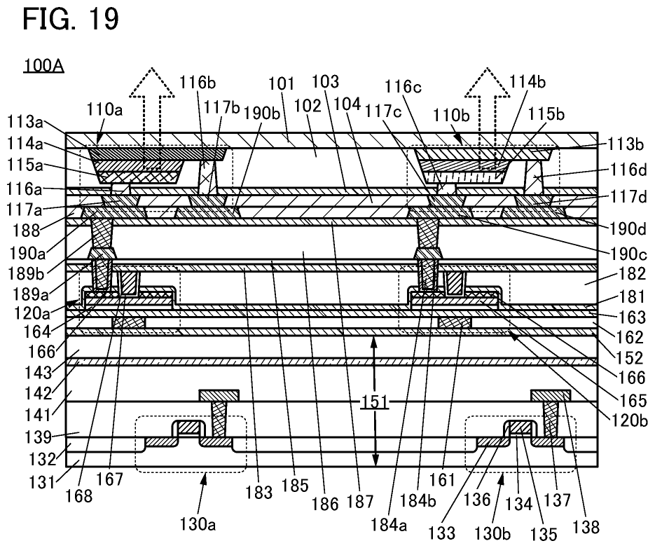

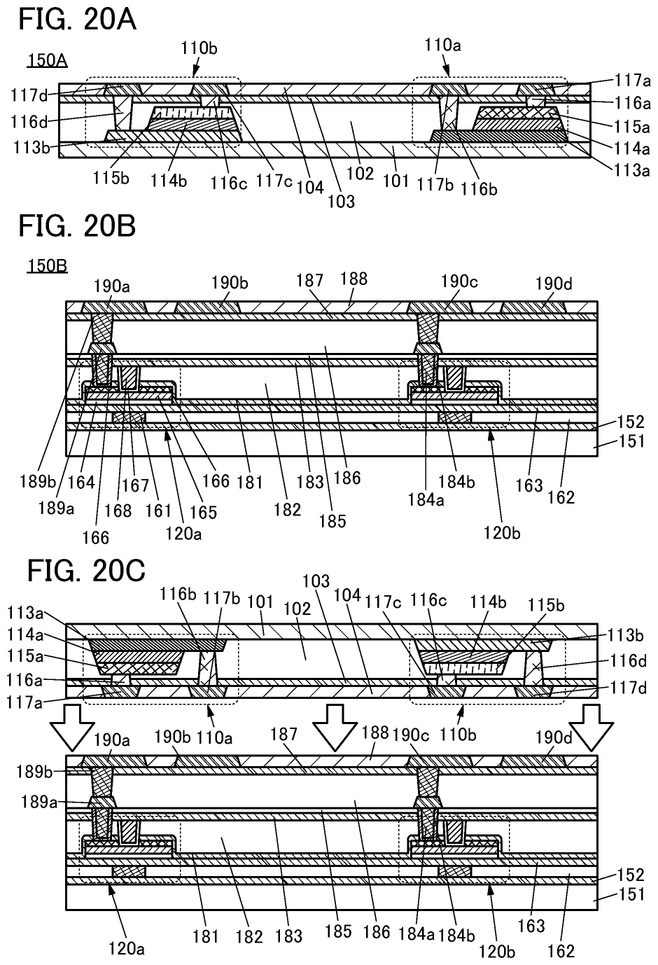

FIG. 19 shows a cross-sectional view of a display apparatus 100A. FIG. 20A to FIG. 20C show cross-sectional views illustrating a method for fabricating the display apparatus 100A.

The display apparatus 100A illustrated in FIG. 19 is formed by attaching an LED substrate 150A illustrated in FIG. 20A and a circuit board 150B illustrated in FIG. 20B to each other (see FIG. 20C).

The display apparatus 100A includes a stacked-layer structure of transistors including a channel formation region in a substrate 131 (a transistor 130a and a transistor 130b) and transistors including a channel formation region in a metal oxide layer (a transistor 120a and a transistor 120b).

The transistor 120a and the transistor 120b, and the transistor 130a and the transistor 130b can each be used as any one or more of a transistor included in a pixel circuit, a transistor included in a driver circuit (one or both of a gate driver and a source driver) for driving the pixel circuit, and a transistor included in a variety of functional circuits such as an arithmetic circuit and a memory circuit.

For example, the transistor including the channel formation region in the metal oxide layer can be used as the transistor included in the pixel circuit. The transistor including the channel formation region in the substrate 131 (e.g., single crystal silicon substrate) can be used as the transistor included in one or both of the gate driver and the source driver and the transistor included in a variety of functional circuits. This enables high-speed operation of the circuit and extremely low power consumption.

With such a structure, not only the pixel circuit but also the driver circuit or the like can be formed directly under the light-emitting diode; thus, the display apparatus can be downsized as compared with the case where the driver circuit is provided outside a display portion. In addition, the display apparatus can have a narrow bezel (narrow non-display region).

It is preferable to use an OS transistor as at least one of the transistors included in the pixel circuit. An OS transistor has extremely higher field-effect mobility than a transistor containing amorphous silicon. In addition, an OS transistor has an extremely low leakage current between a source and a drain in an off state (hereinafter, also referred to as off-state current), and charge accumulated in a capacitor that is connected in series to the transistor can be held for a long period. Furthermore, power consumption of the display apparatus can be reduced with an OS transistor.

The off-state current value per micrometer of channel width of an OS transistor at room temperature can be lower than or equal to 1 aA (1×10⁻¹⁸ A), lower than or equal to 1 zA (1×10⁻² A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of the OS transistor is lower than that of the Si transistor by approximately ten orders of magnitude.

Note that the transistor including the channel formation region in the substrate 131 is not limited to being used as the transistor included in the driver circuit, and may be used as a transistor included in a CPU (Central Processing Unit), a GPU (Graphics Processing Unit), a memory circuit portion, or the like. In this embodiment and the like, a driver circuit, a CPU, a GPU, and a memory circuit portion are collectively referred to as a “functional circuit” in some cases.

For example, the CPU has a function of controlling operations of the GPU and the circuit provided in the layer 151, following the program stored in the memory circuit portion. The GPU has a function of performing arithmetic processing for generating image data. Furthermore, the GPU can perform a large number of matrix operations (product-sum operations) in parallel and thus, can perform arithmetic operation using a neural network at high speed, for example. The GPU has a function of correcting image data using correction data stored in the memory circuit portion, for example. For example, the GPU has a function of generating image data in which brightness, hue, and/or contrast, or the like is corrected.

Upconversion or downconversion of image data may be performed using the GPU. A super-definition circuit may be provided in the layer 151. The super-definition circuit has a function of determining a potential of any pixel included in the display region of the display apparatus 100A by a product-sum operation of weights and potentials of pixels in the periphery of the pixel. The super-definition circuit has a function of upconverting image data with a lower definition than that of the display region of the display apparatus 100A. The super-definition circuit has a function of downconverting image data with a higher definition than that of the display region of the display apparatus 100A.

Providing the super-definition circuit can reduce the load on the GPU. For example, the GPU performs processing up to 2K definition (or 4K definition) and the super-definition circuit performs upconversion to 4K definition (or 8K definition), whereby the load on the GPU can be reduced. Downconversion may be performed in a similar manner.

Note that the functional circuit included in the layer 151 does not necessarily include all of the circuits, and may include another structure. For example, a potential generating circuit that generates a plurality of different potentials, and/or a power management circuit that controls supply and stop of electrical power per circuit included in the display apparatus 100A may be provided.

The supply and stop of electrical power may be performed per circuit included in the CPU. For example, power consumption can be reduced by stopping supply of electrical power to a circuit, which is determined to be not used for a while, of the circuits included in the CPU, and restarting the supply of electrical power to the circuit as needed. Data necessary for restarting supply of electrical power may be stored in a memory circuit in the CPU, the memory circuit portion, or the like before stopping the circuit. By storing data necessary for recovery of the circuit, high-speed recovery of the circuit stopped can be performed. Note that supply of a clock signal may be stopped to stop the circuit operation.

As the functional circuit, a DSP (Digital Signal Processor) circuit, a sensor circuit, a communication circuit, an FPGA (Field Programmable Gate Array), a high-speed input/output (I/O) circuit, a luminance correction circuit, and/or a regulator may be included, for example.

An OS transistor may be used as some of the transistors included in a functional circuit included in the layer 151. In addition, some of the transistors included in the pixel circuit may be provided in the layer 151. Thus, the functional circuit may include a Si transistor and an OS transistor. In addition, the pixel circuit may include a Si transistor and an OS transistor.

FIG. 20A is a cross-sectional view of the LED substrate 150A.

The LED substrate 150A includes a substrate 101, a light-emitting diode 110a, a light-emitting diode 110b, an insulating layer 102, an insulating layer 103, and an insulating layer 104. Each of the insulating layer 102, the insulating layer 103, and the insulating layer 104 may have a single-layer structure or a stacked-layer structure.

The display apparatus 100A including the LED substrate 150A includes two light-emitting diodes (the light-emitting diode 110a and the light-emitting diode 110b). Thus, the display apparatus 100A corresponds to the display apparatus 11bR and the display apparatus 11bL that are described in Embodiment 1. The display apparatus 100A including one of the light-emitting diode 110a and the light-emitting diode 110b corresponds to the display apparatus 11aR and the display apparatus 11aL that are described in Embodiment 1.

The light-emitting diode 110a includes a semiconductor layer 113a, a light-emitting layer 114a, a semiconductor layer 115a, a conductive layer 116a, a conductive layer 116b, an electrode 117a, and an electrode 117b. The light-emitting diode 110b includes a semiconductor layer 113b, a light-emitting layer 114b, a semiconductor layer 115b, a conductive layer 116c, a conductive layer 116d, an electrode 117c, and an electrode 117d. Each of the layers included in the light-emitting diode may have a single-layer structure or a stacked-layer structure.

The semiconductor layer 113a is provided over the substrate 101, the light-emitting layer 114a is provided over the semiconductor layer 113a, and the semiconductor layer 115a is provided over the light-emitting layer 114a. The electrode 117a is electrically connected to the semiconductor layer 115a through the conductive layer 116a. The electrode 117b is electrically connected to the semiconductor layer 113a through the conductive layer 116b.

The semiconductor layer 113b is provided over the substrate 101, the light-emitting layer 114b is provided over the semiconductor layer 113b, and the semiconductor layer 115b is provided over the light-emitting layer 114b. The electrode 117c is electrically connected to the semiconductor layer 115b through the conductive layer 116c. The electrode 117d is electrically connected to the semiconductor layer 113b through the conductive layer 116d.

The insulating layer 102 is provided to cover the substrate 101, the semiconductor layer 113a, the semiconductor layer 113b, the light-emitting layer 114a, the light-emitting layer 114b, the semiconductor layer 115a, and the semiconductor layer 115b. The insulating layer 102 preferably has a planarization function. The insulating layer 103 is provided over the insulating layer 102. The conductive layer 116a, the conductive layer 116b, the conductive layer 116c, and the conductive layer 116d are provided so as to fill openings formed in the insulating layer 102 and the insulating layer 103. It is preferable that the top surfaces of the conductive layer 116a, the conductive layer 116b, the conductive layer 116c, and the conductive layer 116d be substantially level with the top surface of the insulating layer 103. The insulating layer 104 is provided over the conductive layer 116a, the conductive layer 116b, the conductive layer 116c, the conductive layer 116d, and the insulating layer 103. The electrode 117a, the electrode 117b, the electrode 117c, and the electrode 117d are provided to fill openings formed in the insulating layer 104. It is preferable that the top surfaces of the electrode 117a, the electrode 117b, the electrode 117c, and the electrode 117d be substantially level with the top surface of the insulating layer 104.

The display apparatus of this embodiment includes at least one structure where the top surface of the insulating layer is substantially level with the top surface of the conductive layer. An example of a method for fabricating the structure is a method in which an insulating layer is formed, an opening is provided in the insulating layer, and a conductive layer is formed so as to fill the opening, and then, planarization treatment is performed by a CMP (Chemichl Mechanical Polishing) method or the like. Thus, the top surface of the conductive layer can be level with the top surface of the insulating layer.

Note that in this specification and the like, the expression “A and B are level with or substantially level with each other” includes the case where A and B are level with each other and the case where a difference in level occurs between A and B owing to a manufacturing error when A and B are fabricated so that A and B are level with each other.

The insulating layer 102 is preferably formed using an inorganic insulating material such as silicon oxide, silicon oxynitride, silicon nitride oxide, silicon nitride, aluminum oxide, hafnium oxide, or titanium nitride.

Note that in this specification and the like, silicon oxynitride is a material that contains more oxygen than nitrogen in its composition. Moreover, silicon nitride oxide is a material that contains more nitrogen than oxygen in its composition.

As the insulating layer 103, it is possible to use a film through which one or both of hydrogen and oxygen are less likely to diffuse than through a silicon oxide film, such as an aluminum oxide film, a hafnium oxide film, and a silicon nitride film, for example. The insulating layer 103 preferably functions as a barrier layer that prevents diffusion of impurities from the LED substrate 150A into the circuit board 150B.

An oxide insulating film is preferably used for the insulating layer 104. The insulating layer 104 is a layer that is directly bonded to the insulating layer included in the circuit board 150B. The oxide insulating films are directly bonded to each other, whereby the bonding strength (attachment strength) can be increased.

Examples of materials that can be used for the conductive layer 116a to the conductive layer 116d include metal such as aluminum (Al), titanium (Ti), chromium (Cr), nickel (Ni), copper (Cu), yttrium (Y), zirconium (Zr), tin (Sn), zinc (Zn), silver (Ag), platinum (Pt), gold (Au), molybdenum (Mo), tantalum (Ta), and tungsten (W), and an alloy containing the metal as its main component (e.g., an alloy of silver, palladium (Pd), and copper (Ag—Pd—Cu (APC))). Alternatively, an oxide such as tin oxide or zinc oxide may be used.

As the electrode 117a to the electrode 117d, for example, Cu, Al, Sn, Zn, W, Ag, Pt, Au, or the like can be used. The electrode 117a to the electrode 117d are layers that are directly bonded to the conductive layers included in the circuit board 150B. Preferably, Cu, Al, W, or Au is used for easy bonding.

The light-emitting layer 114a is positioned between the semiconductor layer 113a and the semiconductor layer 115a. The light-emitting layer 114b is positioned between the semiconductor layer 113b and the semiconductor layer 115b. In the light-emitting layer 114a and the light-emitting layer 114b, electrons and holes are combined to emit light. Either the semiconductor layer 113a and the semiconductor layer 113b or the semiconductor layer 115a and the semiconductor layer 115b are n-type semiconductor layers, and the others are p-type semiconductor layers.

A stacked-layer structure including the semiconductor layer 113a, the light-emitting layer 114a, and the semiconductor layer 115a and a stacked-layer structure including the semiconductor layer 113b, the light-emitting layer 114b, and the semiconductor layer 115b are each formed to emit light of red, yellow, green, blue, or the like. Any of the stacked-layer structures may be formed to emit ultraviolet light. It is preferable that the two stacked-layer structures emit light of different colors. For these stacked-layer structures, for example, a compound containing a Group 13 element and a Group 15 element (also referred to as a Group III-V compound) can be used. Examples of the Group 13 element include aluminum, gallium, and indium. Examples of the Group 15 element include nitrogen, phosphorus, arsenic, and antimony. For the light-emitting diodes to be formed, a compound of gallium and phosphorus, a compound of gallium and arsenic, a compound of gallium, aluminum, and arsenic, a compound of aluminum, gallium, indium, and phosphorus, gallium nitride (GaN), a compound of indium and gallium nitride, a compound of selenium and zinc, or the like can be used, for example.

When the light-emitting diode 110a and the light-emitting diode 110b are formed to emit light of different colors, a step of forming a color conversion layer is not necessary. Consequently, the manufacturing cost of the display apparatus can be reduced.

The two stacked-layer structures may emit light of the same color. In this case, light emitted from the light-emitting layer 114a and the light-emitting layer 114b may be extracted to the outside of the display apparatus through one or both of a color conversion layer and a coloring layer. Note that the structure where pixels of each color include light-emitting diodes emitting light of the same color will be described later in Structure example 2 of the display apparatus and Structure example 4 of the display apparatus.

The display apparatus of this embodiment may include a light-emitting diode emitting infrared light. The light-emitting diode emitting infrared light can be used as a light source of an infrared light sensor, for example.

A compound semiconductor substrate may be used as the substrate 101; for example, a compound semiconductor substrate containing a Group 13 element and a Group 15 element may be used. As the substrate 101, for example, it is possible to use a single crystal substrate such as a sapphire (Al₂O₃) substrate, a silicon carbonate (SiC) substrate, a silicon (Si) substrate, a gallium nitride (GaN) substrate, a gallium arsenide (GaAs) substrate, a gallium phosphide (GaP) substrate, an indium phosphide (InP) substrate, an aluminum gallium arsenide (GaAlAs) substrate, an indium gallium arsenide (InGaAs) substrate, a GaInNAs substrate, an InGaAlP substrate, or a silicon germanium (SiGe) substrate.

As illustrated in FIG. 19, light from the light-emitting diode 110a and the light-emitting diode 110b is emitted toward the substrate 101. For that reason, the substrate 101 preferably has a visible-light-transmitting property. The visible-light-transmitting property of the substrate 101 may be increased by thinning the substrate 101 by polishing or the like, for example. The substrate 101 may be removed by performing etching or the like after the substrate 101 is polished.

FIG. 20B shows a cross-sectional view of the circuit board 150B.

The circuit board 150B includes the layer 151, an insulating layer 152, the transistor 120a, the transistor 120b, a conductive layer 184a, a conductive layer 184b, a conductive layer 189a, a conductive layer 189b, an insulating layer 186, an insulating layer 187, an insulating layer 188, a conductive layer 190a, a conductive layer 190b, a conductive layer 190c, and a conductive layer 190d. The circuit board 150B also includes insulating layers such as an insulating layer 162, an insulating layer 181, an insulating layer 182, an insulating layer 183, and an insulating layer 185. One or more of these insulating layers are sometimes considered as components of a transistor, but are not included as components of a transistor in the description in this embodiment. Note that each of the conductive layers and each of the insulating layers included in the circuit board 150B may have either a single-layer structure or a stacked-layer structure.

As illustrated in FIG. 19, the layer 151 has a stacked-layer structure including the substrate 131 and components thereover up to an insulating layer 143.

A single crystal silicon substrate is suitable as the substrate 131. Alternatively, a compound semiconductor substrate may be used as the substrate 131. The transistor 130a and the transistor 130b each include a conductive layer 135, an insulating layer 134, an insulating layer 136, and a pair of low-resistance regions 133. The conductive layer 135 functions as a gate. The insulating layer 134 is positioned between the conductive layer 135 and the substrate 131 and functions as agate insulating layer. The insulating layer 136 is provided to cover the side surface of the conductive layer 135 and functions as a sidewall. The pair of low-resistance regions 133 are regions doped with an impurity in the substrate 131; one of them functions as a source region of the transistor and the other functions as a drain region of the transistor.

An element isolation layer 132 is provided, between two adjacent transistors, to be embedded in the substrate 131.

An insulating layer 139 is provided to cover the transistor 130a and the transistor 130b, and a conductive layer 138 is provided over the insulating layer 139. The conductive layer 138 is electrically connected to one of the pair of low-resistance regions 133 through a conductive layer 137 embedded in an opening in the insulating layer 139. An insulating layer 141 is provided to cover the conductive layer 138, and a conductive layer 142 is provided over the insulating layer 141. The conductive layer 138 and the conductive layer 142 each function as a wiring. The insulating layer 143 and the insulating layer 152 are provided to cover the conductive layer 142, and the transistor 120a and the transistor 120b are provided over the insulating layer 152.

The layer 151 preferably blocks visible light (has a non-transmitting property with respect to visible light). When the layer 151 blocks visible light, entry of light from the outside into the transistor 120a and the transistor 120b formed over the layer 151 can be inhibited. However, one embodiment of the present invention is not limited thereto, and the layer 151 may have a transmitting property with respect to visible light.

The insulating layer 152 is provided over the layer 151. The insulating layer 152 functions as a barrier layer that prevents diffusion of impurities such as water and hydrogen from the layer 151 into the transistor 120a and the transistor 120b and release of oxygen from a metal oxide layer 165 toward the insulating layer 152. As the insulating layer 152, it is possible to use, a film in which hydrogen or oxygen is less likely to diffuse than in a silicon oxide film, such as an aluminum oxide film, a hafnium oxide film, or a silicon nitride film, for example.

The transistor 120a and the transistor 120b are each a transistor containing a metal oxide (also referred to as an oxide semiconductor) in a semiconductor layer where a channel is formed (i.e., an OS transistor).

The semiconductor layers where the channels of the transistor 120a and the transistor 120b are formed may each contain silicon. Examples of silicon include amorphous silicon and crystalline silicon (e.g., low-temperature polysilicon or single crystal silicon).

The semiconductor layers where the channels of the transistor 120a and the transistor 120b are formed may each contain a layered substance functioning as a semiconductor. The layered substance is a general term of a group of materials having a layered crystal structure. In the layered crystal structure, layers formed by covalent bonding or ionic bonding are stacked with bonding such as the Van der Waals force, which is weaker than covalent bonding or ionic bonding. The layered substance has high electrical conductivity in a monolayer, that is, high two-dimensional electrical conductivity. When a material functioning as a semiconductor and having high two-dimensional electrical conductivity is used for a channel formation region, a transistor having a high on-state current can be provided.

Examples of the layered substances include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

The transistor 120a and the transistor 120b each include a conductive layer 161, an insulating layer 163, an insulating layer 164, the metal oxide layer 165, a pair of conductive layers 166, an insulating layer 167, a conductive layer 168, and the like.

The conductive layer 161 and the insulating layer 162 are provided over the insulating layer 152, and the insulating layer 163 and the insulating layer 164 are provided to cover the conductive layer 161 and the insulating layer 162. The conductive layer 161 includes a region overlapping with the metal oxide layer 165 with the insulating layer 163 and the insulating layer 164 therebetween. The conductive layer 161 functions as a first gate electrode, and the insulating layer 163 and the insulating layer 164 function as first gate insulating layers.

In particular, the display apparatus of this embodiment preferably includes a transistor in which the top surface of a gate electrode and the top surface of an insulating layer are substantially level with each other. By planarization treatment employing a CMP method or the like, for example, the top surfaces of the gate electrode and the insulating layer are planarized, so that the top surface of the gate electrode and the top surface of the insulating layer can be level with each other.

A transistor with such a structure can be easily reduced in size. When the size of a transistor is reduced, the size of a pixel can be reduced, so that the resolution of the display apparatus can be improved.

Specifically, the top surface of the conductive layer 161 is substantially level with the top surface of the insulating layer 162. Thus, the size of the transistor 120a and the transistor 120b can be reduced.

It is preferable that the conductive layer 161 be a single conductive layer or two or more conductive layers stacked. In the case where the conductive layer 161 is two or more conductive layers stacked, of the two conductive layers, the conductive layer in contact with the bottom and side surfaces of an opening provided in the insulating layer 162 is preferably formed using a conductive material having a function of inhibiting diffusion of oxygen or an impurity such as water or hydrogen. Examples of such a conductive material include titanium, titanium nitride, tantalum, tantalum nitride, ruthenium, and ruthenium oxide. The above structure can inhibit diffusion of an impurity such as water or hydrogen into the metal oxide layer 165.

The top surface of the insulating layer 162 is preferably planarized.

It is preferable that the insulating layer 163 be a single inorganic insulating film or two or more inorganic insulating films stacked. The inorganic insulating film used as the insulating layer 163 preferably functions as a barrier layer that prevents diffusion of impurities such as water and hydrogen into the transistor 120a and the transistor 120b from the substrate 131.

As the insulating layer 164 in contact with the metal oxide layer 165, an oxide insulating film such as a silicon oxide film is preferably used.

The metal oxide layer 165 is provided over the insulating layer 164. The metal oxide layer 165 includes a channel formation region. The metal oxide layer 165 includes a first region overlapping with one of the pair of conductive layers 166, a second region overlapping with the other of the pair of conductive layers 166, and a third region between the first region and the second region. A material that can be suitably used for the metal oxide layer 165 will be described in detail later.

The pair of conductive layers 166 is provided over the metal oxide layer 165 to be apart from each other. The pair of conductive layers 166 functions as a source electrode and a drain electrode.

The insulating layer 181 is provided to cover the metal oxide layer 165 and the pair of conductive layers 166, and the insulating layer 182 is provided over the insulating layer 181. The insulating layer 181 functions as a barrier layer that prevents diffusion of impurities such as water and hydrogen from the insulating layer 186 and the like into the metal oxide layer 165 and release of oxygen from the metal oxide layer 165.

An opening reaching the metal oxide layer 165 is provided in the insulating layer 181 and the insulating layer 182, and the insulating layer 167 and the conductive layer 168 are embedded in the opening. The opening overlaps with the third region. The insulating layer 167 overlaps with a side surface of the insulating layer 181 and a side surface of the insulating layer 182. The conductive layer 168 overlaps with the side surface of the insulating layer 181 and the side surface of the insulating layer 182 with the insulating layer 167 therebetween. The conductive layer 168 functions as a second gate electrode, and the insulating layer 167 functions as a second gate insulating layer. The conductive layer 168 includes a region overlapping with the metal oxide layer 165 with the insulating layer 167 therebetween.

As the insulating layer 167, for example, an inorganic insulating film such as a silicon oxide film or a silicon oxynitride film can be used. Note that the insulating layer 167 is not necessarily a single inorganic insulating film but may be two or more inorganic insulating films stacked. For example, an aluminum oxide film, a hafnium oxide film, a silicon nitride film, or the like may be provided in the form of a single layer or stacked layers on the side in contact with the conductive layer 168. Thus, oxidation of the conductive layer 168 can be inhibited. Furthermore, for example, an aluminum oxide film or a hafnium oxide film may be provided on the side in contact with the insulating layer 182, the insulating layer 181, and the conductive layer 166. In this case, release of oxygen from the metal oxide layer 165, excess supply of oxygen to the metal oxide layer 165, oxidation of the conductive layer 166, and the like can be inhibited.

Here, the top surface of the conductive layer 168 is substantially level with the top surface of the insulating layer 182. Thus, the size of the transistor 120a and the transistor 120b can be reduced.

Note that the conductive layer 161 and the conductive layer 168 preferably overlap with each other with the insulators therebetween on the outer side of the side surface of the metal oxide layer 165 in the channel width direction. With this structure, the channel formation region of the metal oxide layer 165 can be electrically surrounded by the electric field of the conductive layer 161 functioning as the first gate electrode and the electric field of the conductive layer 168 functioning as the second gate electrode. In this specification, a transistor structure where the channel formation region is electrically surrounded by the electric fields of the first gate electrode and the second gate electrode is referred to as a surrounded channel (S-channel) structure.

In this specification and the like, a transistor having the S-channel structure refers to a transistor having a structure where a channel formation region is electrically surrounded by the electric fields of a pair of gate electrodes. The S-channel structure disclosed in this specification and the like is different from a fin-type structure and a planar structure. With the S-channel structure, resistance to a short-channel effect can be enhanced, that is, a transistor in which a short-channel effect is less likely to occur can be provided.

When the transistor 120a and the transistor 120b become normally-off and have the above-described S-channel structure, the channel formation region can be electrically surrounded. Accordingly, the transistor 120a and the transistor 120b can be regarded as having a GAA (Gate All Around) structure or an LGAA (Lateral Gate All Around) structure. When the transistor 120a and the transistor 120b have the S-channel structure, the GAA structure, or the LGAA structure, the channel formation region that is formed at the interface between the metal oxide layer 165 and the gate insulating film or in the vicinity of the interface can be formed in the entire bulk of the metal oxide layer 165. Accordingly, the density of current flowing in the transistor can be improved, and it can be expected to improve the on-state current of the transistor or increase the field-effect mobility of the transistor.

The insulating layer 183 and the insulating layer 185 are provided to cover the top surfaces of the insulating layer 182, the insulating layer 167, and the conductive layer 168. The insulating layer 181 and the insulating layer 183 each preferably function as a barrier layer like the insulating layer 152. When the pair of conductive layers 166 is covered with the insulating layer 181, oxidation of the pair of conductive layers 166 due to oxygen contained in the insulating layer 182 can be inhibited.

A plug electrically connected to one of the pair of conductive layers 166 and the conductive layer 189a is embedded in an opening provided in the insulating layer 181, the insulating layer 182, the insulating layer 183, and the insulating layer 185. The plug preferably includes the conductive layer 184b in contact with the side surface of the opening and the top surface of one of the pair of conductive layers 166, and the conductive layer 184a embedded inside the conductive layer 184b. In this case, a conductive material in which hydrogen and oxygen are less likely to diffuse is preferably used for the conductive layer 184b. This structure inhibits an impurity such as water or hydrogen from entering the metal oxide layer 165 from the insulating layer 182 and the like through the plug. Furthermore, the structure inhibits oxygen contained in the insulating layer 182 from being absorbed by the plug.

An insulating layer may be provided in contact with the side surface of the plug. That is, a structure may be employed where the insulating layer is provided in contact with the inner wall of the opening in the insulating layer 182, the insulating layer 181, and the plug is provided in contact with the side surface of the insulating layer and part of the top surface of the conductive layer 166.

The conductive layer 189a and the insulating layer 186 are provided over the insulating layer 185, the conductive layer 189b is provided over the conductive layer 189a, and the insulating layer 187 is provided over the insulating layer 186. The insulating layer 186 preferably has a planarization function. Here, the level of the top surface of the conductive layer 189b is substantially the same as the level of the top surface of the insulating layer 187. An opening reaching the conductive layer 189a is provided in the insulating layer 187 and the insulating layer 186, and the conductive layer 189b is embedded in the opening. The conductive layer 189b functions as a plug for electrically connecting the conductive layer 189a to the conductive layer 190a or the conductive layer 190c.

One of the pair of conductive layers 166 of the transistor 120a is electrically connected to the conductive layer 190a through the conductive layer 184a, the conductive layer 184b, the conductive layer 189a, and the conductive layer 189b.

Similarly, one of the pair of conductive layers 166 of the transistor 120b is electrically connected to the conductive layer 190c through the conductive layer 184a, the conductive layer 184b, the conductive layer 189a, and the conductive layer 189b.

The insulating layer 186 is preferably formed using an inorganic insulating material such as silicon oxide, silicon oxynitride, silicon nitride oxide, silicon nitride, aluminum oxide, hafnium oxide, or titanium nitride.

As the insulating layer 187, a film through which one or both of hydrogen and oxygen are less likely to diffuse than through a silicon oxide film, such as an aluminum oxide film, a hafnium oxide film, and a silicon nitride film, can be used, for example. The insulating layer 187 preferably functions as a barrier layer that prevents diffusion of impurities (e.g., hydrogen and water) from the LED substrate 150A into the transistor. The insulating layer 187 preferably functions as a barrier layer that prevents diffusion of impurities from the circuit board 150B into the LED substrate 150A.

The insulating layer 188 is a layer that is directly bonded to the insulating layer 104 included in the LED substrate 150A. The insulating layer 188 is preferably formed using the same material as the insulating layer 104. An oxide insulating film is preferably used for the insulating layer 188. The oxide insulating films are directly bonded to each other, whereby the bonding strength (attachment strength) can be increased. For example, a silicon oxide film is preferably used as each of the insulating layer 104 and the insulating layer 188. The bonding strength between the insulating layer 104 and the insulating layer 188 can be increased because of hydrophilic bonding through a hydroxyl group (OH group). Note that in the case where one or both of the insulating layer 104 and the insulating layer 188 have a stacked-layer structure, layers (including a surface layer and a bonding surface) that are in contact with each other are preferably formed using the same material.

The conductive layer 190a to the conductive layer 190d are layers that are directly bonded to the electrode 117a to the electrode 117d of the LED substrate 150A. It is preferable that the main components of the conductive layer 190a to the conductive layer 190d and the main components of the electrode 117a to the electrode 117d be the same metal element, and further preferable that the conductive layers and the electrodes be formed using the same material. For the conductive layer 190a to the conductive layer 190d, Cu, Al, Sn, Zn, W, Ag, Pt, or Au can be used, for example. Preferably, Cu, Al, W, or Au is used for easy bonding. Note that in the case where one or both of a conductive layer 190 (the conductive layer 190a to the conductive layer 190d) and an electrode 117 (the electrode 117a to the electrode 117d) have a stacked-layer structure, layers (including a surface layer and a bonding surface) that are in contact with each other are preferably formed using the same material.

Note that the circuit board 150B may include one or both of a reflective layer that reflects light of a light-emitting diode and a light-blocking layer that blocks the light.

As illustrated in FIG. 19, the electrode 117a, the electrode 117b, the electrode 117c, and the electrode 117d, which are provided in the LED substrate 150A, are respectively bonded to be electrically connected to the conductive layer 190a, the conductive layer 190b, the conductive layer 190c, and the conductive layer 190d, which are provided in the circuit board 150B.

For example, connecting the electrode 117a and the conductive layer 190a enables the transistor 120a and the light-emitting diode 110a to be electrically connected to each other. The electrode 117a functions as a pixel electrode of the light-emitting diode 110a. The electrode 117b and the conductive layer 190b are connected to each other. The electrode 117b functions as a common electrode of the light-emitting diode 110a.

Similarly, connecting the electrode 117c and the conductive layer 190c enables the transistor 120b and the light-emitting diode 110b to be electrically connected to each other. The electrode 117c functions as a pixel electrode of the light-emitting diode 110b. The electrode 117d and the conductive layer 190d are connected to each other. The electrode 117d functions as a common electrode of the light-emitting diode 110b.

It is preferable that the main components of the electrode 117a, the electrode 117b, the electrode 117c, and the electrode 117d and the main components of the conductive layer 190a, the conductive layer 190b, the conductive layer 190c, and the conductive layer 190d be the same metal element.

Here, the insulating layer 104 provided in the LED substrate 150A and the insulating layer 188 provided in the circuit board 150B are directly bonded to each other. The insulating layer 104 and the insulating layer 188 are preferably formed of the same component or material.

The layers formed using the same material are in contact with each other at the bonding surface between the LED substrate 150A and the circuit board 150B, whereby connection with mechanical strength can be obtained.

For bonding the metal layers to each other, it is possible to use a surface activated bonding method in which an oxide film, a layer adsorbing impurities, and the like on the surface are removed by sputtering treatment or the like and the cleaned and activated surfaces are brought into contact to be bonded to each other. Alternatively, a diffusion bonding method in which the surfaces are bonded to each other by using temperature and pressure together can be used, for example. Both methods cause bonding at an atomic level, and therefore not only electrically but also mechanically excellent bonding can be obtained.

For bonding insulating layers to each other, a hydrophilic bonding method or the like can be used; in the method, after high planarity is obtained by polishing or the like, the surfaces of the insulating layers subjected to hydrophilicity treatment with oxygen plasma or the like are arranged in contact with and bonded to each other temporarily, and then dehydrated by heat treatment to perform final bonding. The hydrophilic bonding method can also cause bonding at an atomic level; thus, mechanically excellent bonding can be obtained. In the case where an oxide insulating film is used, hydrophilicity treatment is preferably used, in which case the bonding strength can be further increased. Note that in the case where an oxide insulating film is used, hydrophilicity treatment is not necessarily performed separately.

A combination of two or more of bonding methods may be used for the bonding because both the insulating layer and the metal layer exist at the bonding surface between the LED substrate 150A and the circuit board 150B. For example, a surface activated bonding method and a hydrophilic bonding method can be performed in combination.

For example, it is possible to use a method in which the surfaces are made clean after polishing, the surfaces of the metal layers are subjected to antioxidant treatment and hydrophilicity treatment, and then bonding is performed. Furthermore, hydrophilicity treatment may be performed on the surfaces of the metal layers being hardly oxidizable metal such as Au. In the case where hydrophilicity treatment is not performed, antioxidant treatment can be omitted and there is no limitation on the kinds of the materials, so that the fabrication cost and the number of fabrication steps can be reduced. Note that a bonding method other than the above-mentioned methods may be used.

Note that the bonding between the LED substrate 150A and the circuit board 150B is not necessarily direct bonding over the entire surfaces of the substrates; the substrates may be connected to each other in at least part of the substrates with a conductive paste of silver, carbon, copper, or the like, or a bump of gold, solder, or the like.

In the conductive layer 190a to the conductive layer 190d, an angle between a surface on the transistor (the layer 151) side and a side surface is preferably greater than 0° and less than or equal to 90° or greater than 0° and less than 90°. In the electrode 117a to the electrode 117d, an angle between a surface on the transistor (the layer 151) side and a side surface is preferably greater than or equal to 90° and less than 180° or greater than 900 and less than 180°. In the case where all of the conductive layer 190a to the conductive layer 190d and the electrode 117a to the electrode 117d are formed over the same substrate as the transistor, the conductive layer 190a to the conductive layer 190d and the electrode 117a to the electrode 117d are often fabricated such that the angle between the surface on the transistor side and the side surface is less than or equal to 90°. Therefore, by cross-sectional observation of the display apparatus with a scanning electron microscope (SEM), a scanning transmission electron microscope (STEM), or the like, a boundary between the two conductive layers can be presumed to be a boundary surface of the attachment because of the different tapered shapes of the two conductive layers (the conductive layer 190 and the electrode 117).

Note that a plurality of light-emitting diodes may be electrically connected to one transistor.

Note that the transistor 120a for driving the light-emitting diode 110a and the transistor 120b for driving the light-emitting diode 110b may differ in at least one of the transistor size, the channel length, the channel width, the structure, and the like. For example, in the case where the light-emitting diode 110a and the light-emitting diode 110b emit light of different colors, the structure of the transistor may be changed for each color. Specifically, depending on the amount of current required for light emission with desired luminance, one or both of the channel length and the channel width of the transistor may be changed for each color.

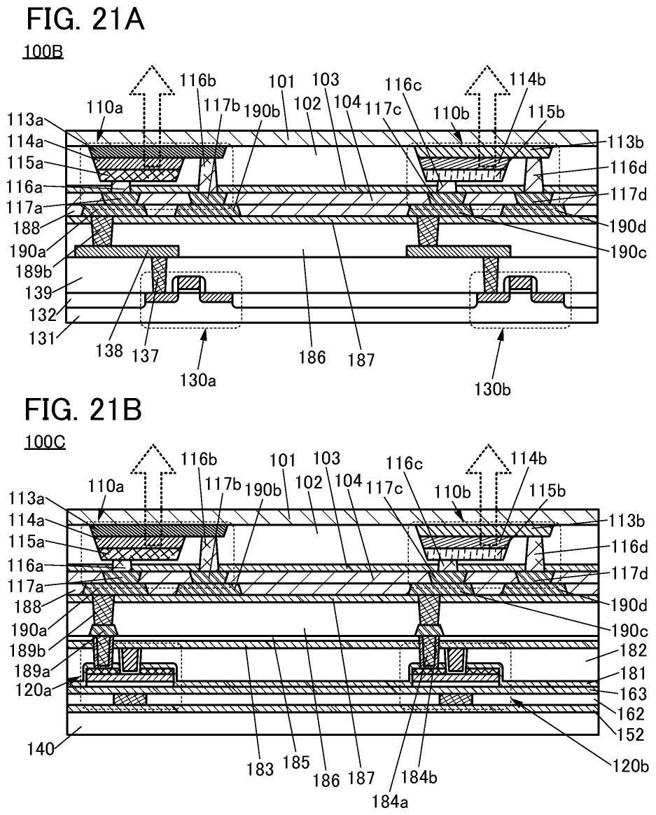

In addition, FIG. 21A shows a cross-sectional view of a display apparatus 100B. The display apparatus 100B is different from the display apparatus 100A mainly in not including a stacked-layer structure including the insulating layer 141 and components thereover up to the insulating layer 185. That is, the display apparatus 100B does not include the transistor including the channel formation region in the metal oxide layer (the transistor 120a and the transistor 120b). In the display apparatus 100B, the transistor including the channel formation region in the substrate 131 (e.g., single crystal substrate) can be used as any of the transistor included in the pixel circuit, the transistor included in one or both of the gate driver and the source driver, and the transistor included in a variety of functional circuits such as an arithmetic circuit and a memory circuit.

The display apparatus 100B can be fabricated by attaching a substrate where the transistor 130a and the transistor 130b are formed and the substrate where the light-emitting diode 110a and the light-emitting diode 110b are formed. The electrode 117a, the electrode 117b, the electrode 117c, and the electrode 117d are bonded to be electrically connected to the conductive layer 190a, the conductive layer 190b, the conductive layer 190c, and the conductive layer 190d, respectively.

Any of a variety of substrates may be used instead of the layer 151. FIG. 21B shows a cross-sectional view of a display apparatus 100C. The display apparatus 100C is different from the display apparatus 100A mainly in including a substrate 140 instead of the stacked-layer structure including the substrate 131 and components thereover up to the insulating layer 143. That is, the display apparatus 100C does not include the transistor including the channel formation region in the substrate (the transistor 130a and the transistor 130b). In the display apparatus 100C, an OS transistor can be used as any of the transistor included in the pixel circuit, the transistor included in one or both of the gate driver and the source driver, and the transistor included in a variety of functional circuits such as an arithmetic circuit and a memory circuit.

Examples of the substrate 140 include an insulating substrate such as a glass substrate, a quartz substrate, a sapphire substrate, or a ceramic substrate; a single crystal semiconductor substrate or a polycrystalline semiconductor substrate including silicon, silicon carbide, or the like as a material; a compound semiconductor substrate of silicon germanium or the like; and a semiconductor substrate such as an SOI (Silicon On Insulator) substrate. The substrate 140 may be formed using a flexible material. Furthermore, a polarizing plate may be used as the substrate 140.

Although this embodiment describes an example where a display apparatus is fabricated in such a manner that a transistor and a light-emitting diode are formed over different substrates and the substrates are attached to each other, the display apparatus may be fabricated by forming the transistor and the light-emitting diode to be stacked over the same substrate.

### Structure Example 2 of Display Apparatus

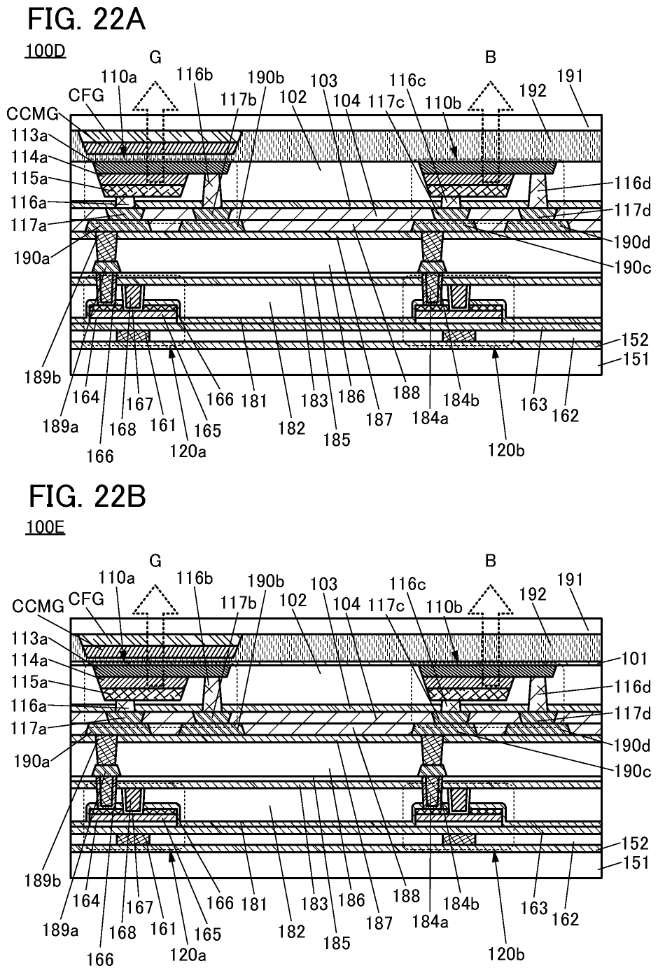

FIG. 22A shows a cross-sectional view of a display apparatus 100D, and FIG. 22B shows a cross-sectional view of a display apparatus 100E. Note that in the following description of the structure examples, detailed description of the components described above is omitted in some cases.

In the display apparatus 100D and the display apparatus 100E, the pixels of each color include light-emitting diodes that emit light of the same color.

The display apparatus 100D and the display apparatus 100E each include a substrate 191 provided with a coloring layer CFG and a color conversion layer CCMG.

Specifically, the substrate 191 includes the coloring layer CFG and the color conversion layer CCMG in a region overlapping with the light-emitting diode 110a included in a green pixel. The color conversion layer CCMG has a function of converting blue light into green light.

In FIG. 22A and FIG. 22B, light emitted from the light-emitting diode 110a included in the green pixel is converted from blue light into green light by the color conversion layer CCMG, the purity of the green light is improved by the coloring layer CFG, and the green light is emitted to the outside of the display apparatus 100D or the display apparatus 100E.

On the other hand, the substrate 191 does not include a color conversion layer in a region overlapping with the light-emitting diode 110b included in a blue pixel. The substrate 191 may include a blue coloring layer in the region overlapping with the light-emitting diode 110b included in the blue pixel. Provision of a blue coloring layer can increase the purity of blue light. In the case where a blue coloring layer is not provided, the fabrication process can be simplified and light emitted from the light-emitting diode can be extracted to the outside of the display apparatus efficiently.

Blue light emitted from the light-emitting diode 110b is emitted to the outside of the display apparatus 100D or the display apparatus 100E through an adhesive layer 192 and the substrate 191.

Although FIG. 22A and FIG. 22B illustrate structures where the display apparatus 100D and the display apparatus 100E each include a green pixel and a blue pixel, the present invention is not limited thereto. For example, the display apparatus 100D and the display apparatus 100E may each include a red pixel and a blue pixel.

In the above structure, the substrate 191 includes a red coloring layer and a color conversion layer that converts blue light into red light in a region overlapping with a light-emitting diode included in a red pixel. Thus, light emitted from the light-emitting diode included in the red pixel is converted from blue into red by the color conversion layer, the purity of the red light is improved by the coloring layer, and the red light is emitted to the outside of the display apparatus.

Although FIG. 22A and FIG. 22B each illustrate an example where the light-emitting diode 110a and the light-emitting diode 110b emit blue light, the present invention is not limited thereto. The light-emitting diode 110a and the light-emitting diode 110b may emit red or green light. In this case, the display apparatus 100D and the display apparatus 100E are preferably provided with a color conversion layer and a coloring layer as appropriate depending on the colors of the pixels included in the display apparatus 100D and the display apparatus 100E. For example, in the case where the light-emitting diode 110a and the light-emitting diode 110b emit green light and the display apparatus 100D and the display apparatus 100E each include a green pixel and a blue pixel, a blue coloring layer and a color conversion layer that converts green light into blue are preferably provided in a region overlapping with a light-emitting diode included in the blue pixel.

In fabricating a display apparatus in which the pixels of each color include light-emitting diodes having the same structure, only light-emitting diodes of the same type need to be formed over a substrate; hence, a manufacturing apparatus and manufacturing process can be simplified and the yield can be improved compared to the case where a plurality of types of light-emitting diodes are formed.

The substrate 191 is positioned on the side where light from the light-emitting diode is extracted, and thus is preferably formed using a material having a high visible-light-transmitting property. Examples of a material that can be used for the substrate 191 include glass, quartz, sapphire, and a resin. A film such as a resin film may be used as the substrate 191. In this case, the display apparatus can be reduced in weight and thickness.

For the color conversion layer, one or both of a phosphor and a quantum dot (QD) are preferably used. In particular, a quantum dot has an emission spectrum with a narrow peak width, so that emission with high color purity can be obtained. Thus, the display quality of the display apparatus can be improved.

The color conversion layer can be formed by a droplet discharge method (e.g., an inkjet method), a coating method, an imprinting method, a variety of printing methods (screen printing or offset printing), or the like. A color conversion film such as a quantum dot film may also be used.

For processing a film to be the color conversion layer, a photolithography method is preferably employed. As a photolithography method, there are a method in which a resist mask is formed over a thin film to be processed, the thin film is processed by etching or the like, and the resist mask is removed, and a method in which a photosensitive thin film is formed, and then exposed to light and developed to be processed into a desired shape. For example, a thin film is formed using a material in which a quantum dot is mixed with a photoresist, and the thin film is processed by a photolithography method, whereby an island-shaped color conversion layer can be formed.

There is no particular limitation on a material of a quantum dot, and examples include a Group 14 element, a Group 15 element, a Group 16 element, a compound of a plurality of Group 14 elements, a compound of an element belonging to any of Group 4 to Group 14 and a Group 16 element, a compound of a Group 2 element and a Group 16 element, a compound of a Group 13 element and a Group 15 element, a compound of a Group 13 element and a Group 17 element, a compound of a Group 14 element and a Group 15 element, a compound of a Group 11 element and a Group 17 element, iron oxides, titanium oxides, spinel chalcogenides, and a variety of semiconductor clusters.

Specific examples include cadmium selenide; cadmium sulfide; cadmium telluride; zinc selenide; zinc oxide; zinc sulfide; zinc telluride; mercury sulfide; mercury selenide; mercury telluride; indium arsenide; indium phosphide; gallium arsenide; gallium phosphide; indium nitride; gallium nitride; indium antimonide; gallium antimonide; aluminum phosphide; aluminum arsenide; aluminum antimonide; lead selenide; lead telluride; lead sulfide; indium selenide; indium telluride; indium sulfide; gallium selenide; arsenic sulfide; arsenic selenide; arsenic telluride; antimony sulfide; antimony selenide; antimony telluride; bismuth sulfide; bismuth selenide; bismuth telluride; silicon; silicon carbide; germanium; tin; selenium; tellurium; boron; carbon; phosphorus; boron nitride; boron phosphide; boron arsenide; aluminum nitride; aluminum sulfide; barium sulfide; barium selenide; barium telluride; calcium sulfide; calcium selenide; calcium telluride; beryllium sulfide; beryllium selenide; beryllium telluride; magnesium sulfide; magnesium selenide; germanium sulfide; germanium selenide; germanium telluride; tin sulfide; tin selenide; tin telluride; lead oxide; copper fluoride; copper chloride; copper bromide; copper iodide; copper oxide; copper selenide; nickel oxide; cobalt oxide; cobalt sulfide; iron oxide; iron sulfide; manganese oxide; molybdenum sulfide; vanadium oxide; tungsten oxide; tantalum oxide; titanium oxide; zirconium oxide; silicon nitride; germanium nitride; aluminum oxide; barium titanate; a compound of selenium, zinc, and cadmium; a compound of indium, arsenic, and phosphorus; a compound of cadmium, selenium, and sulfur; a compound of cadmium, selenium, and tellurium; a compound of indium, gallium, and arsenic; a compound of indium, gallium, and selenium; a compound of indium, selenium, and sulfur; a compound of copper, indium, and sulfur; and a combinations thereof. What is called an alloyed quantum dot, whose composition is represented by a given ratio, may be used.

Examples of the quantum dot include a core-type quantum dot, a core-shell quantum dot, and a core-multishell quantum dot. Quantum dots have a high proportion of surface atoms and thus have high reactivity and easily aggregate together. For this reason, it is preferable that a protective agent be attached to, or a protective group be provided on the surfaces of quantum dots. The attachment of the protective agent or the provision of the protective group can prevent aggregation and increase solubility in a solvent. It can also reduce reactivity and improve electrical stability.

Since band gaps of quantum dots are increased as their size is decreased, the size is adjusted as appropriate so that light with a desired wavelength can be obtained. Light emission from the quantum dots is shifted to a blue color side, i.e., a high energy side, as the crystal size is decreased; thus, emission wavelengths of the quantum dots can be adjusted over a wavelength range in the spectrum of an ultraviolet region, a visible light region, and an infrared region by changing the size of quantum dots. The size (diameter) of quantum dots is, for example, greater than or equal to 0.5 nm and less than or equal to 20 nm, preferably greater than or equal to 1 nm and less than or equal to 10 nm. The emission spectra are narrowed as the size distribution of quantum dots gets smaller, and thus light emission with high color purity can be obtained. The shape of quantum dots is not particularly limited and may be a spherical shape, a rod shape, a circular shape, or the like. A quantum rod, which is a rod-shaped quantum dot, has a function of emitting directional light.

The coloring layer is a colored layer that transmits light in a specific wavelength range. For example, a color filter that transmits light in a red, green, blue, or yellow wavelength range can be used. Examples of a material that can be used for the coloring layer include a metal material, a resin material, and a resin material containing a pigment or a dye.

The display apparatus 100D can be fabricated in the following manner: first, the circuit board and the LED substrate are attached to each other as in the display apparatus 100A, and then the substrate 101 of the LED substrate is separated, and the substrate 191 provided with the coloring layer CFG, the color conversion layer CCMG, and the like is attached to the surface exposed by the separation with the use of the adhesive layer 192.

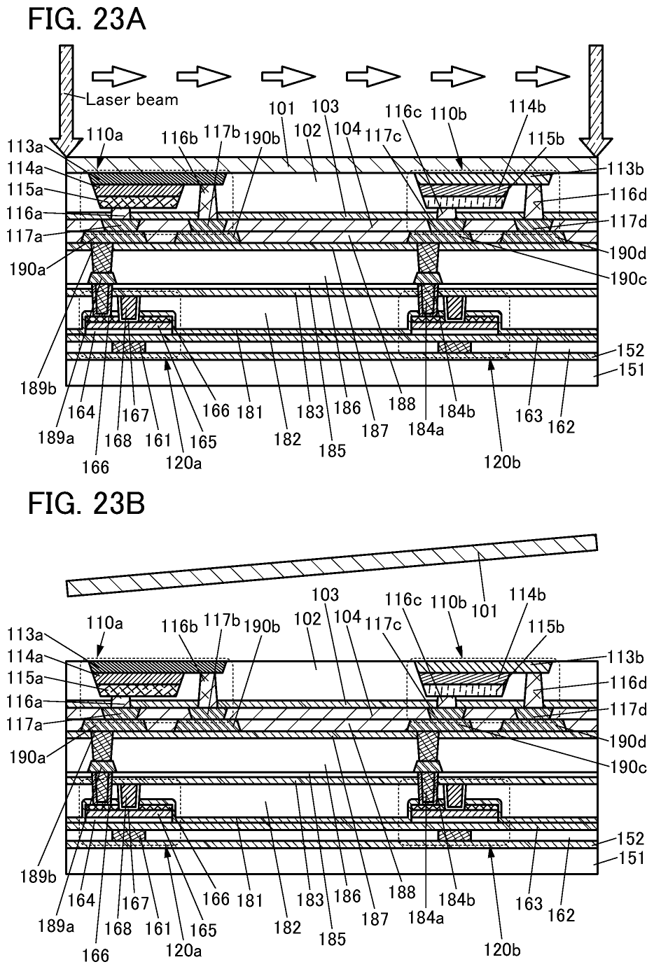

There is no limitation on the method for separating the substrate 101; for example, a method in which the entire surface of the substrate 101 is irradiated with laser light (Laser beam) as illustrated in FIG. 23A may be employed. Thus, the substrate 101 can be separated, and the insulating layer 102, the light-emitting diode 110a, and the light-emitting diode 110b can be exposed (FIG. 23B).

As the laser, an excimer laser, a solid-state laser, and the like can be used. For example, a diode-pumped solid-state laser (DPSS) may be used.

A separation layer may be provided between the substrate 101 and the light-emitting diode 110a and the light-emitting diode 110b.

The separation layer can be formed using an organic material or an inorganic material.

Examples of the organic material that can be used for the separation layer include a polyimide resin, an acrylic resin, an epoxy resin, a polyamide resin, a polyimide-amide resin, a siloxane resin, a benzocyclobutene-based resin, and a phenol resin.

Examples of the inorganic material that can be used for the separation layer include a metal containing an element selected from tungsten, molybdenum, titanium, tantalum, niobium, nickel, cobalt, zirconium, zinc, ruthenium, rhodium, palladium, osmium, iridium, and silicon, an alloy containing the element, and a compound containing the element. A crystal structure of a layer containing silicon may be any of amorphous, microcrystal, and polycrystal.

For the adhesive layer 192, a variety of curable adhesives such as a photocurable adhesive such as an ultraviolet curable adhesive, a reactive curable adhesive, a thermosetting adhesive, and an anaerobic adhesive can be used. An adhesive sheet or the like may be used.

Alternatively, as in the display apparatus 100E, the substrate 191 provided with the coloring layer CFG, the color conversion layer CCMG, and the like may be attached to the substrate 101 with the use of the adhesive layer 192. In other words, the substrate 101 is not necessarily separated.

At this time, the substrate 101 is preferably thinned by polishing or the like. This can increase the extraction efficiency of light emitted from the light-emitting diode. In addition, the display apparatus can be reduced in thickness and weight.

The display apparatus 100E can be fabricated in the following manner: first, the circuit board and the LED substrate are attached to each other as in the display apparatus 100A, and then the substrate 101 of the LED substrate is polished, and the substrate 191 provided with the coloring layer CFG, the color conversion layer CCMG, and the like is attached to the polished surface of the substrate 101 with the use of the adhesive layer 192.

The substrate 191 can be provided with at least one of a coloring layer, a color conversion layer, and a light-blocking layer.

### Structure Example 3 of Display Apparatus

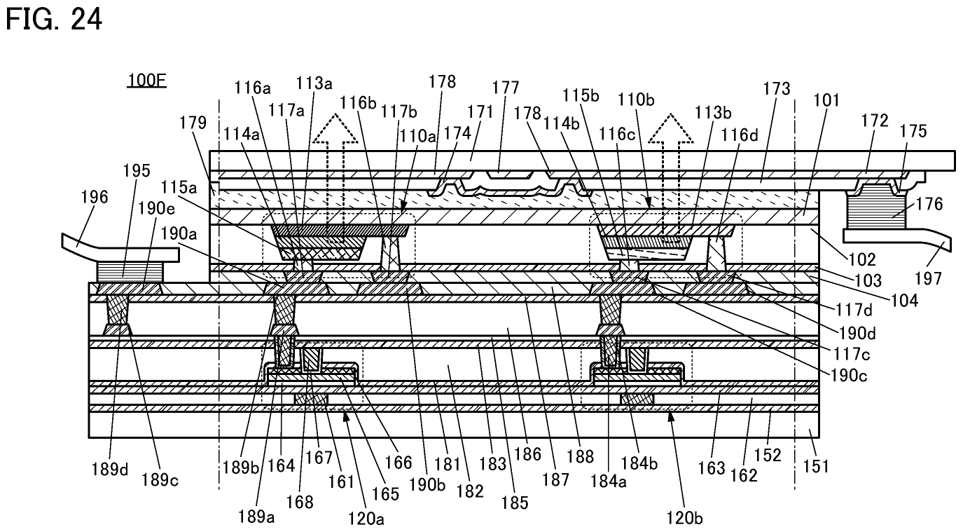

FIG. 24 shows a cross-sectional view of a display apparatus 100F.

The display apparatus of one embodiment of the present invention may be a display apparatus in which a touch sensor is mounted (also referred to as an input/output device or a touch panel). The structures of the display apparatuses described above can be used for the touch panel. The display apparatus 100F is an example in which a touch sensor is provided in the display apparatus 100A.

There is no limitation on a detection device (also referred to as a sensor device, a detection element, or a sensor element) included in the touch panel of one embodiment of the present invention. A variety of sensors capable of sensing an approach or a contact of a sensing target such as a finger or a stylus can be used as the sensor device.

For example, a variety of types such as a capacitive type, a resistive type, a surface acoustic wave type, an infrared type, an optical type, and a pressure-sensitive type can be used as the sensor type.

In this embodiment, a touch panel including a capacitive sensor device is described as an example.

Examples of the capacitive touch sensor include a surface capacitive touch sensor and a projected capacitive touch sensor. Examples of the projected capacitive type include a self-capacitive type and a mutual capacitive type. The use of a mutual capacitive type is preferable because multiple points can be sensed simultaneously.

The touch panel of one embodiment of the present invention can have any of a variety of structures, including a structure where a display apparatus and a detection device that are separately formed are attached to each other and a structure where an electrode and the like included in a detection device are provided on one or both of a substrate supporting a display apparatus and a counter substrate.

The stacked-layer structure from the layer 151 to the substrate 101 in the display apparatus 100F is the same as that in the display apparatus 100A; thus, detailed description thereof is omitted.

The conductive layer 189c is electrically connected to an FPC (Flexible printed circuit) 196 through a conductive layer 189d, a conductive layer 190e, and a conductor 195. The display apparatus 100F is supplied with a signal and power through the FPC196.

The conductive layer 189c can be formed using the same material and the same step as the conductive layer 189a. The conductive layer 189d can be formed using the same material and the same step as the conductive layer 189b. The conductive layer 190e can be formed using the same material and the same step as the conductive layers 190a to 190d.

As the conductor 195, for example, an anisotropic conductive film (ACF) or an anisotropic conductive paste (ACP) can be used.

A substrate 171 is provided with a touch sensor. The substrate 171 and the substrate 101 are attached to each other with an adhesive layer 179 such that the surface of the substrate 171 where the touch sensor is provided faces the substrate 101.

An electrode 177 and an electrode 178 are provided on the substrate 171 on the substrate 101 side. The electrode 177 and the electrode 178 are formed on the same plane. A material transmitting visible light is used for the electrode 177 and the electrode 178. An insulating layer 173 is provided to cover the electrode 177 and the electrode 178. An electrode 174 is electrically connected to two electrodes 178 that are provided to sandwich the electrode 177 therebetween, through openings provided in the insulating layer 173.

A wiring 172 that is obtained by processing the same conductive layer as the electrode 177 and the electrode 178 is connected to a conductive layer 175 that is obtained by processing the same conductive layer as the electrode 174. The conductive layer 175 is electrically connected to the FPC197 through a connector 176.

### Structure Example 4 of Display Apparatus

Although the display apparatus 100A to the display apparatus 100F each include the light-emitting diode as the display device, the present invention is not limited thereto. For example, an organic EL element may be included as the display device.

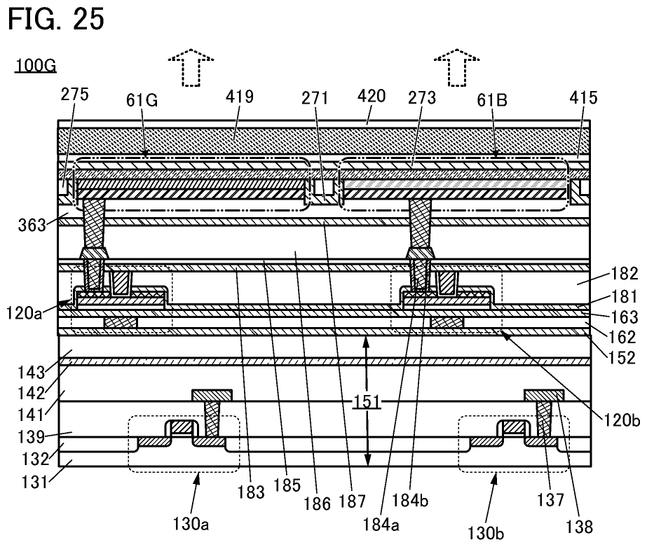

FIG. 25 shows a cross-sectional view of a display apparatus 100G. The display apparatus 100G is different from the display apparatus 100A mainly in including a light-emitting element 61G and a light-emitting element 61B instead of the light-emitting diode 110a and the light-emitting diode 110b. The light-emitting element 61G emits green light, and the light-emitting element 61B emits blue light.

A protective layer 415 is provided over the light-emitting element 61G and the light-emitting element 61B, and a substrate 420 is provided over the top surface of the protective layer 415 with a resin layer 419 therebetween.

The display apparatus 100G including two colors corresponds to the display apparatus 11bR and the display apparatus 11bL that are described in Embodiment 1. The display apparatus 100G including one color corresponds to the display apparatus 11aR and the display apparatus 11aL that are described in Embodiment 1. For example, the display apparatus 100G including the light-emitting element 61G and the light-emitting element 61B corresponds to the display apparatus 11bR and the display apparatus 11bL that are described in Embodiment 1, and the display apparatus 100G including a light-emitting element emitting red light corresponds to the display apparatus 11aR and the display apparatus 11aL that are described in Embodiment 1.

Structure examples of the light-emitting element 61 will be described below.

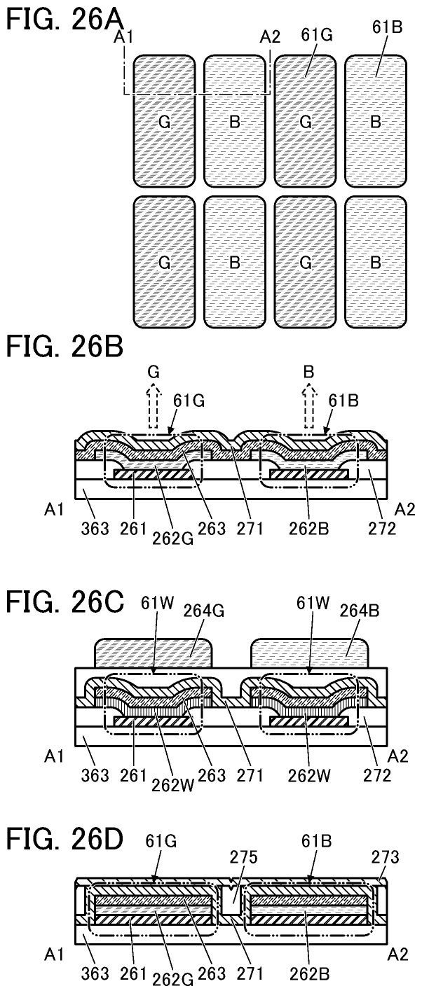

FIG. 26A shows a schematic top view of the light-emitting element 61 placed in a display region of the display apparatus 100G. The light-emitting element 61 includes a plurality of light-emitting elements 61G exhibiting green and a plurality of light-emitting elements 61B exhibiting blue. Note that in the description in this specification and the like, the light-emitting element 61G exhibiting green and the light-emitting element 61B exhibiting blue are collectively referred to as the light-emitting element 61 in some cases. In FIG. 26A, light-emitting regions of the light-emitting elements are denoted by G, and B to easily differentiate the light-emitting elements. Note that the structure of the light-emitting element 61 illustrated in FIG. 26A may be referred to as an SBS (Side By Side) structure. Although the structure illustrated in FIG. 26A has two colors of green (G) and blue (B), the present invention is not limited thereto. For example, the structure may have two colors of red (R) and green (G) or two colors of red (R) and blue (B). Although the structure illustrated in FIG. 26A has two colors of green (G) and blue (B), the present invention is not limited thereto. For example, the structure may have one color or three or more colors.

The light-emitting elements 61G and the light-emitting elements 61B are arranged in a matrix. FIG. 26A illustrates what is called stripe arrangement, in which the light-emitting elements of the same color are arranged in one direction. Note that the arrangement method of the light-emitting elements is not limited thereto; another arrangement method such as delta arrangement or zigzag arrangement may be used, or PenTile arrangement can be used.

As the light-emitting element exhibiting red, the light-emitting element 61G, and the light-emitting element 61B, an organic EL device such as an OLED (Organic Light Emitting Diode) or a QOLED (Quantum-dot Organic Light Emitting Diode) is preferably used. As examples of a light-emitting substance contained in the EL element, a substance that emits fluorescent light (a fluorescent material), a substance that emits phosphorescent light (a phosphorescent material), an inorganic compound (e.g., a quantum dot material), a substance exhibiting thermally activated delayed fluorescence (a thermally activated delayed fluorescence (TADF) material), and the like can be given.

FIG. 26B is a schematic cross-sectional view taken along the dashed-dotted line A1-A2 in FIG. 26A. FIG. 26B illustrates cross sections of the light-emitting element 61G and the light-emitting element 61B. The light-emitting element 61G and the light-emitting element 61B are provided over an insulating layer 363, and include a conductive layer 261 functioning as a pixel electrode and a conductive layer 263 functioning as a common electrode. As the insulating layer 363, one or both of an inorganic insulating film and an organic insulating film can be used. An inorganic insulating film is preferably used as the insulating layer 363. Examples of the inorganic insulating film include oxide insulating films, oxynitride insulating films, nitride oxide insulating films, and nitride insulating films, such as a silicon oxide film, a silicon oxynitride film, a silicon nitride oxide film, a silicon nitride film, an aluminum oxide film, an aluminum oxynitride film, and a hafnium oxide film.

The light-emitting element 61G includes an EL layer 262G between the conductive layer 261 functioning as a pixel electrode and the conductive layer 263 functioning as a common electrode. The EL layer 262G contains at least a light-emitting organic compound that emits light with intensity in the green wavelength range. The light-emitting element 61B includes an EL layer 262B between the conductive layer 261 functioning as a pixel electrode and the conductive layer 263 functioning as a common electrode. The EL layer 262B contains at least a light-emitting organic compound that emits light with intensity in the blue wavelength range.

The EL layer 262G and the EL layer 262B may each include one or more of an electron-injection layer, an electron-transport layer, a hole-injection layer, and a hole-transport layer in addition to the layer containing a light-emitting organic compound (the light-emitting layer).

The conductive layer 261 functioning as a pixel electrode is provided for each of the light-emitting elements. The conductive layer 263 functioning as a common electrode is provided as a continuous layer shared by the light-emitting elements. A conductive film that transmits visible light is used as either the conductive layer 261 functioning as a pixel electrode or the conductive layer 263 functioning as a common electrode, and a reflective conductive film is used as the other. When the conductive layer 261 functioning as a pixel electrode has a light-transmitting property and the conductive layer 263 functioning as a common electrode has a reflective property, a bottom-emission display apparatus can be obtained, whereas when the conductive layer 261 functioning as a pixel electrode has a reflective property and the conductive layer 263 functioning as a common electrode has a light-transmitting property, a top-emission display apparatus can be obtained. Note that when both the conductive layer 261 functioning as a pixel electrode and the conductive layer 263 functioning as a common electrode have a light-transmitting property, a dual-emission display apparatus can be obtained.

An insulating layer 272 is provided to cover an end portion of the conductive layer 261 functioning as a pixel electrode. An end portion of the insulating layer 272 is preferably tapered. For the insulating layer 272, a material similar to the material that can be used for the insulating layer 363 can be used.

The EL layer 262G and the EL layer 262B each include a region in contact with the top surface of the conductive layer 261 functioning as a pixel electrode and a region in contact with a surface of the insulating layer 272. End portions of the EL layer 262G and the EL layer 262B are positioned over the insulating layer 272.

As illustrated in FIG. 26B, there is a gap between the two EL layers of the light-emitting elements that emit light of different colors. In this manner, the EL layer 262G and the EL layer 262B are preferably provided so as not to be in contact with each other. This can suitably prevent unintentional light emission (also referred to as crosstalk) from being caused by a current flowing through two adjacent EL layers. As a result, the contrast can be increased to achieve a display apparatus with high display quality.

The EL layer 262G and the EL layer 262B can be formed separately by a vacuum evaporation method or the like using a shadow mask such as a metal mask. Alternatively, these layers may be formed separately by a photolithography method. The use of the photolithography method achieves a display apparatus with high resolution, which is difficult to achieve in the case of using a metal mask.

In this specification and the like, a device formed using a metal mask or an FMM (fine metal mask, high-resolution metal mask) may be referred to as a device having an MM (metal mask) structure. In this specification and the like, a device fabricated without using a metal mask or an FMM may be referred to as a device having an MML (metal maskless) structure. A display apparatus having an MML structure is fabricated without using a metal mask and thus has higher flexibility in designing the pixel arrangement, the pixel shape, and the like than a display apparatus having an MM structure.

Note that in the method for fabricating a display apparatus having an MML structure, an island-shaped EL layer is formed not by using a fine metal mask but by processing an EL layer formed over an entire surface. Accordingly, a high-resolution display apparatus or a display apparatus with a high aperture ratio, each of which has been difficult to achieve, can be obtained. Moreover, EL layers can be formed separately for the respective colors, enabling the display apparatus to perform extremely clear display with high contrast and high display quality. Moreover, providing the sacrificial layer over the EL layer can reduce damage to the EL layer in the fabrication process of the display apparatus, resulting in an increase in reliability of the light-emitting device.

The display apparatus of one embodiment of the present invention can have a structure where an insulator for covering the end portion of the pixel electrode is not provided. In other words, an insulator is not provided between the pixel electrode and the EL layer. With such a structure, light can be efficiently extracted from the EL layer, leading to extremely low viewing angle dependence. For example, in the display apparatus of one embodiment of the present invention, the viewing angle (the maximum angle with a certain contrast ratio maintained when the screen is seen from an oblique direction) can be greater than or equal to 100° and less than 180°, preferably greater than or equal to 150° and less than or equal to 170°. Note that the viewing angle refers to that in both the vertical direction and the lateral direction. The display apparatus of one embodiment of the present invention can have improved viewing angle dependence and high image visibility.

In the case where a display apparatus is a device having a fine metal mask (FMM) structure, the pixel arrangement structure or the like is restricted in some cases. Here, the FMM structure is described below.

In fabrication of the FMM structure, a metal mask (also referred to as an FMM) provided with an opening so that an EL material can be deposited to a desired region at the time of EL evaporation is set to be opposed to a substrate. Then, the EL material is deposited to the desired region by EL evaporation through the FMM. When the size of the substrate at the time of EL evaporation is larger, the size of the FMM is increased and accordingly the weight thereof is also increased. In addition, heat or the like is applied to the FMM at the time of EL evaporation and may change the shape of the FMM. Furthermore, there is a method in which EL evaporation is performed while a certain level of tension is applied to the FMM; therefore, the weight and strength of the FMM are important parameters.

Therefore, a structure of pixel arrangement in a device having the FMM structure needs to be designed under certain restrictions; for example, the above-described parameters and the like need to be considered. In contrast, in the display apparatus of one embodiment of the present invention fabricated using an MML structure, an excellent effect such as higher flexibility in the pixel arrangement structure or the like than the FMM structure can be exhibited. This structure is highly compatible with a flexible device or the like, for example, and thus one or both of a pixel and a driver circuit can have a variety of circuit arrangements.

In this specification and the like, a structure where light-emitting layers in light-emitting devices of different colors (here, blue (B), green (G), and red (R)) are separately formed or separately patterned may be referred to as an SBS (Side By Side) structure. In this specification and the like, a light-emitting device capable of emitting white light may be referred to as a white-light-emitting device. Note that a combination of a white light-emitting device with a coloring layer (e.g., a color filter) enables a full-color display apparatus.

Structures of light-emitting devices can be classified roughly into a single structure and a tandem structure. A device having a single structure includes one light-emitting unit between a pair of electrodes, and the light-emitting unit preferably includes one or more light-emitting layers. To obtain white light emission by using two light-emitting layers, two light-emitting layers are selected such that the light-emitting layers emit light of complementary colors. For example, when emission colors of a first light-emitting layer and a second light-emitting layer are complementary colors, a light-emitting device can be configured to emit white light as a whole. To obtain white light emission by using three or more light-emitting layers, the light-emitting device is configured to emit white light as a whole by combining emission colors of the three or more light-emitting layers.

A device having a tandem structure includes two or more light-emitting units between a pair of electrodes, and each light-emitting unit preferably includes one or more light-emitting layers. To obtain white light emission, the structure is made so that light from light-emitting layers of the plurality of light-emitting units can be combined to be white light. Note that a structure for obtaining white light emission is similar to that in the case of a single structure. In the device having a tandem structure, an intermediate layer such as a charge-generation layer is suitably provided between the plurality of light-emitting units.

When the white-light-emitting device (having a single structure or a tandem structure) and a light-emitting device having an SBS structure are compared to each other, the light-emitting device having an SBS structure can have lower power consumption than the white-light-emitting device. To reduce power consumption, a light-emitting device having an SBS structure is preferably used. Meanwhile, the white-light-emitting device is suitable in terms of lower manufacturing cost or higher manufacturing yield because the manufacturing process of the white-light-emitting device is simpler than that of the light-emitting device having an SBS structure.

A protective layer 271 is provided over the conductive layer 263 functioning as a common electrode to cover the light-emitting element 61G and the light-emitting element 61B. The protective layer 271 has a function of preventing diffusion of impurities such as water into the light-emitting elements from above.

The protective layer 271 can have, for example, a single-layer structure or a stacked-layer structure at least including an inorganic insulating film. Examples of the inorganic insulating film include oxide films, oxynitride films, nitride oxide films, and nitride films, such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as indium gallium oxide or indium gallium zinc oxide (IGZO) may be used for the protective layer 271. Note that the protective layer 271 is formed by an ALD method, a CVD method, or a sputtering method. Although the protective layer 271 includes an inorganic insulating film in this example, one embodiment of the present invention is not limited thereto. For example, the protective layer 271 may have a stacked-layer structure of an inorganic insulating film and an organic insulating film.

Note that in this specification, a nitride oxide refers to a compound that contains more nitrogen than oxygen. An oxynitride refers to a compound that contains more oxygen than nitrogen. The content of each element can be measured by Rutherford backscattering spectrometry (RBS), for example.

In the case where an indium gallium zinc oxide is used as the protective layer 271, the indium gallium zinc oxide can be processed by a wet etching method or a dry etching method. For example, in the case where IGZO is used as the protective layer 271, a chemical solution of oxalic acid, phosphoric acid, a mixed chemical solution (e.g., a mixed chemical solution of phosphoric acid, acetic acid, nitric acid, and water, which is also referred to as a mixed acid aluminum etchant), or the like can be used. Note that the volume ratio of phosphoric acid, acetic acid, nitric acid, and water mixed in the mixed acid aluminum etchant can be 53.3:6.7:3.3:36.7 or in the neighborhood thereof.

FIG. 26C illustrates an example different from the above. Specifically, in FIG. 26C, light-emitting elements 61W that emit white light are provided. The light-emitting element 61W includes an EL layer 262W between the conductive layer 261 functioning as a pixel electrode and the conductive layer 263 functioning as a common electrode.

The EL layer 262W can have, for example, a structure where two or more light-emitting layers that are selected so as to emit light of complementary colors are stacked. It is also possible to use a stacked EL layer in which a charge-generation layer is interposed between light-emitting layers.

FIG. 26C illustrates two light-emitting elements 61W side by side. A coloring layer 264G is provided above the left light-emitting element 61W. The coloring layer 264G functions as a band path filter transmitting green light. Similarly, a coloring layer 264B transmitting blue light is provided above the right light-emitting element 61W.

Here, the EL layer 262W and the conductive layer 263 functioning as a common electrode are each separated between adjacent two light-emitting elements 61W. This can prevent unintentional light emission from being caused by current flowing through the EL layers 262W of the two adjacent light-emitting elements 61W. In particular, when a stacked EL layer in which a charge-generation layer is provided between two light-emitting layers is used for the EL layer 262W, the effect of crosstalk is more significant as the resolution increases, i.e., as the distance between adjacent pixels decreases, leading to lower contrast. Thus, the above structure can achieve a display apparatus having both high resolution and high contrast.

The EL layer 262W and the conductive layer 263 functioning as a common electrode are preferably separated by a photolithography method. This can reduce an interval between light-emitting elements, achieving a display apparatus with a higher aperture ratio than that formed using, for example, a shadow mask such as a metal mask.

Note that in the case of a bottom-emission light-emitting element, a coloring layer is provided between the conductive layer 261 functioning as a pixel electrode and the insulating layer 363.

FIG. 26D illustrates an example different from the above. Specifically, in FIG. 26D, the insulating layer 272 is not provided between the light-emitting element 61G and the light-emitting element 61B. With such a structure, the display apparatus can have a high aperture ratio. When the insulating layer 272 is not provided, unevenness formed by the light-emitting elements 61 can be reduced, thereby improving the viewing angle of the display apparatus. Specifically, the viewing angle can be greater than or equal to 150° and less than 180°, preferably greater than or equal to 160° and less than 180°, further preferably greater than or equal to 160° and less than 180°.

The protective layer 271 covers the side surfaces of the EL layer 262G and the EL layer 262B. With this structure, impurities (typically, water or the like) can be inhibited from entering the EL layer 262G and the EL layer 262B through their side surfaces. In addition, leak current between adjacent light-emitting elements 61 is reduced, so that color saturation and contrast ratio are improved and power consumption is reduced.

In the structure illustrated in FIG. 26D, the conductive layer 261, the EL layer 262G, and the conductive layer 263 have substantially the same top surface shape. This structure can be formed in such a manner that the conductive layer 261, the EL layer 262G, and the conductive layer 263 are formed and collectively processed using a resist mask or the like. In this process, the EL layer 262G and the conductive layer 263 are processed using the conductive layer 263 as a mask, and thus this process can be called self-alignment patterning. Although the EL layer 262G is described here, the EL layer 262B can have a similar structure.

In FIG. 26D, a protective layer 273 is further provided over the protective layer 271. For example, the protective layer 271 is formed with an apparatus that can form a film with excellent coverage (typically, an ALD apparatus), and the protective layer 273 is formed with an apparatus that can form a film with coverage inferior to that of the protective layer 271 (typically, a sputtering apparatus), whereby a region 275 can be provided between the protective layer 271 and the protective layer 273. In other words, the region 275 is positioned between the EL layer 262G and the EL layer 262B.

Note that the region 275 includes, for example, one or more selected from air, nitrogen, oxygen, carbon dioxide, and Group 18 elements (typically, helium, neon, argon, xenon, krypton, and the like). Furthermore, for example, a gas used during formation of the protective layer 273 is sometimes included in the region 275. For example, in the case where the protective layer 273 is formed using a sputtering method, any one or more of the above-described Group 18 elements is sometimes included in the region 275. In the case where a gas is included in the region 275, the gas can be identified with a gas chromatography method or the like, for example. Alternatively, in the case where the protective layer 273 is formed using a sputtering method, a gas used in the sputtering is sometimes contained in the protective layer 273. In this case, an element such as argon is sometimes detected when the protective layer 273 is analyzed by an energy dispersive X-ray analysis (EDX analysis) or the like.

In the case where the refractive index of the region 275 is lower than the refractive index of the protective layer 271, light emitted from the EL layer 262G or the EL layer 262B is reflected at the interface between the protective layer 271 and the region 275. Thus, light emitted from the EL layer 262G or the EL layer 262B can be inhibited from entering an adjacent pixel in some cases. This can inhibit color mixture of light emitted from adjacent pixels and thus can improve the display quality of the display apparatus.

In the case of the structure illustrated in FIG. 26D, a region between the light-emitting element 61G and the light-emitting element 61B (hereinafter simply referred to as a distance between the light-emitting elements) can be narrow. Specifically, the distance between the light-emitting elements can be less than or equal to 1 m, preferably less than or equal to 500 nm, further preferably less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus includes a region where a distance between the side surface of the EL layer 262G and the side surface of the EL layer 262B is less than or equal to 1 m, preferably less than or equal to 0.5 μm (500 nm), further preferably less than or equal to 100 nm.

In the case where the region 275 includes a gas, for example, the light-emitting elements can be isolated from each other and color mixture of light from the light-emitting elements, crosstalk, or the like can be inhibited.

Alternatively, the region 275 may be filled with a filler. Examples of the filler include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. Alternatively, a photoresist may be used as the filler. The photoresist used as the filler may be a positive photoresist or a negative photoresist.

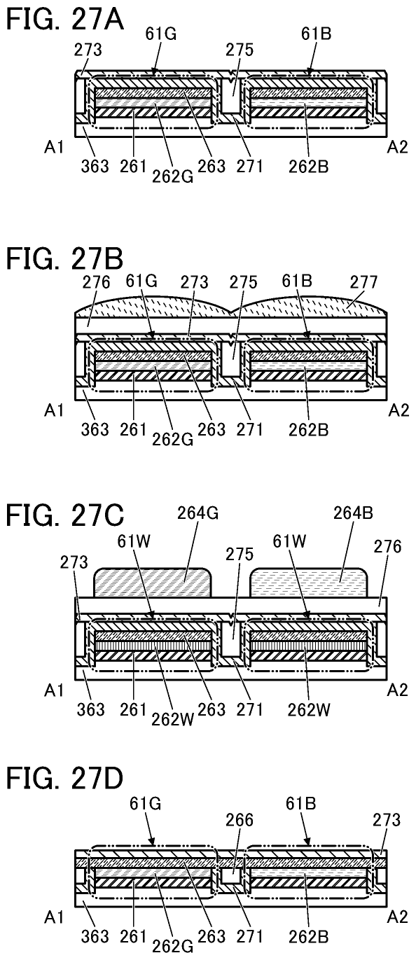

FIG. 27A illustrates an example different from the above. Specifically, the structure illustrated in FIG. 27A is different from the structure illustrated in FIG. 26D in the structure of the insulating layer 363. The insulating layer 363 has a depressed portion in its top surface that is formed by being partially etched when the light-emitting element 61G and the light-emitting element 61B are processed. In addition, the protective layer 271 is formed in the depressed portion. In other words, in a cross-sectional view, there is a region in which the bottom surface of the protective layer 271 is positioned below the bottom surface of the conductive layer 261. With the region, impurities (typically, water or the like) can be suitably inhibited from entering the light-emitting element 61G and the light-emitting element 61B from below. The depressed portion can be formed when impurities (also referred to as residue) that could be attached to the side surfaces of the light-emitting element 61G and the light-emitting element 61B in processing of the light-emitting elements are removed by wet etching or the like. After the residue is removed, the side surfaces of the light-emitting elements are covered with the protective layer 271, whereby a highly reliable display apparatus can be provided.

FIG. 27B illustrates an example different from the above. Specifically, the structure illustrated in FIG. 27B includes an insulating layer 276 and a microlens array 277 in addition to the structure illustrated in FIG. 27A. The insulating layer 276 functions as an adhesive layer. Note that in the case where the refractive index of the insulating layer 276 is lower than the refractive index of the microlens array 277, the microlens array 277 can condense light emitted from the light-emitting element 61G and the light-emitting element 61B. This can increase the light extraction efficiency of the display apparatus. In particular, this is suitable, because a user can see bright images when the user sees the display surface from the front of the display surface of the display apparatus. As the insulating layer 276, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-liquid-mixture-type resin may be used. An adhesive sheet or the like may be used.

FIG. 27C illustrates an example different from the above. Specifically, the structure illustrated in FIG. 27C includes two light-emitting elements 61W instead of the light-emitting element 61G and the light-emitting element 61B in the structure illustrated in FIG. 27A. In addition, the insulating layer 276 is provided over the two light-emitting elements 61W, and the coloring layer 264G and the coloring layer 264B are provided over the insulating layer 276. Specifically, the coloring layer 264G transmitting green light is provided at a position overlapping with the left light-emitting element 61W, and the coloring layer 264B transmitting blue light is provided at a position overlapping with the right light-emitting element 61W. The structure illustrated in FIG. 27C is also a variation example of the structure illustrated in FIG. 26C.

FIG. 27D illustrates an example different from the above. Specifically, in the structure illustrated in FIG. 27D, the protective layer 271 is provided to be adjacent to the side surfaces of the conductive layer 261, the EL layer 262G, and the EL layer 262B. The conductive layer 263 is provided as a continuous layer shared by the light-emitting elements. In the structure illustrated in FIG. 27D, a resin layer 266 is provided between the protective layer 271 and the conductive layer 263. Note that a region between the protective layer 271 and the conductive layer 263 may contain a gas.

The top surface of the resin layer 266 is preferably as flat as possible; however, the top surface of the resin layer 266 may be concave or convex depending on an uneven shape of a surface on which the resin layer 266 is formed and formation conditions of the resin layer 266.

An insulating layer containing an organic material can be suitably used as the resin layer 266. For example, the resin layer 266 can be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. The resin layer 266 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photosensitive resin can be used as the resin layer 266. A photoresist may be used as the photosensitive resin. As the photosensitive resin, a positive photosensitive material or a negative photosensitive material can be used.

With the use of the photosensitive resin, the resin layer 266 can be formed by only light exposure and developing steps. The resin layer 266 may be formed using a negative photosensitive resin (e.g., a resist material). In the case where an insulating layer containing an organic material is used as the resin layer 266, a material absorbing visible light is suitably used. When a material absorbing visible light is used for the resin layer 266, light emitted from the EL layer can be absorbed by the resin layer 266, whereby light that might leak to an adjacent EL layer (stray light) can be reduced. Accordingly, a display apparatus with high display quality can be provided.

The resin layer 266 may be formed using a colored material (e.g., a material containing a black pigment) to have a function of blocking stray light from an adjacent pixel and inhibiting color mixture.

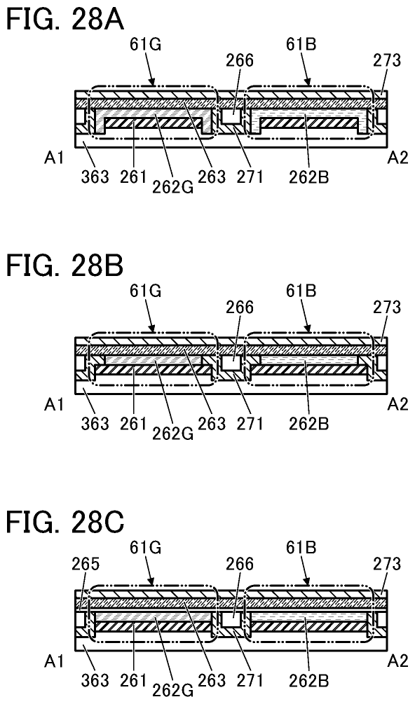

FIG. 28A illustrates an example different from the above. Specifically, in the structure illustrated in FIG. 28A, the width of the conductive layer 261 is smaller than that of the EL layer 262G. In addition, the width of the conductive layer 261 is smaller than that of the EL layer 262B. The protective layer 271 is provided to be adjacent to the side surfaces of the EL layer 262G and the EL layer 262B. The conductive layer 263 is provided as a continuous layer shared by the light-emitting elements. In the structure illustrated in FIG. 28A, the resin layer 266 is provided between the protective layer 271 and the conductive layer 263.

FIG. 28B illustrates an example different from the above. Specifically, in the structure illustrated in FIG. 28B, the width of the conductive layer 261 is larger than that of the EL layer 262G. In addition, the width of the conductive layer 261 is larger than that of the EL layer 262B. The protective layer 271 is provided to be adjacent to the side surfaces of the conductive layer 261, the EL layer 262G, and the EL layer 262B. The conductive layer 263 is provided as a continuous layer shared by the light-emitting elements. In the structure illustrated in FIG. 28B, the resin layer 266 is provided between the protective layer 271 and the conductive layer 263.

FIG. 28C illustrates an example different from the above. Specifically, in the structure illustrated in FIG. 28C, an organic layer 265 is provided between the conductive layer 263 and the EL layer 262G, the EL layer 262B, and the protective layer 271. The organic layer 265 can also be referred to as a common layer. The organic layer 265 and the conductive layer 263 are each provided as a continuous layer shared by the light-emitting elements. In the structure illustrated in FIG. 28C, the resin layer 266 is provided between the protective layer 271 and the organic layer 265.

The organic layer 265 can have a structure not including the light-emitting layer. For example, the organic layer 265 includes one or more of an electron-injection layer, an electron-transport layer, a hole-injection layer, and a hole-transport layer.

Here, the uppermost layer in the stacked-layer structure of each of the EL layer 262G and the EL layer 262B, i.e., the layer in contact with organic layer 265, is preferably a layer other than the light-emitting layer. For example, a structure is preferable where an electron-injection layer, an electron-transport layer, a hole-injection layer, a hole-transport layer, or a layer other than those is provided to cover the light-emitting layer so as to be in contact with the organic layer 265. When the top surface of the light-emitting layer is protected by another layer in fabricating each light-emitting element, the reliability of the light-emitting element can be improved.

A color purity of the emission color can be increased when the light-emitting element 61 has a micro-optical resonator (microcavity) structure. In order that the light-emitting element 61 has a microcavity structure, a product of a distance d between the conductive layer 261 and the conductive layer 263 and a refractive index n of the EL layer 262G or the EL layer 262B (optical path length) is set to m times greater than the half of a wavelength λ (m is an integer greater than or equal to 1). The distance d can be obtained by Formula (1) below.

$$\begin{matrix}[ Formula 1 ] & \\ d = \frac{m λ}{2 n} & ( 1 )\end{matrix}$$

According to Formula (1), in the light-emitting element 61 having the microcavity structure, the distance d is determined in accordance with the wavelength (emission color) of emitted light. The distance d corresponds to the thickness of the EL layer 262G or the EL layer 262B. Thus, the EL layer 262G is provided to be thicker than the EL layer 262B in some cases.

To be exact, the distance d is a distance from a reflection region in the conductive layer 261 functioning as a reflective electrode to a reflection region in the conductive layer 263 functioning as a semi-transmissive and semi-reflective electrode. For example, in the case where the conductive layer 261 is a stack of silver and ITO that is a transparent conductive film and the ITO is positioned on the EL layer 262G side or the EL layer 262B side, the distance d suitable for the emission color can be set by adjusting the thickness of the ITO. That is, even when the EL layer 262G and the EL layer 262B have the same thickness, the distance d suitable for the emission color can be obtained by adjusting the thickness of the ITO.

However, it is sometimes difficult to determine the exact position of the reflection region in each of the conductive layer 261 and the conductive layer 263. In this case, it is assumed that the effect of the microcavity structure can be obtained sufficiently with a certain position in each of the conductive layer 261 and the conductive layer 263 being supposed as the reflective region.

The light-emitting element 61 includes a hole-injection layer, a hole-transport layer, a light-emitting layer, an electron-transport layer, an electron-injection layer, and the like. The detailed structure example of the light-emitting element 61 will be described later. In order to increase the light extraction efficiency in the microcavity structure, the optical path length from the conductive layer 261 functioning as a reflective electrode to the light-emitting layer is preferably set to an odd multiple of λ/4. In order to achieve this optical path length, the thicknesses of the layers included in the light-emitting element 61 are preferably adjusted as appropriate.

In the case where light is emitted from the conductive layer 263 side, the reflectance of the conductive layer 263 is preferably higher than the transmittance thereof. The transmittance of the conductive layer 263 is preferably higher than or equal to 2% and lower than or equal to 50%, further preferably higher than or equal to 2% and lower than or equal to 30%, still further preferably higher than or equal to 2% and lower than or equal to 10%. When the transmittance of the conductive layer 263 is set low (the reflectance is set high), the effect of the microcavity structure can be enhanced.

Note that the pixel density of the display region of the display apparatus 100G is preferably higher than or equal to 100 ppi and lower than or equal to 10000 ppi, further preferably higher than or equal to 1000 ppi and lower than or equal to 10000 ppi. For example, the resolution may be higher than or equal to 2000 ppi and lower than or equal to 6000 ppi, or higher than or equal to 3000 ppi and lower than or equal to 5000 ppi.

Note that there is no particular limitation on the aspect ratio of the display region of the display apparatus 100G. The display region of the display apparatus 100G can have various aspect ratios, such as 1:1 (a square), 4:3, 16:9, and 16:10.

The diagonal size of the display region of the display apparatus 100G is at least greater than or equal to 0.1 inches and less than or equal to 100 inches and may be greater than or equal to 100 inches.

Note that in the case where the display apparatus 100G is used as a display apparatus for virtual reality (VR) or augmented reality (AR), the display region of the display apparatus 100G can have a diagonal size of greater than or equal to 0.1 inches and less than or equal to 5.0 inches, preferably greater than or equal to 0.5 inches and less than or equal to 2.0 inches. For example, the display region of the display apparatus 100G may have a diagonal size of 1.5 inches or around 1.5 inches. When the display region of the display apparatus 100G has a diagonal size of less than or equal to 2.0 inches, preferably, approximately 1.5 inches, the number of times of light exposure treatment using a light exposure apparatus (typified by a scanner apparatus) can be one; thus, the productivity of a manufacturing process can be improved.

### Structure Example of Light-Emitting Element

A light-emitting element (also referred to as light-emitting device) that can be used for a semiconductor device of one embodiment of the present invention will be described.

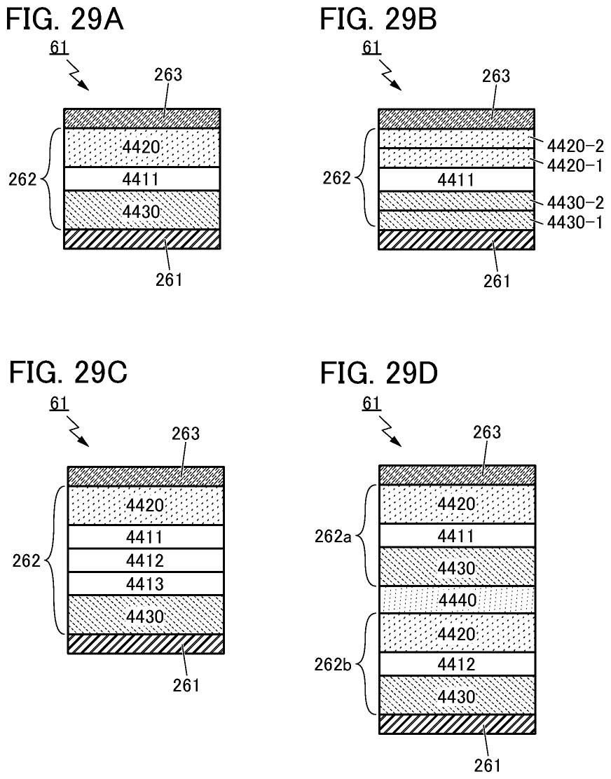

As illustrated in FIG. 29A, the light-emitting element 61 includes an EL layer 262 between a pair of electrodes (the conductive layer 261 and the conductive layer 263). The EL layer 262 can be formed of a plurality of layers such as a layer 4420, a light-emitting layer 4411, and a layer 4430. The layer 4420 can include, for example, a layer containing a substance with a high electron-injection property (an electron-injection layer) and a layer containing a substance with a high electron-transport property (an electron-transport layer). The light-emitting layer 4411 contains alight-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430, which are provided between the pair of electrodes, can function as a single light-emitting unit, and the structure in FIG. 29A is referred to as a single structure in this specification and the like.

FIG. 29B illustrates a variation example of the EL layer 262 included in the light-emitting element 61 illustrated in FIG. 29A. Specifically, the light-emitting element 61 illustrated in FIG. 29B includes a layer 4430-1 over the conductive layer 261, a layer 4430-2 over the layer 4430-1, the light-emitting layer 4411 over the layer 4430-2, a layer 4420-1 over the light-emitting layer 4411, a layer 4420-2 over the layer 4420-1, and the conductive layer 263 over the layer 4420-2. For example, when the conductive layer 261 is a positive electrode and the conductive layer 263 is a negative electrode, the layer 4430-1 functions as a hole-injection layer, the layer 4430-2 functions as a hole-transport layer, the layer 4420-1 functions as an electron-transport layer, and the layer 4420-2 functions as an electron-injection layer. Alternatively, when the conductive layer 261 is a negative electrode and the conductive layer 263 is a positive electrode, the layer 4430-1 functions as an electron-injection layer, the layer 4430-2 functions as an electron-transport layer, the layer 4420-1 functions as a hole-transport layer, and the layer 4420-2 functions as a hole-injection layer. With such a layered structure, carriers can be efficiently injected to the light-emitting layer 4411, and the efficiency of the recombination of carriers in the light-emitting layer 4411 can be enhanced.

Note that the structure where a plurality of light-emitting layers (the light-emitting layer 4411, a light-emitting layer 4412, and a light-emitting layer 4413) are provided between the layer 4420 and the layer 4430 as illustrated in FIG. 29C is also an example of the single structure.

The structure where a plurality of light-emitting units (an EL layer 262a and an EL layer 262b) are connected in series with an intermediate layer (charge-generation layer) 4440 therebetween as illustrated in FIG. 29D is referred to as a tandem structure or a stack structure in this specification and the like. Note that the tandem structure enables a light-emitting element capable of high-luminance light emission.

In the case where the light-emitting element 61 has the tandem structure illustrated in FIG. 29D, the EL layer 262a and the EL layer 262b may emit light of the same color. For example, both the EL layer 262a and the EL layer 262b may emit green light. Note that in the case where the display region of the display apparatus includes two or more subpixels of R, G, and B and each of the subpixels includes a light-emitting element, the tandem structure may be employed for the light-emitting element of each of the subpixels. Specifically, the EL layer 262a and the EL layer 262b in the subpixel of R each contain a material capable of emitting red light, the EL layer 262a and the EL layer 262b in the subpixel of G each contain a material capable of emitting green light, and the EL layer 262a and the EL layer 262b in the subpixel of B each contain a material capable of emitting blue light. In other words, the light-emitting layer 4411 and the light-emitting layer 4412 may contain the same material. When the EL layer 262a and the EL layer 262b emit light of the same color, the current density per unit emission luminance can be reduced. Thus, the reliability of the light-emitting element 61 can be increased.

The emission color of the light-emitting element can be red, green, blue, cyan, magenta, yellow, white, or the like depending on the material contained in the EL layer 262. Furthermore, the color purity can be further increased when the light-emitting element has a microcavity structure.

The light-emitting layer may contain two or more of light-emitting substances that emit light of R (red), G (green), B (blue), Y (yellow), O (orange), and the like. The light-emitting element that emits white light preferably contains two or more kinds of light-emitting substances in the light-emitting layer. To obtain white light emission, two or more kinds of light-emitting substances are selected such that their emission colors are complementary. For example, when an emission color of a first light-emitting layer and an emission color of a second light-emitting layer have a relationship of complementary colors, it is possible to obtain a light-emitting element which emits white light as a whole. This is similar in a light-emitting element including three or more light-emitting layers.

The light-emitting layer preferably contains two or more selected from light-emitting substances that emit light of red (R), green (G), blue (B), yellow (Y), orange (O), and the like. Alternatively, the light-emitting layer preferably contains two or more light-emitting substances that emit light containing two or more of spectral components of R, G, and B.

As a light-emitting substance, a substance that emits fluorescent light (a fluorescent material), a substance that emits phosphorescent light (a phosphorescent material), an inorganic compound (a quantum dot material or the like), a substance that emits thermally activated delayed fluorescent light (a Thermally Activated Delayed Fluorescence (TADF) material), and the like can be given. Note that as a TADF material, a material that is in a thermal equilibrium state between a singlet excited state and a triplet excited state may be used. Since such a TADF material enables a short emission lifetime (excitation lifetime), an efficiency decrease of a light-emitting element in a high-luminance region can be inhibited.

The light-emitting device includes an EL layer between a pair of electrodes. In this specification and the like, one of the pair of electrodes may be referred to as a pixel electrode and the other may be referred to as a common electrode.

One of the pair of electrodes of the light-emitting device functions as an anode and the other electrode functions as a cathode. The case where the pixel electrode functions as an anode and the common electrode functions as a cathode is described below as an example.

A conductive film that transmits visible light is used as the electrode through which light is extracted, which is either the pixel electrode or the common electrode. A conductive film that reflects visible light is preferably used as the electrode through which light is not extracted.

As a material that forms the pair of electrodes (the pixel electrode and the common electrode) of the light-emitting device, a metal, an alloy, an electrically conductive compound, a mixture thereof, and the like can be used as appropriate. Specific examples include indium tin oxide (In—Sn oxide, also referred to as ITO), In—Si—Sn oxide (also referred to as ITSO), indium zinc oxide (In—Zn oxide), In—W—Zn oxide, an alloy containing aluminum (an aluminum alloy) such as an alloy of aluminum, nickel, and lanthanum (Al—Ni—La), and an alloy of silver, palladium, and copper (Ag—Pd—Cu, also referred to as APC). In addition, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use a Group 1 element or a Group 2 element in the periodic table, which is not described above (e.g., lithium (Li), cesium (Cs), calcium (Ca), or strontium (Sr)), a rare earth metal such as europium (Eu) or ytterbium (Yb), an alloy containing an appropriate combination of any of these elements, graphene, or the like.

The light-emitting devices preferably employ a microcavity structure. Therefore, one of the pair of electrodes of the light-emitting device is preferably an electrode having properties of transmitting and reflecting visible light (a semi-transmissive and semi-reflective electrode), and the other is preferably an electrode having a property of reflecting visible light (a reflective electrode). When the light-emitting device has a microcavity structure, light obtained from the light-emitting layer can be resonated between the electrodes, whereby light emitted from the light-emitting device can be intensified.

The transparent electrode has a light transmittance higher than or equal to 40%. For example, an electrode having a visible light (light with wavelengths greater than or equal to 400 nm and less than 750 nm) transmittance higher than or equal to 40% is preferably used in the light-emitting device. The visible light reflectance of the semi-transmissive and semi-reflective electrode is higher than or equal to 10% and lower than or equal to 95%, preferably higher than or equal to 30% and lower than or equal to 80%. The visible light reflectance of the reflective electrode is higher than or equal to 40% and lower than or equal to 100%, preferably higher than or equal to 70% and lower than or equal to 100%. These electrodes preferably have a resistivity lower than or equal to 1×10⁻² Ωcm.

The light-emitting layer is a layer containing a light-emitting substance. The light-emitting layer can contain one or more kinds of light-emitting substances. As the light-emitting substance, a substance that exhibits an emission color of blue, violet, bluish violet, green, yellowish green, yellow, orange, red, or the like is used as appropriate. Alternatively, as the light-emitting substance, a substance that emits near-infrared light can be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (in particular, an iridium complex) having a 4H-triazole skeleton, a 1H-triazole skeleton, an imidazole skeleton, a pyrimidine skeleton, a pyrazine skeleton, or a pyridine skeleton; an organometallic complex (in particular, an iridium complex) having a phenylpyridine derivative including an electron-withdrawing group as a ligand; a platinum complex; and a rare earth metal complex.

The light-emitting layer may contain one or more kinds of organic compounds (e.g., a host material and an assist material) in addition to the light-emitting substance (a guest material). As one or more kinds of organic compounds, one or both of the hole-transport material and the electron-transport material can be used. Alternatively, as one or more kinds of organic compounds, a bipolar material or a TADF material may be used.

The light-emitting layer preferably contains a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from an exciplex to a light-emitting substance (a phosphorescent material). When a combination of materials is selected to form an exciplex that exhibits light emission whose wavelength overlaps with the wavelength of the lowest-energy-side absorption band of the light-emitting substance, energy can be transferred smoothly and light emission can be obtained efficiently. With this structure, high efficiency, low-voltage driving, and a long lifetime of a light-emitting device can be achieved at the same time.

The hole-injection layer is a layer that injects holes from an anode to a hole-transport layer and contains a material with a high hole-injection property. Examples of the material with a high hole-injection property include an aromatic amine compound, and a composite material containing a hole-transport material and an acceptor material (an electron-accepting material).

The hole-transport layer is a layer that transports holes, which are injected from the anode by the hole-injection layer, to the light-emitting layer. The hole-transport layer is a layer containing a hole-transport material. As the hole-transport material, a substance having a hole mobility greater than or equal to 1×10⁻⁶ cm²/Vs is preferable. Note that other substances can also be used as long as they have a property of transporting more holes than electrons. As the hole-transport material, materials with a high hole-transport property, such as a π-electron rich heteroaromatic compound (e.g., a carbazole derivative, a thiophene derivative, and a furan derivative) and an aromatic amine (a compound having an aromatic amine skeleton), are preferable.

The electron-transport layer is a layer that transports electrons, which are injected from a cathode by the electron-injection layer, to the light-emitting layer. The electron-transport layer is a layer containing an electron-transport material. As the electron-transport material, a substance having an electron mobility greater than or equal to 1×10⁻⁶ cm²Vs is preferable. Note that other substances can also be used as long as they have a property of transporting more electrons than holes. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

The electron-transport layer may have a stacked-layer structure, and may include a hole-blocking layer, in contact with the light-emitting layer, which blocks holes moving from the anode side to the cathode side through the light-emitting layer.

The electron-injection layer is a layer that injects electrons from the cathode to the electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato)lithium (abbreviation: Liq), 2-(2-pyridyl)phenolatolithium (abbreviation: LiPP), 2-(2-pyridyl)-3-pyridinolato lithium (abbreviation: LiPPy), 4-phenyl-2-(2-pyridyl)phenolatolithium (abbreviation: LiPPP), lithium oxide (LiOₓ), or cesium carbonate, for example. The electron-injection layer may have a stacked-layer structure of two or more layers. In the stacked-layer structure, for example, lithium fluoride can be used for the first layer and ytterbium can be used for the second layer.

Alternatively, the electron-injection layer may be formed using an electron-transport material. For example, a compound having an unshared electron pair and an electron deficient heteroaromatic ring can be used as the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) of the organic compound having an unshared electron pair is preferably greater than or equal to −3.6 eV and less than or equal to −2.3 eV. In general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-bis(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used for the organic compound having an unshared electron pair. Note that NBPhen has a higher glass transition temperature (Tg) than BPhen and thus has high heat resistance.

In the case of fabricating a tandem light-emitting device, an intermediate layer is provided between two light-emitting units. The intermediate layer has a function of injecting electrons into one of the two light-emitting units and injecting holes to the other when voltage is applied between the pair of electrodes.

For example, the intermediate layer can be suitably formed using a material that can be used for the electron-injection layer, such as lithium. Alternatively, as another example, a material that can be used for the hole-injection layer can be suitably used for the intermediate layer. Alternatively, a layer containing a hole-transport material and an acceptor material (an electron-accepting material) can be used for the intermediate layer. Alternatively, a layer containing an electron-transport material and a donor material can be used for the intermediate layer. Forming the intermediate layer including such a layer can suppress an increase in the driving voltage that would be caused when the light-emitting units are stacked.

This embodiment can be combined with the other embodiments as appropriate.

### Embodiment 3

In this embodiment, a metal oxide (also referred to as an oxide semiconductor) that can be used for the OS transistor described in the above embodiment will be described.

The band gap of a metal oxide used for the OS transistor is preferably greater than or equal to 2 eV, further preferably greater than or equal to 2.5 eV. With use of a metal oxide having a wide bandgap, the off-state current of the OS transistor can be reduced.

The metal oxide used for the OS transistor preferably contains at least indium or zinc, and further preferably contains indium and zinc. A metal oxide preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. In particular, M is preferably one or more kinds selected from gallium, aluminum, yttrium, and tin, and is further preferably gallium. Hereinafter, a metal oxide containing indium, M, and zinc is referred to as In-M-Zn oxide in some cases.

It is particularly preferable to use an oxide containing indium (In), gallium (Ga), and zinc (Zn) (also referred to as IGZO) for the semiconductor layer of the transistor. Alternatively, an oxide containing indium (In), aluminum (Al), and zinc (Zn) (also referred to as IAZO) may be used for the semiconductor layer of the transistor. Further alternatively, an oxide containing indium (In), aluminum (Al), gallium (Ga), and zinc (Zn) (also referred to as IAGZO) may be used for the semiconductor layer.

When a metal oxide is an In-M-Zn oxide, the atomic proportion of In is preferably higher than or equal to the atomic proportion of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of ±30% of an intended atomic ratio. By increasing the atomic proportion of indium in the metal oxide, the on-state current, field-effect mobility, or the like of the transistor can be improved.

For example, when the atomic ratio is described as In:M:Zn=4:2:3 or a composition in the neighborhood thereof, the case is included where M is greater than or equal to 1 and less than or equal to 3 and Zn is greater than or equal to 2 and less than or equal to 4 with In being 4. When the atomic ratio is described as In:M:Zn=5:1:6 or a composition in the neighborhood thereof, the case is included where M is greater than 0.1 and less than or equal to 2 and Zn is greater than or equal to 5 and less than or equal to 7 with In being 5. When the atomic ratio is described as In:M:Zn=1:1:1 or a composition in the neighborhood thereof, the case is included where M is greater than 0.1 and less than or equal to 2 and Zn is greater than 0.1 and less than or equal to 2 with In being 1.

The atomic proportion of In may be less than that of Min the In-M-Zn oxide. Examples of the atomic ratio of the metal elements in such an In-M-Zn oxide include In:M:Zn=1:3:2 or a composition in the neighborhood thereof, In:M:Zn=1:3:3 or a composition in the neighborhood thereof, and In:M:Zn=1:3:4 or a composition in the neighborhood thereof. By increasing the atomic proportion of Min the metal oxide, the band gap of the In-M-Zn oxide is further increased; thus, the resistance to a negative bias stress test with light irradiation can be improved. Specifically, the amount of change in the threshold voltage or the amount of change in the shift voltage (Vsh) measured in a NBTIS (Negative Bias Temperature Illumination Stress) test of the transistor can be decreased. Note that the shift voltage (Vsh) is defined as Vg at which, in a drain current (Id)-gate voltage (Vg) curve of a transistor, the tangent at a point where the slope of the curve is the steepest intersects the straight line of Id=1 pA.

The metal oxide can be formed by a sputtering method, a chemical vapor deposition (CVD) method such as a metal organic chemical vapor deposition (MOCVD) method, an atomic layer deposition (ALD) method, or the like.

Hereinafter, an oxide containing indium (In), gallium (Ga), and zinc (Zn) is described as an example of the metal oxide. Note that an oxide containing indium (In), gallium (Ga), and zinc (Zn) may be referred to as an In—Ga—Zn oxide.

### <Classification of Crystal Structure>

Amorphous (including a completely amorphous structure), CAAC (c-axis-aligned crystalline), nc (nanocrystalline), CAC (cloud-aligned composite), single crystal, and polycrystalline (poly crystal) structures can be given as examples of a crystal structure of an oxide semiconductor.

Note that a crystal structure of a film or a substrate can be evaluated with an X-ray diffraction (XRD) spectrum. For example, evaluation is possible using an XRD spectrum that is obtained by GIXD (Grazing-Incidence XRD) measurement. Note that a GIXD method is also referred to as a thin film method or a Seemann-Bohlin method. Hereinafter, an XRD spectrum obtained from GIXD measurement is simply referred to as an XRD spectrum in some cases.

For example, the XRD spectrum of a quartz glass substrate shows a peak with a substantially bilaterally symmetrical shape. On the other hand, the peak of the XRD spectrum of the In—Ga—Zn oxide film having a crystal structure has a bilaterally asymmetrical shape. The bilaterally asymmetrical peak of the XRD spectrum clearly shows the existence of crystals in the film or the substrate. In other words, the crystal structure of the film or the substrate cannot be regarded as “amorphous” unless it has a bilaterally symmetrical peak in the XRD spectrum.

A crystal structure of a film or a substrate can also be evaluated with a diffraction pattern obtained by a nanobeam electron diffraction (NBED) method (such a pattern is also referred to as a nanobeam electron diffraction pattern). For example, a halo pattern is observed in the diffraction pattern of the quartz glass substrate, which indicates that the quartz glass substrate is in an amorphous state. Furthermore, not a halo pattern but a spot-like pattern is observed in the diffraction pattern of the In—Ga—Zn oxide film formed at room temperature. Thus, it is suggested that the In—Ga—Zn oxide film formed at room temperature is in an intermediate state, which is neither a single crystal nor polycrystal nor an amorphous state, and it cannot be concluded that In—Ga—Zn oxide film is in an amorphous state.

### <<Structure of Oxide Semiconductor>>

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the CAAC-OS and the nc-OS. Other examples of the non-single-crystal oxide semiconductors include a polycrystalline oxide semiconductor, an amorphous-like oxide semiconductor (a-like OS), and an amorphous oxide semiconductor.

Here, the CAAC-OS, the nc-OS, and the a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the orientation of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more minute crystals (crystals each of which has a maximum diameter of less than 10 nm). In the case where the crystal region is formed of one minute crystal, the maximum diameter of the crystal region is less than 10 nm. In the case where the crystal region is formed of a large number of fine crystals, the maximum diameter of the crystal region may be approximately several tens of nanometers.

In the case of an In—Ga—Zn oxide, the CAAC-OS tends to have a layered crystal structure (also referred to as a layered structure) in which a layer containing indium (In) and oxygen (hereinafter, an In layer) and a layer containing gallium (Ga), zinc (Zn), and oxygen (hereinafter, a (Ga,Zn) layer) are stacked. Note that indium and gallium can be replaced with each other. Therefore, indium may be contained in the (Ga,Zn) layer. In addition, gallium may be contained in the In layer. Note that zinc may be contained in the In layer. Such a layered structure is observed as a lattice image in a high-resolution TEM (Transmission Electron Microscope) image, for example.

When the CAAC-OS film is subjected to structural analysis by out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 20) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of an incident electron beam passing through a sample (also referred to as a direct spot) as a symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (also referred to as grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure where a clear grain boundary is observed is what is called polycrystal. It is highly probable that the crystal grain boundary becomes a recombination center and traps carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, it can be said that a reduction in electron mobility due to the crystal grain boundary is unlikely to occur. Moreover, since the crystallinity of an oxide semiconductor might be decreased by entry of impurities, formation of defects, or the like, the CAAC-OS can be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor depending on the analysis method. For example, when an nc-OS film is subjected to structural analysis by out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., larger than or equal to 1 nm and smaller than or equal to 30 nm).

### [A-Like OS]

The a-like OS is an oxide semiconductor having a structure between those of the nc-OS and the amorphous oxide semiconductor. The a-like OS has a void or a low-density region. That is, the a-like OS has lower crystallinity than the nc-OS and the CAAC-OS. Moreover, the a-like OS has a higher hydrogen concentration in the film than the nc-OS and the CAAC-OS.

### <<Structure of Oxide Semiconductor>>

Next, the above-described CAC-OS will be described in detail. Note that the CAC-OS relates to the material composition.

### [CAC-OS]

The CAC-OS refers to one composition of a material in which elements included in a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in an In—Ga—Zn oxide are denoted with [In], [Ga], and [Zn], respectively. For example, the first region in the CAC-OS in the In—Ga—Zn oxide is a region having [In] higher than [In] in the composition of the CAC-OS film. Moreover, the second region is a region having [Ga] higher than [Ga] in the composition of the CAC-OS film. Alternatively, for example, the first region is a region having [In] higher than [In] in the second region and [Ga] lower than [Ga] in the second region. Moreover, the second region is a region having [Ga] higher than [Ga] in the first region and [In] lower than [In] in the first region.

Specifically, the first region includes indium oxide, indium zinc oxide, or the like as its main component. The second region includes gallium oxide, gallium zinc oxide, or the like as its main component. That is, the first region can be rephrased as a region containing In as its main component. The second region can be rephrased as a region containing Ga as its main component.

Note that a clear boundary between the first region and the second region cannot be observed in some cases.

In addition, in a material composition of a CAC-OS in an In—Ga—Zn oxide that contains In, Ga, Zn, and O, there are regions containing Ga as a main component in part of the CAC-OS and regions containing In as a main component in another part of the CAC-OS. These regions each form a mosaic pattern and are randomly present. Thus, it is suggested that the CAC-OS has a structure where metal elements are unevenly distributed.

The CAC-OS can be formed by a sputtering method under a condition where a substrate is not heated, for example. Furthermore, in the case where the CAC-OS is formed by a sputtering method, any one or more selected from an inert gas (typically, argon), an oxygen gas, and a nitrogen gas is used as a deposition gas. The proportion of the flow rate of an oxygen gas in the total flow rate of the deposition gas during deposition is preferably as low as possible. For example, the proportion of the flow rate of an oxygen gas in the total flow rate of the deposition gas during deposition is preferably higher than or equal to 0% and lower than 30%, further preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure where the region containing In as its main component (the first region) and the region containing Ga as its main component (the second region) are unevenly distributed and mixed.

Here, the first region is a region having higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

The second region is a region having a higher insulating property than the first region. In other words, when the second regions are distributed in a metal oxide, leakage current can be inhibited.

Thus, in the case where a CAC-OS is used for a transistor, by the complementary action of the conductivity due to the first region and the insulating property due to the second region, the CAC-OS can have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when a CAC-OS is used for a transistor, a high on-state current (Iₒₙ), a high field-effect mobility (μ), and favorable switching operation can be achieved.

A transistor using the CAC-OS has high reliability. Thus, the CAC-OS is most suitable for a variety of semiconductor devices such as a display apparatus.

An oxide semiconductor has various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### <Transistor Including Oxide Semiconductor>

Next, the case where the above oxide semiconductor is used for a transistor will be described.

When the above oxide semiconductor is used for a transistor, a transistor with high field-effect mobility can be achieved. In addition, a transistor with high reliability can be achieved.

An oxide semiconductor having a low carrier concentration is preferably used for a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon. Note that an impurity in an oxide semiconductor refers to, for example, elements other than the main components of the oxide semiconductor. For example, an element with a concentration lower than 0.1 atomic % can be regarded as an impurity.

### <Impurity>

Here, the influence of each impurity in the oxide semiconductor will be described.

When silicon or carbon, which is one of Group 14 elements, is contained in the oxide semiconductor, defect states are formed in the oxide semiconductor. Thus, the concentration of silicon or carbon (the concentration obtained by secondary ion mass spectrometry (SIMS)) in the semiconductor layer is set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the oxide semiconductor, which is obtained by SIMS, is lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. When nitrogen is contained in the oxide semiconductor, a trap state is sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. For this reason, hydrogen in the oxide semiconductor is preferably reduced as much as possible. Specifically, the concentration of hydrogen in the oxide semiconductor, which is measured by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

At least part of this embodiment can be implemented in combination with the other embodiments described in this specification as appropriate.

### Embodiment 4

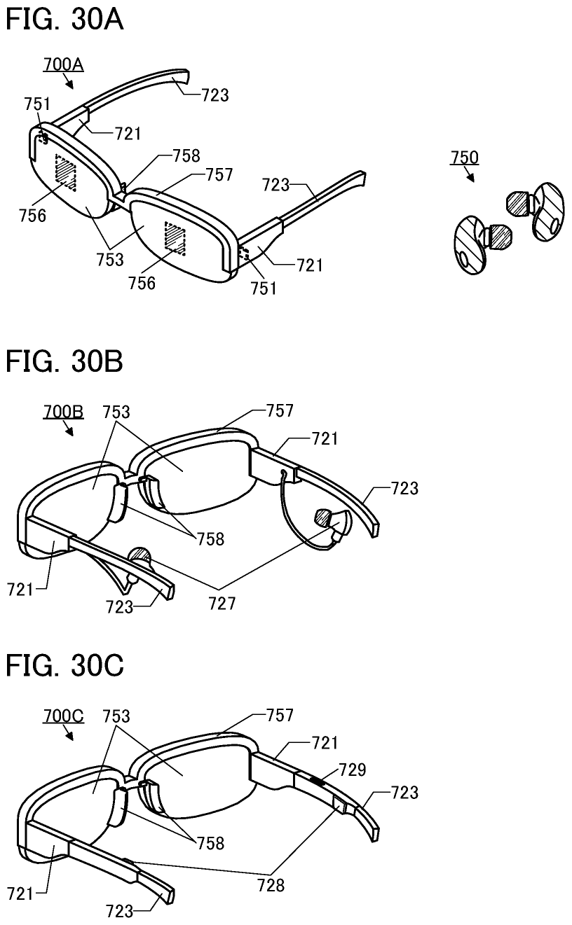

In this embodiment, electronic devices of embodiments of the present invention will be described with reference to FIG. 30 to FIG. 32.

Electronic devices of this embodiment each include the display apparatus of one embodiment of the present invention in a display portion. The display apparatus of one embodiment of the present invention has high display quality and low power consumption. In addition, the display apparatus of one embodiment of the present invention can be easily increased in resolution and definition. Thus, the display apparatus of one embodiment of the present invention can be used for a display portion of a variety of electronic devices.

Examples of the electronic devices include a digital camera, a digital video camera, a digital photo frame, a cellular phone, a portable game machine, a portable information terminal, and an audio reproducing device, in addition to electronic devices provided with comparatively large screens, such as a television device, a desktop or laptop personal computer, a monitor for a computer or the like, digital signage, and a large game machine such as a pachinko machine.

In particular, the display apparatus of one embodiment of the present invention can have high resolution, and thus can be suitably used for an electronic device having a relatively small display portion. Examples of such an electronic device include a watch-type or a bracelet-type information terminal device (wearable device), and a wearable device worn on a head, such as a device for VR such as a head-mounted display, a glasses-type device for AR, and a device for MR.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display apparatus of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. With the use of such a display apparatus having one or both of high definition and high resolution, the electronic device can provide higher realistic sensation, sense of depth, and the like in personal use such as portable use and home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

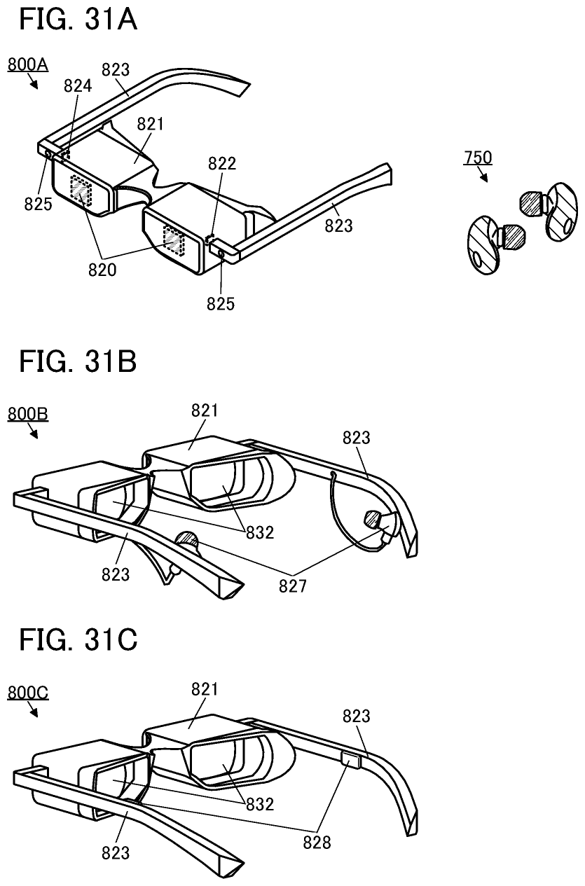

Examples of head-mounted wearable devices will be described with reference to FIG. 30A to FIG. 30C and FIG. 31A to FIG. 31C. These wearable devices have one or both of a function of displaying AR contents and a function of displaying VR contents. Note that these wearable devices may have a function of displaying SR or MR contents, in addition to AR and VR contents. The electronic device having a function of displaying contents of AR, VR, SR, MR, or the like enables the user to reach a higher level of immersion.

An electronic device 700A illustrated in FIG. 30A, an electronic device 700B illustrated in FIG. 30B, and an electronic device 700C illustrated in FIG. 30C each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic devices can perform display with extremely high resolution. As the optical member 753, the optical element described in the above embodiment can be used.

The electronic device 700A, the electronic device 700B, and the electronic device 700C can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A, the electronic device 700B, and the electronic device 700C are electronic devices capable of AR display.

In the electronic device 700A, the electronic device 700B, and the electronic device 700C, a camera capable of capturing images of the front side may be provided as the image capturing portion. Furthermore, when the electronic device 700A, the electronic device 700B, and the electronic device 700C are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of the wireless communication device or in addition to the wireless communication device, a connector that can be connected to a cable for supplying a video signal and a power supply potential may be provided.

The electronic device 700A, the electronic device 700B, and the electronic device 700C are provided with a battery so that they can be charged wirelessly and/or by wire.

A touch sensor module may be provided in the housing 721. The touch sensor module has a function of detecting a touch on the outer surface of the housing 721. A tap operation, a slide operation, or the like by the user can be detected with the touch sensor module, whereby a variety of processing can be executed. For example, processing such as pausing or restarting a video can be executed by a tap operation, and processing such as fast-forwarding or fast-rewinding can be executed by a slide operation. When the touch sensor module is provided in each of the two housings 721, the range of the operation can be increased.

Various touch sensors can be used as the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic device 800A illustrated in FIG. 31A, an electronic device 800B illustrated in FIG. 31B, and an electronic device 800C illustrated in FIG. 31C each include a pair of display portions 820, a housing 821, a communication portion 822, a pair of mounting portions 823, a control portion 824, a pair of image capturing portions 825, and a pair of lenses 832.

The display apparatus of one embodiment of the present invention can be used for the display portions 820. Thus, the electronic devices can perform display with extremely high resolution. Such electronic devices can provide an enhanced sense of immersion to the user. As the lens 832, the optical element described in the above embodiment can be used.

The display portions 820 are positioned inside the housing 821 so as to be seen through the lenses 832. When the pair of display portions 820 display different images, three-dimensional display using parallax can be performed.

The electronic device 800A, the electronic device 800B, and the electronic device 800C can be regarded as electronic devices for VR. The user who wears the electronic device 800A, the electronic device 800B, or the electronic device 800C can see images displayed on the display portions 820 through the lenses 832.

The electronic device 800A, the electronic device 800B, and the electronic device 800C preferably include a mechanism for adjusting the lateral positions of the lenses 832 and the display portions 820 so that the lenses 832 and the display portions 820 are positioned optimally in accordance with the positions of the user's eyes. Moreover, a mechanism for adjusting focus by changing the distance between the lenses 832 and the display portions 820 is preferably included.

The electronic device 800A, the electronic device 800B, or the electronic device 800C can be mounted on the user's head with the mounting portions 823. FIG. 31A and the like illustrate examples where the mounting portion 823 has a shape like a temple (also referred to as a joint or the like) of glasses; however, one embodiment of the present invention is not limited thereto. The mounting portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example of including the image capturing portion 825 is described here, a range sensor (hereinafter also referred to as a sensing portion) that is capable of measuring a distance from an object just needs to be provided. In other words, the image capturing portion 825 is one embodiment of the sensing portion. As the sensing portion, an image sensor or a distance image sensor such as LIDAR (Light Detection and Ranging) can be used, for example. By using images obtained by the camera and images obtained by the distance image sensor, more information can be obtained and a gesture operation with higher accuracy is possible.

The electronic device 800A, the electronic device 800B, and the electronic device 800C may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not illustrated) and has a wireless communication function. The earphones 750 can receive information (e.g., audio data) from the electronic device with the wireless communication function. For example, the electronic device 700A illustrated in FIG. 30A has a function of transmitting information to the earphones 750 with the wireless communication function. As another example, the electronic device 800A in FIG. 31A has a function of transmitting information to the earphones 750 with the wireless communication function.

The electronic device may include an earphone portion. The electronic device 700B illustrated in FIG. 30B includes earphone portions 727. For example, the earphone portion 727 and the control portion can be connected to each other by wire. Part of a wiring that connects the earphone portion 727 and the control portion may be placed inside the housing 721 or the mounting portion 723.

Similarly, the electronic device 800B illustrated in FIG. 31B includes earphone portions 827. For example, the earphone portion 827 and the control portion 824 can be connected to each other by wire. Part of a wiring that connects the earphone portion 827 and the control portion 824 may be placed inside the housing 821 or the mounting portion 823. Alternatively, the earphone portions 827 and the mounting portions 823 may include magnets. This is preferable because the earphone portions 827 can be fixed to the mounting portions 823 with magnetic force and thus can be easily housed.

The electronic device of one embodiment of the present invention may include a vibration mechanism that functions as bone-conduction earphones. For example, any one or more of the display portion 820, the housing 821, and the mounting portion 823 can include the vibration mechanism. Thus, without additionally requiring an audio device such as headphones, earphones, or a speaker, the user can enjoy video and sound only by wearing the electronic device.

For example, the electronic device 700C illustrated in FIG. 30C includes a bone-conduction speaker 728 and an operation button 729. The operation button 729 can be provided with a volume control button. Although FIG. 30C illustrates a structure where one operation button 729 is provided, two or more operation buttons 729 may be provided.

Similarly, for example, the electronic device 800C illustrated in FIG. 31C includes a bone-conduction speaker 828. Although not illustrated in FIG. 31C, the electronic device 800C may include an operation button such as a volume control button.

Note that the electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A, the electronic device 700B, and the electronic device 700C) and the goggles-type device (e.g., the electronic device 800A, the electronic device 800B, and the electronic device 800C) are preferable as the electronic device of one embodiment of the present invention.

The electronic device of one embodiment of the present invention can transmit information to earphones by wire or wirelessly.

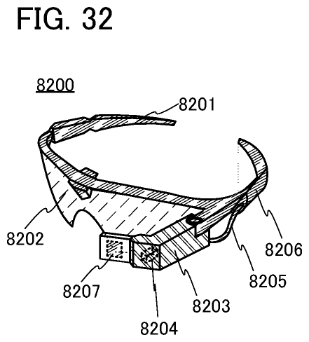

FIG. 32 is a diagram illustrating an appearance of a head-mounted display 8200.

The head-mounted display 8200 includes a mounting portion 8201, a lens 8202, a main body 8203, a display apparatus 8204, a cable 8205, and the like. A battery 8206 is incorporated in the mounting portion 8201.

The head-mounted display 8200 includes one display region 8207 on the left eye side. Note that the main body 8203 may be placed on the right eye side so that the display region 8207 is positioned on the right eye side.

The cable 8205 supplies electric power from the battery 8206 to the main body 8203. The main body 8203 includes a wireless receiver or the like to receive video information and display it on the display region 8207. The main body 8203 includes a camera, and information on the movement of the eyeballs or the eyelids of the user can be used as an input means.

The mounting portion 8201 may include a plurality of electrodes capable of sensing current flowing accompanying with the movement of the user's eyeball at a position in contact with the user to recognize the user's sight line. The mounting portion 8201 may also have a function of monitoring the user's pulse with the use of current flowing through the electrodes. The mounting portion 8201 may include a variety of sensors such as a temperature sensor, a pressure sensor, and an acceleration sensor to have a function of displaying the user's biological information on the display region 8207, a function of changing a video displayed on the display region 8207 in accordance with the movement of the user's head, and the like.

The display apparatus of one embodiment of the present invention can be used as the display apparatus 8204. As the lens 8202, the optical element described in the above embodiment can be used.

This embodiment can be combined with the other embodiments as appropriate.

### REFERENCE NUMERALS

CCMG: color conversion layer, CFG: coloring layer, 10: electronic device, 10A: electronic device, 10B: electronic device, 10C: electronic device, 10D: electronic device, 10E: electronic device, 10F: electronic device, 11: display apparatus, 11aL: display apparatus, 11aR: display apparatus, 11bL: display apparatus, 11bR: display apparatus, 11L: display apparatus, 11R: display apparatus, 12: housing, 13: optical element, 13L: optical element, 13R: optical element, 14: mounting portion, 15: display region, 15L: display region, 15R: display region, 17: fixing member, 21aL: lens, 21bL: lens, 22aL: input portion diffraction element, 22b1L: input portion diffraction element, 22b2L: input portion diffraction element, 22cL: input portion diffraction element, 22dL: input portion diffraction element, 23aL: light guide plate, 23bL: light guide plate, 24aL: output portion diffraction element, 24b1L: output portion diffraction element, 24b2L: output portion diffraction element, 24cL: output portion diffraction element, 24dL: output portion diffraction element, 25aL: diffraction element, 25b1L: diffraction element, 25b2L: diffraction element, 27: spacer, 31aL: light, 31b1L: light, 31b2L: light, 31cL: light, 31dL: light, 31L: light, 31R: light, 32: light, 35L: left eye, 61: light-emitting element, 61B: light-emitting element, 61G: light-emitting element, 61W: light-emitting element, 90a: pixel, 90a1: subpixel, 90a2: subpixel, 90b: pixel, 90b1: subpixel, 90b2: subpixel, 100A: display apparatus, 100B: display apparatus, 100C: display apparatus, 100D: display apparatus, 100E: display apparatus, 100F: display apparatus, 100G: display apparatus, 101: substrate, 102: insulating layer, 103: insulating layer, 104: insulating layer, 110a: light-emitting diode, 110b: light-emitting diode, 113a: semiconductor layer, 113b: semiconductor layer, 114a: light-emitting layer, 114b: light-emitting layer, 115a: semiconductor layer, 115b: semiconductor layer, 116a: conductive layer, 116b: conductive layer, 116c: conductive layer, 116d: conductive layer, 117: electrode, 117a: electrode, 117b: electrode, 117c: electrode, 117d: electrode, 120a: transistor, 120b: transistor, 130a: transistor, 130b: transistor, 131: substrate, 132: element isolation layer, 133: low-resistance region, 134: insulating layer, 135: conductive layer, 136: insulating layer, 137: conductive layer, 138: conductive layer, 139: insulating layer, 140: substrate, 141: insulating layer, 142: conductive layer, 143: insulating layer, 150A: LED substrate, 150B: circuit board, 151: layer, 152: insulating layer, 161: conductive layer, 162: insulating layer, 163: insulating layer, 164: insulating layer, 165: metal oxide layer, 166: conductive layer, 167: insulating layer, 168: conductive layer, 171: substrate, 172: wiring, 173: insulating layer, 174: electrode, 175: conductive layer, 176: connector, 177: electrode, 178: electrode, 179: adhesive layer, 181: insulating layer, 182: insulating layer, 183: insulating layer, 184a: conductive layer, 184b: conductive layer, 185: insulating layer, 186: insulating layer, 187: insulating layer, 188: insulating layer, 189a: conductive layer, 189b: conductive layer, 189c: conductive layer, 189d: conductive layer, 190: conductive layer, 190a: conductive layer, 190b: conductive layer, 190c: conductive layer, 190d: conductive layer, 190e: conductive layer, 191: substrate, 192: adhesive layer, 195: conductor, 196: FPC, 197: FPC, 261: conductive layer, 262: EL layer, 262a: EL layer, 262b: EL layer, 262B: EL layer, 262G: EL layer, 262W: EL layer, 263: conductive layer, 264B: coloring layer, 264G: coloring layer, 265: organic layer, 266: resin layer, 271: protective layer, 272: insulating layer, 273: protective layer, 275: region, 276: insulating layer, 277: micro lens array, 363: insulating layer, 415: protective layer, 419: resin layer, 420: substrate, 700A: electronic device, 700B: electronic device, 700C: electronic device, 721: housing, 723: mounting portion, 727: earphone portion, 728: bone-conduction speaker, 729: operation button, 750: earphones, 751: display panel, 753: optical member, 756: display region, 757: frame, 758: nose pad, 800A: electronic device, 800B: electronic device, 800C: electronic device, 820: display portion, 821: housing, 822: communication portion, 823: mounting portion, 824: control portion, 825: image capturing portion, 827: earphone portion, 828: bone-conduction speaker, 832: lens, 4411: light-emitting layer, 4412: light-emitting layer, 4413: light-emitting layer, 4420: layer, 4420-1: layer, 4420-2: layer, 4430: layer, 4430-1: layer, 4430-2: layer, 4440: intermediate layer, 8200: head-mounted display, 8201: mounting portion, 8202: lens, 8203: main body, 8204: display apparatus, 8205: cable, 8206: battery, 8207: display region

1. An electronic device comprising a first display apparatus, a second display apparatus, and an optical element,
wherein the first display apparatus comprises a first light-emitting element,
wherein the second display apparatus comprises a second light-emitting element,
wherein a color of first light emitted from the first light-emitting element is different from a color of second light emitted from the second light-emitting element,
wherein the optical element is provided between the first display apparatus and the second display apparatus, and
wherein the optical element comprises a first light guide plate and a second light guide plate.

2. An electronic device comprising a first display apparatus, a second display apparatus, and an optical element,
wherein the first display apparatus comprises a first light-emitting element,
wherein the second display apparatus comprises a second light-emitting element,
wherein a color of first light emitted from the first light-emitting element is different from a color of second light emitted from the second light-emitting element,
wherein the optical element is provided between the first display apparatus and the second display apparatus,
wherein the optical element comprises a first light guide plate, a second light guide plate, a first input portion diffraction element, a second input portion diffraction element, a first output portion diffraction element, and a second output portion diffraction element,
wherein the first input portion diffraction element is configured to make the first light enter the first light guide plate,
wherein the second input portion diffraction element is configured to make the second light enter the second light guide plate,
wherein the first output portion diffraction element is configured to deliver the first light entering the first light guide plate to an outside of the first light guide plate, and
wherein the second output portion diffraction element is configured to deliver the second light entering the second light guide plate to an outside of the second light guide plate.

3. The electronic device according to claim 1,
wherein the first display apparatus comprises a region overlapping with the second display apparatus with the optical element therebetween.

4. The electronic device according to claim 1,
wherein the first display apparatus does not overlap with the second display apparatus with the optical element therebetween.

5. The electronic device according to claim 3,
wherein the second display apparatus further comprises a third light-emitting element, and
wherein the color of the first light, the color of the second light, and a color of third light emitted from the third light-emitting element are different from each other.

6. The electronic device according to claim 5,
wherein the optical element further comprises a third input portion diffraction element and a third output portion diffraction element,
wherein the third input portion diffraction element is configured to make the third light enter the first light guide plate,
wherein the third output portion diffraction element is configured to deliver the third light entering the first light guide plate to the outside of the first light guide plate, and
wherein an image is formed by synthesizing the first light and the third light delivered by the first light guide plate and the second light delivered by the second light guide plate.

7. The electronic device according to claim 5,
wherein the first light-emitting element is an element emitting red light,
wherein the second light-emitting element is an element emitting green light, and
wherein the third light-emitting element is an element emitting blue light.

8. The electronic device according to claim 7,
wherein the first light-emitting element, the second light-emitting element, and the third light-emitting element are each a micro light-emitting diode comprising an inorganic compound as a light-emitting material.

9. The electronic device according to claim 7,
wherein the first light-emitting element is a micro light-emitting diode comprising an organic compound as a light-emitting material, and
wherein the second light-emitting element and the third light-emitting element are each a micro light-emitting diode comprising an inorganic compound as a light-emitting material.

10. The electronic device according to claim 5,
wherein the first light-emitting element is an element emitting blue light,
wherein the second light-emitting element is an element emitting green light, and
wherein the third light-emitting element is an element emitting red light.

11. The electronic device according to claim 10,
wherein the first light-emitting element, the second light-emitting element, and the third light-emitting element are each a micro light-emitting diode comprising an organic compound as a light-emitting material.

12. The electronic device according to claim 3 4,
wherein the first display apparatus further comprises a fourth light-emitting element,
wherein the second display apparatus further comprises a third light-emitting element, and
wherein the color of the first light, the color of the second light, a color of third light emitted from the third light-emitting element, and a color of fourth light emitted from the fourth light-emitting element are different from each other.

13. The electronic device according to claim 12,
wherein an image is formed by synthesizing the first light, the second light, the third light, and the fourth light delivered by the optical element.

14. The electronic device according to claim 12,
wherein the first light-emitting element is an element emitting red light,
wherein the second light-emitting element is an element emitting green light,
wherein the third light-emitting element is an element emitting blue light, and
wherein the fourth light-emitting element is an element emitting yellow light.

15. The electronic device according to claim 3 4,
wherein the second display apparatus further comprises a third light-emitting element and a fourth light-emitting element, and
wherein the color of the first light, the color of the second light, a color of third light emitted from the third light-emitting element, and a color of fourth light emitted from the fourth light-emitting element are different from each other.

16. The electronic device according to claim 15,
wherein an image is formed by synthesizing the first light, the second light, the third light, and the fourth light delivered by the optical element.

17. The electronic device according to claim 15,
wherein the first light-emitting element is an element emitting red light,
wherein the second light-emitting element is an element emitting green light,
wherein the third light-emitting element is an element emitting blue light, and
wherein the fourth light-emitting element is an element emitting white light.

18. The electronic device according to claim 2,
wherein the first display apparatus comprises a region overlapping with the second display apparatus with the optical element therebetween.

19. The electronic device according to claim 2,
wherein the first display apparatus does not overlap with the second display apparatus with the optical element therebetween.

20. The electronic device according to claim 18,
wherein the second display apparatus further comprises a third light-emitting element, and
wherein the color of the first light, the color of the second light, and a color of third light emitted from the third light-emitting element are different from each other.

21. The electronic device according to claim 20,
wherein the optical element further comprises a third input portion diffraction element and a third output portion diffraction element,
wherein the third input portion diffraction element is configured to make the third light enter the first light guide plate,
wherein the third output portion diffraction element is configured to deliver the third light entering the first light guide plate to the outside of the first light guide plate, and
wherein an image is formed by synthesizing the first light and the third light delivered by the first light guide plate and the second light delivered by the second light guide plate.

22. The electronic device according to claim 20,
wherein the first light-emitting element is an element emitting red light,
wherein the second light-emitting element is an element emitting green light, and
wherein the third light-emitting element is an element emitting blue light.

23. The electronic device according to claim 22,
wherein the first light-emitting element, the second light-emitting element, and the third light-emitting element are each a micro light-emitting diode comprising an inorganic compound as a light-emitting material.

24. The electronic device according to claim 22,
wherein the first light-emitting element is a micro light-emitting diode comprising an organic compound as a light-emitting material, and
wherein the second light-emitting element and the third light-emitting element are each a micro light-emitting diode comprising an inorganic compound as a light-emitting material.

25. The electronic device according to claim 20,
wherein the first light-emitting element is an element emitting blue light,
wherein the second light-emitting element is an element emitting green light, and
wherein the third light-emitting element is an element emitting red light.

26. The electronic device according to claim 25,
wherein the first light-emitting element, the second light-emitting element, and the third light-emitting element are each a micro light-emitting diode comprising an organic compound as a light-emitting material.

27. The electronic device according to claim 18,
wherein the first display apparatus further comprises a fourth light-emitting element,
wherein the second display apparatus further comprises a third light-emitting element, and
wherein the color of the first light, the color of the second light, a color of third light emitted from the third light-emitting element, and a color of fourth light emitted from the fourth light-emitting element are different from each other.

28. The electronic device according to claim 27,
wherein an image is formed by synthesizing the first light, the second light, the third light, and the fourth light delivered by the optical element.

29. The electronic device according to claim 27,
wherein the first light-emitting element is an element emitting red light,
wherein the second light-emitting element is an element emitting green light,
wherein the third light-emitting element is an element emitting blue light, and
wherein the fourth light-emitting element is an element emitting yellow light.

30. The electronic device according to claim 18,
wherein the second display apparatus further comprises a third light-emitting element and a fourth light-emitting element, and
wherein the color of the first light, the color of the second light, a color of third light emitted from the third light-emitting element, and a color of fourth light emitted from the fourth light-emitting element are different from each other.

31. The electronic device according to claim 30,
wherein an image is formed by synthesizing the first light, the second light, the third light, and the fourth light delivered by the optical element.

32. The electronic device according to claim 30,
wherein the first light-emitting element is an element emitting red light,
wherein the second light-emitting element is an element emitting green light,
wherein the third light-emitting element is an element emitting blue light, and
wherein the fourth light-emitting element is an element emitting white light.
